(19) United States
(12) Patent Application Publication
(10) Pub. No.: US 2023/0125712 A1
(43) Pub. Date: Apr. 27, 2023

(54) SELF-LUMINOUS DISPLAY DEVICE

(71) Applicant: FUJIFILM Corporation, Tokyo (JP)

(72) Inventor: Nobutaka FUKAGAWA, Kanagawa (JP)

(73) Assignee: FUJIFILM Corporation, Tokyo (JP)

(21) Appl. No.: 18/048,307

(22) Filed: Oct. 20, 2022

Related U.S. Application Data
(63) Continuation of application No. PCT/JP2021/017052, filed on Apr. 28, 2021.

(30) Foreign Application Priority Data
Apr. 30, 2020 (JP) 2020-080658

(51) Int. Cl. G02B 5/22; G02B 5/20; H01L 33/50; G02B 1/04; C08L 25/06; C08L 71/02; C08L 29/04

(52) U.S. Cl. CPC G02B 5/223; G02B 5/202; H01L 33/504; G02B 1/04; C08L 25/06; C08L 71/02; C08L 29/04

(57) ABSTRACT

A self-luminous display device includes a wavelength selective absorption filter containing a resin and a dye including dye A, which has a main absorption wavelength band (WB) at a wavelength of 390 to 435 nm, a dye B, which has a main absorption WB at a wavelength of 500 to 520 nm, and a dye C, which has a main absorption WB at a wavelength of 580 to 620 nm, and a light emitting diode source, the wavelength selective absorption filter satisfies a definition according to Expression (I): Tₘᵢₙ (500 to 520)−Tₘᵢₙ (580 to 620)>0%; where Tₘᵢₙ indicates a minimum transmittance (%) at the cited wavelength, and a self-luminous display device in which the wavelength selective filter has a specific gas barrier layer directly disposed on at least one surface of the wavelength selective absorption filter.

### CROSS-REFERENCE TO RELATED APPLICATIONS

This application is a Continuation of PCT International Application No. PCT/JP2021/017052 filed on Apr. 28, 2021, which claims priority under 35 U.S.C. § 119 (a) to Japanese Patent Application No. 2020-080658 filed in Japan on Apr. 30, 2020. Each of the above applications is hereby expressly incorporated by reference, in its entirety, into the present application.

### 1. FIELD OF THE INVENTION

The present invention relates to a self-luminous display device.

### 2. DESCRIPTION OF THE RELATED ART

On the other hand, with the increase in the size of displays (display devices) or the spread of tablet personal computers (PCs) and smartphones, the environment in which displays are used has become more diverse, and thus it has become increasingly important to improve the visibility in bright places, for example, directly under sunlight or bright indoor lighting. In general, an antireflection function is provided in the display screen of the display so that an observer can easily see the image. Such a function is realized by an antireflection film or an antiglare film. Examples of the general antireflection film include an anti-reflection (AR) film or a low reflection (LR) film, in which a film having a refractive index different from that of a base material is coated on the surface of the base material to reduce reflection by the effect of interference between the light reflected on the surface of the base material and the light reflected on the surface of the coated film. In addition, examples of the general antiglare film include an antiglare (AG) film including an antiglare layer, in which a film having a fine uneven pattern is coated on the surface of a base material to prevent the reflected glare of the image by using the light scattering effect.

However, a part of the light incident on the display is transmitted through the antireflection film or the antiglare film on the surface and then is reflected on the surface of the electrode, wire, or the like, or the glass surface of the cell. This is called internal reflection. In association with the increase in resolution of displays, the proportion of the area of the metal parts such as electrodes or wires to the area of the entire panel (the area of the metal parts such as electrodes or wires/the area of the entire panel) increases, and thus the prevention of the above-described internal reflection is a particularly important factor in ensuring high-quality display performance.

As a means for preventing the internal reflection, there is known a method of providing a λ/4 phase difference plate or a λ/2 phase difference plate between a polarizing element of a polarizing plate and an internal reflection place and causing it to function as a circularly polarizing plate, for example, as described in WO2012/0433375A. However, this method has a problem that the transmittance of the display light is reduced to about 40% and that in a case where scattering particles are present between the circularly polarizing plate and the internal reflection place, depolarization occurs and thus a sufficient antireflection effect cannot be obtained.

As a result, there is a demand for the development of an antireflection unit that does not use the λ/4 phase difference plate or the λ/2 phase difference plate.

For example, JP2015-36734A discloses a liquid crystal display device using a method of preventing external light reflection by adding an absorption material having an absorption peak having a half-width of 50 nm or less in a polarizing plate on a viewer side, the absorption material being at least one of a first absorption material having a maximum value of absorbance in a wavelength band of 470 to 510 nm or a second absorption material having a maximum value of absorbance in a wavelength band of 560 to 610 nm.

In addition, for the intended purpose of suppressing a decrease in contrast and improving color reproduction in a bright place for an image display device, particularly a self-luminous type image display device such as a plasma display, JP2008-203436A proposes using an optical filter having an absorption maximum in each of a wavelength range of 380 nm to 420 nm, a wavelength range of 480 nm to 520 nm, and a wavelength range of 585 nm to 620 nm.

### SUMMARY OF THE INVENTION

In recent years, in association with the development of a display (hereinafter, referred to as a “self-luminous display device”) using self-luminous light from an organic light emitting diode (OLED) element, a micro light emitting diode (LED) element, a mini LED element, or the like has been promoted, there is a need for an antireflection unit different from the λ/4 phase difference plate or the λ/2 phase difference plate, which is capable of being applied to a self-luminous display device including this LED as a light emitting element.

As a result of repeated studies by the inventors of the present invention, it was found that in the technique described in JP2015-36734A above, a change in the tint of the reflected light becomes large in a case of attempting to reduce the external light reflection to a desired level, and conversely, the reflectivity cannot be sufficiently reduced in a case of attempting to suppress the change in the tint of the reflected light to a desired level. In addition, it has been found that the technique described in JP2008-203436A is not sufficient from the viewpoint of reducing external light reflection while suppressing a decrease in brightness, and there is room for improvement.

Therefore, an object of one form of the present invention is to provide a self-luminous display device in which suppression of a decrease in brightness and antireflection are excellent and a change in the tint of the reflected light, due to the inclusion of the wavelength selective absorption filter, is suppressed in a case where a wavelength selective absorption filter is used as the antireflection unit instead of the circularly polarizing plate, in a self-luminous display device including LED as a light emitting element.

In addition, it was also found that although the technique described in JP2015-36734A is a promising method in a display, such as a liquid crystal display device, in which the use of a polarizing plate is essential, the self-luminous display device has a problem that it does not have a polarizing plate, and thus the absorber material is easily deteriorated by light due to the fact that the absorber material is not covered with a polarizer, and improvement is required from the viewpoint of light resistance. It has also been found that the method described in JP2008-203436A has a problem that the absorber material is easily deteriorated by light, and improvement is required from the viewpoint of light resistance.

That is, in a case where the wavelength selective absorption filter is used as an antireflection unit of a self-luminous display device instead of a circularly polarizing plate, a configuration is made such that a polarizing plate does not exist on the outside of the wavelength selective absorption filter. Therefore, a dye in the wavelength selective absorption filter is required to have a high light resistance.

For example, WO2017/014272A describes a color correction filter containing two types of coloring agents each having a maximal absorption at a specific different wavelength range and a resin as a color correction filter that is used in a liquid crystal display device using a white light emitting diode (LED) as a light source. Further, it is described that a gas barrier layer is provided in order to suppress a decrease in an absorption intensity of a coloring agent due to light irradiation, and specifically, a color correction filter including a gas barrier layer consisting of an inorganic material SiOₓ or SiNₓ is described. Among materials having gas barrier properties, an inorganic material can exhibit more excellent gas barrier properties, because an oxygen permeability coefficient is lower and hygroscopicity is also lower than organic material.

On the other hand, the gas barrier layer consisting of the inorganic material is unsuitable from the viewpoint of industrial productivity. That is, since the gas barrier layer of the inorganic material is obtained by laminating the inorganic material, such as a plasma-enhanced chemical vapor deposition (plasma CVD) method, a sputtering method, or a vapor deposition method, a production step is complicated and the cost also increases, compared to an organic material with which the gas barrier layer can be produced by a coating method, film bonding, or the like. In addition, production efficiency is also inferior. For example, in a case where a gas barrier layer consisting of an inorganic material is formed by a sputtering method, it takes time about 100 times to 1000 times to provide a layer having the same thickness as a gas barrier layer of an organic material to be obtained by a coating method, which is not suitable for mass production.

Therefore, an object of one form of the present invention is to provide a self-luminous display device in which suppression of a decrease in brightness and antireflection are excellent, a change in the tint of the reflected light, due to the inclusion of the wavelength selective absorption filter, is suppressed, excellent light resistance is exhibited, and productivity is also excellent in a case where the wavelength selective absorption filter is used as an antireflection unit instead of the circularly polarizing plate and a gas barrier layer is provided on the wavelength selective absorption filter, in a self-luminous display device including LED as a light emitting element.

As a result of diligent studies in consideration of the above problems, the inventors of the present invention found that in a self-luminous display device that has a wavelength selective absorption filter containing three kinds of dyes respectively having main absorption wavelength bands in specific wavelength ranges different from each other and a resin and includes LED as a light emitting element, it is possible to achieve both the suppression of external light reflection and the decrease in brightness and sufficiently suppress the influence on the tint of the display image by employing a wavelength selective absorption filter in which the transmittance at a wavelength of 500 to 520 nm and the transmittance at a wavelength of 580 to 620 nm satisfy a specific relational expression, and it is possible to achieve both the suppression of external light reflection and the decrease in brightness and sufficiently suppress a change in the tint of the reflected light by causing the self-luminous display device to have a configuration in which a gas barrier layer having a specific thickness and containing a crystalline resin is provided, and furthermore, it is possible to obtain a self-luminous display device exhibiting excellent light resistance. Further studies have been carried out based on these findings, whereby the present invention has been completed.

That is, the above object has been achieved by the following means.

<1>

A self-luminous display device comprising:

a wavelength selective absorption filter containing a resin and a dye that includes the following dyes A, B, and C; and

a light emitting diode as a light emitting source,

in which the wavelength selective absorption filter satisfies a definition according to Expression (I),

the dye A: a dye having a main absorption wavelength band at a wavelength of 390 to 435 nm

the dye B: a dye having a main absorption wavelength band at a wavelength of 500 to 520 nm

the dye C: a dye having a main absorption wavelength band at a wavelength of 580 to 620 nm

Tₘᵢₙ(500to520)−Tₘᵢₙ(580to620)>0% Expression (I)

in the expression, Tₘᵢₙ (500 to 520) indicates a minimum transmittance (%) at a wavelength of 500 to 520 nm, and Tₘᵢₙ (580 to 620) indicates a minimum transmittance (%) at a wavelength of 580 to 620 nm.

<2>

A self-luminous display device comprising:

a wavelength selective absorption filter containing a resin and the following dyes A, B, and C; and

a light emitting diode as a light emitting source,

in which the wavelength selective filter has a gas barrier layer directly disposed on at least one surface of the wavelength selective absorption filter, and

the gas barrier layer contains a crystalline resin, where a thickness of the gas barrier layer is 0.1 m to 10 m, and an oxygen permeability of the gas barrier layer is 60 cc/m²·day·atm or less.

the dye A: a dye having a main absorption wavelength band at a wavelength of 390 to 435 nm

the dye B: a dye having a main absorption wavelength band at a wavelength of 500 to 520 nm

the dye C: a dye having a main absorption wavelength band at a wavelength of 580 to 620 nm

<3>

The self-luminous display device according to <1> in which the wavelength selective filter has a gas barrier layer directly disposed on at least one surface of the wavelength selective absorption filter, and

the gas barrier layer contains a crystalline resin, where a thickness of the gas barrier layer is 0.1 m to 10 m, and an oxygen permeability of the gas barrier layer is 60 cc/m²·day·atm or less.

<4>

The self-luminous display device according to <2> or <3>, in which a degree of crystallinity of the crystalline resin contained in the gas barrier layer is 25% or more.

<5>

The self-luminous display device according to any one of <2> to <4>, in which the oxygen permeability of the gas barrier layer is 0.001 cc/m²·day·atm or more and 60 cc/m²·day·atm or less.

<6>

The self-luminous display device according to any one of <1> to <5>, in which the wavelength selective absorption filter contains an antifading agent for a dye.

<7>

The self-luminous display device according to any one of <1> to <6>, in which at least one of the dye B or C is a squarine-based coloring agent represented by General Formula (1),

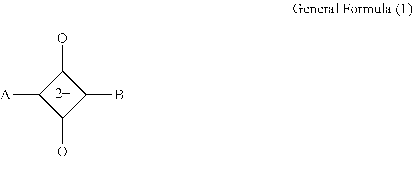

in the formula, A and B each independently represent an aryl group which may have a substituent, a heterocyclic group which may have a substituent, or —CH=G, where G represents a heterocyclic group which may have a substituent.

<8>

The self-luminous display device according to any one of <1> to <7>, in which the dye A is a coloring agent represented by General Formula (A1),

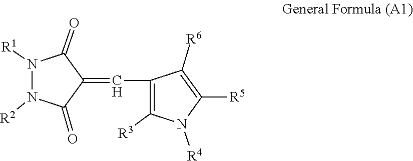

in the formula, R¹ and R² each independently represent an alkyl group or an aryl group, R³ to R⁶ each independently represent a hydrogen atom or a substituent, and R⁵ and R⁶ may be bonded to each other to form a 6-membered ring.

<9>

The self-luminous display device according to <6>, in which the antifading agent is represented by General Formula (IV),

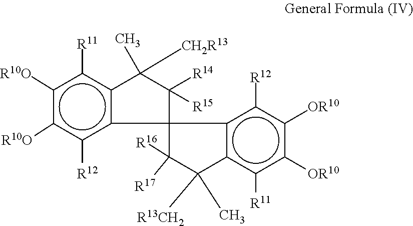

in the formula, R¹⁰'s each independently represent an alkyl group, an alkenyl group, an aryl group, a heterocyclic group, or a group represented by R¹⁸CO—, R¹⁹SO₂—, or R²⁰NHCO—, where R¹⁸, R¹⁹, and R²⁰ each independently represent an alkyl group, an alkenyl group, an aryl group, or a heterocyclic group, R¹¹ and R¹² each independently represent a hydrogen atom, a halogen atom, an alkyl group, an alkenyl group, an alkoxy group, or an alkenyloxy group, and

R¹³ to R¹⁷ each independently represent a hydrogen atom, an alkyl group, an alkenyl group, or an aryl group.

<10>

The self-luminous display device according to any one of <1> to <9>, in which the resin in the wavelength selective absorption filter includes a polystyrene resin.

<11>

The self-luminous display device according to any one of <1> to <10>, in which the light emitting diode includes a mini light emitting diode or a micro light emitting diode.

In the present invention, in a case where there are a plurality of substituents, linking groups, and the like (hereinafter, referred to as substituents and the like) represented by specific reference numerals or formulae, or in a case where a plurality of substituents and the like are defined at the same time, the respective substituents and the like may be the same or different from each other unless otherwise specified. The same applies to the definition of the number of substituents or the like. In addition, in a case where a plurality of substituents and the like are close to each other (particularly in a case where the substituents and the like are adjacent to each other), the substituents and the like may also be linked to each other to form a ring unless otherwise specified. In addition, unless otherwise specified, rings, for example, alicyclic rings, aromatic rings, and heterocyclic rings may be further fused to form a fused ring.

In the present invention, in a case where the number of carbon atoms of a certain group is defined, this number of carbon atoms means the number of carbon atoms of the entire group thereof unless otherwise specified in the present invention or the present specification. That is, in a case where this group is in a form of further having a substituent, the number of carbon atoms means the number of carbon atoms of the entire group including this substituent.

In the present invention, unless otherwise specified, the wavelength selective absorption filter may contain one kind of each of the components constituting the wavelength selective absorption filter (for example, a dye, a resin, and an antifading agent for a dye and another component that may be contained) or may contain two or more kinds thereof. Similarly, unless otherwise specified, one kind of each of components (a crystalline resin and the like) constituting the gas barrier layer may be contained in the gas barrier layer, or two or more kinds thereof may be contained therein.

In the present invention, in a case where an E type double bond and a Z type double bond are present in a molecule, the double bond may be any one thereof or may be a mixture thereof, unless otherwise specified.

In the present invention, the representation of a compound (including a complex) is used to mean not only the compound itself but also a salt thereof, and an ion thereof. In addition, it is meant to include those in which a part of the structure is changed, as long as the effect of the present invention is not impaired. Furthermore, it is meant that a compound, which is not specified to be substituted or unsubstituted, may have any substituent, as long as the effect of the present invention is not impaired. The same applies to the definition of a substituent or a linking group.

In addition, in the present invention, the numerical range indicated by using “to” means a range including the numerical values before and after “to” as the lower limit value and the upper limit value, respectively.

In the present invention, the “composition” includes a mixture in which the component concentration varies within a range in which a desired function is not impaired, in addition to a mixture in which the component concentration is constant (each component is uniformly dispersed).

In the present invention, the description of “having a main absorption wavelength band at a wavelength XX to YY nm” means that a wavelength at which the maximal absorption is exhibited (that is, the maximal absorption wavelength) is present in a wavelength range of XX to YY nm.

Therefore, in a case where the maximal absorption wavelength is present in the above-described wavelength range, the entire absorption band including this wavelength may be in the above-described wavelength range or may also extend up to the outside of the above-described wavelength range. In addition, in a case where there are a plurality of maximal absorption wavelengths, it suffices that a maximal absorption wavelength at which the highest absorbance is exhibited is present in the above-described wavelength range. That is, the maximal absorption wavelength other than the maximal absorption wavelength at which the highest absorbance is exhibited may be present either inside or outside the above-described wavelength range of XX to YY nm.

In the present invention, the minimum transmittance in a wavelength range of SS to TT nm indicates the transmittance at a wavelength at which the minimum transmittance in the wavelength range of SS to TT nm, among the transmittances measured in units of 1 nm.

One form of the self-luminous display device of an aspect of the present invention is a self-luminous display device in which LED is provided as a light emitting element, suppression of a decrease in brightness and antireflection are excellent and furthermore, suppression of a change in the tint of the reflected light due to the inclusion of the wavelength selective absorption filter, is also excellent even in a case where a wavelength selective absorption filter is used as an antireflection unit instead of the circularly polarizing plate.

In addition, another form of the self-luminous display device according to an aspect of the present invention is a self-luminous display device in which LED is provided as a light emitting element, suppression of a decrease in brightness and antireflection are excellent, suppression of a change in the tint of the reflected light, due to the inclusion of the wavelength selective absorption filter, is also excellent, excellent light resistance is exhibited, and productivity is also excellent even in a case where the wavelength selective absorption filter is used as an antireflection unit instead of the circularly polarizing plate and a gas barrier layer is provided on the wavelength selective absorption filter.

### BRIEF DESCRIPTION OF THE DRAWINGS

FIG. 1 is a schematic cross-sectional view illustrating an example of a laminate including a wavelength selective absorption filter that is used in a self-luminous display device of the present invention.

FIG. 2 is a schematic view illustrating a layer configuration assumed for carrying out a simulation of external light reflection in Examples.

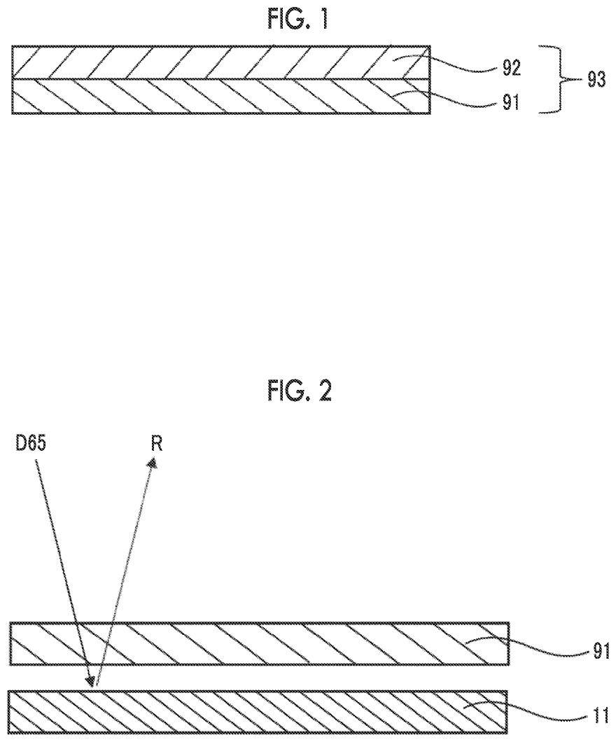

### DESCRIPTION OF THE PREFERRED EMBODIMENTS

Hereinafter, a wavelength selective absorption filter included in a self-luminous display device according to an embodiment of the present invention will be described in order.

<<Wavelength Selective Absorption Filter>>

The wavelength selective absorption filter (hereinafter, also referred to as a wavelength selective absorption layer) included in the self-luminous display device according to the embodiment of the present invention contains a resin and a dye including the following dyes A to C respectively having main absorption wavelength bands in wavelength ranges different from each other.

the dye A: a dye having a main absorption wavelength band at a wavelength of 390 to 435 nm

the dye B: a dye having a main absorption wavelength band at a wavelength of 500 to 520 nm

the dye C: a dye having a main absorption wavelength band at a wavelength of 580 to 620 nm

In the wavelength selective absorption layer, the “dye” is dispersed (preferably dissolved) in the resin to make the wavelength selective absorption layer a layer exhibiting a specific absorption spectrum derived from the dye. In addition, in a case where the wavelength selective absorption layer contains an antifading agent for a dye described below, this “antifading agent for a dye” is dispersed (preferably dissolved) in the resin to capture radicals such as singlet oxygen and to be oxidized instead of the dye, and can effectively suppress the fading of the dye.

In the present invention, the main absorption wavelength band of a dye is a main absorption wavelength band of a dye, which is measured in a state of being a wavelength selective absorption filter. Specifically, in Examples described later, it is measured in a state of being a wavelength selective absorption filter under the conditions described in the sections of the maximal absorption value and the transmittance of the wavelength selective absorption filter.

<Dye>

The wavelength selective absorption layer is a layer containing the dye A, the dye B, and the dye C, which are described above.

The dye A that can be contained in the wavelength selective absorption layer may be one kind or two or more kinds. Similar to the above-described dye A, the dyes B and C that can be contained in the wavelength selective absorption layer may be each independently one kind or two or more kinds.

The wavelength selective absorption layer may also contain a dye other than the above-described dyes A to C within the range in which the effect of the present invention is exhibited.

It suffices that the form of the wavelength selective absorption layer is such that the dye in the wavelength selective absorption layer can exhibit an absorption spectrum, both suppression of external light reflection and suppression of a decrease in brightness can be realized, and further, a change in the tint of the reflected light due to the inclusion of the wavelength selective absorption filter (hereinafter, also simply referred to as a “change in the tint of the reflected light”) is suppressed. Examples of one form of the wavelength selective absorption layer include a form in which at least one of the dye A, . . . , or C is dispersed (preferably dissolved) in the resin. The dispersion may be any type of dispersion, such as a random type or a regular type.

In the wavelength selective absorption layer, the dyes A to C respectively have main absorption wavelength bands in 390 to 435 nm, 500 to 520 nm, 580 to 620 nm, and, which are wavelength ranges other than B (Blue, 440 nm to 470 nm), G (Green, 520 nm to 560 nm), and R (Red, 620 nm to 660 nm) which are used as light emitting sources of the self-luminous display device of the present invention or wavelength ranges that do not significantly overlap with these wavelength ranges. As a result, in a case of containing these dyes A to C, the wavelength selective absorption layer can suppress the external light reflection while suppressing the decrease in brightness and furthermore can suppress the change in the tint of the reflected light.

In a case where the dyes A to C are contained in the wavelength selective absorption layer as described above, there may be a problem that the light resistance is lowered due to the mixing of the dyes due to the chain transfer of radicals generated at the time of dye decomposition. In one embodiment of the present invention, even such a problem can be dealt since an excellent level of light resistance that overtakes the decrease in light resistance in association with the mixing of the dyes can be exhibited in a case where the wavelength selective absorption layer directly includes a specific gas barrier layer described later on at least one surface of the wavelength selective absorption layer.

The wavelength selective absorption layer in the self-luminous display device according to the embodiment of the present invention preferably satisfies the following Relational Expression (I) from the viewpoint of balancedly achieving, at a more excellent level, suppression of a decrease in brightness, antireflection, and suppression of a change in the tint of the reflected light due to the inclusion of the wavelength selective absorption filter, as compared with a case where a wavelength selective absorption filter in the related art is used. Examples of another embodiment of the present invention include a self-luminous display device having a wavelength selective absorption layer satisfying the following Relational Expression (I) as the above-described wavelength selective absorption layer.

Tₘᵢₙ(500to520)−Tₘᵢₙ(580to620)>0% Expression (I)

in the expression, Tₘᵢₙ (500 to 520) indicates a minimum transmittance (%) at a wavelength of 500 to 520 nm, and Tₘᵢₙ(580 to 620) indicates a minimum transmittance (%) at a wavelength of 580 to 620 nm.

The wavelength selective absorption layer satisfying the relationship defined by Expression (I) can minimize a decrease in brightness and prevent external light reflection. In particular, the self-luminous display device according to the embodiment of the present invention is a self-luminous display device including a light emitting diode as a light emitting source, and in a display device in which all three colors R, G, and B are derived from self-luminous light sources as shown in Examples described later, the display light is hardly included in a wavelength range of 580 to 620 nm, whereas the base range of the display light of G is present in a wavelength range of 500 to 520 nm at a constant intensity in a large number of cases. Therefore, in a case of satisfying Relational Expression (I), it is possible to block external light in a wavelength range in which the luminous efficiency is high and the display light is hardly included (that is, the wavelength range of a wavelength of 580 to 620 nm) with respect to the wavelength range of 500 to 520 nm, and it is possible to more efficiently reduce the reflectivity and suppress a change in the tint of the reflected light while suppressing a decrease in brightness to a minimum.

Relational Expression (I) is preferably

Tₘᵢₙ(500to520)−Tₘᵢₙ(580-to620)>5%, and

it is more preferably

Tₘᵢₙ(500to520)−Tₘᵢₙ(580-to620)>10%

The transmittances (Tₘᵢₙ(500 to 520) and Tₘᵢₙ (580 to 620)) described in Relational Expression (I) and the like are measured in Examples described later in a state of being a wavelength selective absorption layer under the conditions described in the sections of the maximal absorption value and the transmittance of the wavelength selective absorption filter (the wavelength selective absorption layer).

(Dye A)

The dye A is not particularly limited as long as it has a main absorption wavelength band in a wavelength of 390 to 435 nm in the wavelength selective absorption filter, and various dyes can be used, where it is preferably a dye having a main absorption wavelength band in a wavelength of 405 to 435 nm in the wavelength selective absorption filter.

The dye A is preferably a coloring agent represented by General Formula (A1) in that an absorption waveform in the main absorption wavelength band is sharp and the light resistance is further improved.

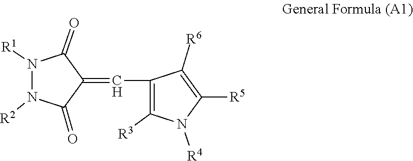

In General Formula (A1), R¹ and R² each independently represent an alkyl group or an aryl group, R³ to R⁶ each independently represent a hydrogen atom or a substituent, and R⁵ and R⁶ may be bonded to each other to form a 6-membered ring.

The alkyl group that can be employed as R¹ and R² may be any one of an unsubstituted alkyl group or a substituted alkyl group having a substituent, may be linear or branched, and may have a cyclic structure.

Examples of the unsubstituted alkyl group include a methyl group, an ethyl group, a normal propyl group, an isopropyl group, and a cyclohexyl group. The number of carbon atoms in the unsubstituted alkyl group is preferably 1 to 12 and more preferably 1 to 6.

Examples of the substituent that can be employed by the substituted alkyl group include a substituent included in the substituent group A below.

(Substituent Group A)

A halogen atom, an alkyl group, a cycloalkyl group, an aralkyl group, an alkenyl group, an alkynyl group, an aryl group, a heterocyclic group, a cyano group, a hydroxy group, a nitro group, and a carboxy group (may be in the form of a salt), an alkoxy group, an aryloxy group, a silyloxy group, a heterocyclic oxy group, an acyloxy group, a carbamoyloxy group, a sulfonyloxy group, an alkoxycarbonyloxy group, an aryloxycarbonyloxy group, and an amino group (containing a substituted amino group represented by —NR^{a}₂ in addition to —NH₂, where R^{a}'s each independently represent a hydrogen atom, an alkyl group, an aryl group, or a heteroaryl group, provided that at least one R^{a} is an alkyl group, an aryl group, or a heteroaryl group), an acylamino group, an aminocarbonylamino group, an alkylcarbonylamino group, an alkoxycarbonylamino group, an aryloxycarbonylamino group, a sulfamoylamino group, an alkylsulfonylamino group, an arylsulfonylamino group, a sulfonamide group, a mercapto group, an alkylthio group, an arylthio group, a heterocyclic thio group, a sulfamoyl group, and a sulfo group (may be in the form of a salt), an alkylsulfinyl group, an arylsulfinyl group, an alkylsulfonyl group, an arylsulfonyl group, an acyl group, an aryloxycarbonyl group, an alkoxycarbonyl group, a carbamoyl group, an imide group, a phosphino group, a phosphinyl group, a phosphinyloxy group, a phosphinylamino group, or a silyl group, and a monovalent group in which at least two of these are linked.

In the substituent group A, preferred examples of the substituent that can be contained in the substituted alkyl group include a halogen atom, an aryl group, an alkoxy group, an acyl group, and a hydroxy group.

The total number of carbon atoms in the substituted alkyl group is preferably 1 to 12. Examples thereof include a benzyl group, a hydroxybenzyl group, and a methoxyethyl group.

The total number of carbon atoms in the substituted alkyl group means the number of carbon atoms in the entire substituted alkyl group including the substituent that can be contained in the substituted alkyl group. Hereinafter, this will be used in the same meaning in regard to other groups as well.

In a case where both R¹ and R² represent an alkyl group, the alkyl groups may be the same or different from each other.

The aryl group that can be employed as R¹ and R² may be any one of an unsubstituted aryl group or a substituted aryl group having a substituent.

The unsubstituted aryl group is preferably an aryl group having 6 to 12 carbon atoms, and examples thereof include a phenyl group.

Examples of the substituent that can be employed by the substituted aryl group include a substituent included in the substituent group A below.

Among the substituent group A, preferred examples of the substituent that can be contained in the substituted aryl group include a halogen atom (for example, a chlorine atom, a bromine atom, or an iodine atom), a hydroxy group, a carboxy group, a sulfonamide group, or an amino group, (preferably, a substituted amino group represented by —NR^{a}₂, where R^{a}'s each independently represent a hydrogen atom or an alkyl group, provided that at least one R^{a} is an alkyl group, and the amino group preferably has 1 to 4 carbon atoms), an alkyl group (preferably, an alkyl group having 1 to 4 carbon atoms; for example, methyl, ethyl, normal propyl, or isopropyl), an alkoxy group (preferably, an alkoxy group having 1 to 4 carbon atoms; for example, methoxy, ethoxy, normal propoxy, or isopropoxy), an alkoxycarbonyl group (preferably, an alkoxycarbonyl groups having 2 to 5 carbon atoms; for example, methoxycarbonyl, ethoxycarbonyl, normal propoxycarbonyl, or isopropoxycarbonyl), and a sulfonyloxy group, as well as a monovalent group in which at least the two thereof are linked to each other.[0037] The substituted aryl group is preferably an aryl group having a total number of carbon atoms of 6 to 18.

For example, examples thereof include a 4-chlorophenyl group, a 2,5-dichlorophenyl group, a hydroxyphenyl group, a 4-carboxyphenyl group, a 3,5-dicarboxyphenyl group, a 4-methanesulfonamidophenyl group, a 4-methylphenyl group, a 4-methoxyphenyl group, a 4-(2-hydroxyethoxy)phenyl group, an N,N-dimethylaminophenyl group, a 4-(N-carboxymethyl-N-ethylamino)phenyl group, a 4-ethoxycarbonylphenyl group, and a 4-methanesulfonyloxyphenyl group.

In a case where both R¹ and R² represent an aryl group, the aryl groups may be the same or different from each other.

Examples of the substituent that can be employed as R³, R⁴, R⁵, and R⁶ include substituents included in the substituent group A.

Among the substituent group A, R³, R⁵, and R⁶ are preferably an alkyl group or an aryl group. That is, R³, R⁵, and R⁶ are each independently preferably a hydrogen atom, an alkyl group, or an aryl group.

In addition, in the substituent group A, R⁴ is preferably an alkyl group or an aryl group. That is, R⁴ is preferably a hydrogen atom, an alkyl group, or an aryl group.

The alkyl group that can be employed as R³, R⁵, and R⁶ may be any of an unsubstituted alkyl group or a substituted alkyl group having a substituent, and any of linear or branched, and may have a cyclic structure.

Examples of the unsubstituted alkyl group that can be employed as R³, R⁵, and R⁶ include a methyl group, an ethyl group, a normal propyl group, and an isopropyl group. The number of carbon atoms of the unsubstituted alkyl group that can be employed as R³, R⁵, and R⁶ is preferably 1 to 8 and more preferably 1 to 4.

Examples of the substituent that can be contained in the substituted alkyl group as R³, R⁵, and R⁶ include substituents included in the substituent group A.

Preferred examples of the substituent that can be contained in the substituted alkyl group as R³, R⁵, and R⁶ include an aryl group (preferably a phenyl group), a halogen atom, an acyl group, an amino group, an alkoxycarbonyl group, a carboxy group, and a hydroxy group.

The total number of carbon atoms in the substituted alkyl group that can be employed as R³, R⁵, and R⁶ is preferably 1 to 8. For example, a benzyl group, a carboxymethyl group, and a hydroxymethyl group are exemplified.

In a case where all of R³, R⁵, and R⁶ represent alkyl groups, the alkyl groups may be the same or different from each other.

The aryl group that can be employed as R³, R⁵, and R⁶ may be any one of an unsubstituted aryl group or a substituted aryl group which has been substituted.

The unsubstituted aryl group that can be employed as R³, R⁵, and R⁶ is preferably an aryl group having 6 to 10 carbon atoms, and examples thereof include a phenyl group.

Examples of the substituent that can be contained in the substituted aryl group as R³, R⁵, and R⁶ include substituents included in the substituent group A.

Preferred examples of the substituent that can be contained in the substituted aryl group as R³, R⁵, and R⁶ include a halogen atom (for example, a fluorine atom, a chlorine atom, a bromine atom, or an iodine atom), a hydroxy group, a carboxy group, an alkyl group (preferably an alkyl groups having 1 to 4 carbon atoms; for example, methyl, ethyl, normal propyl, or isopropyl).

The substituted aryl group that can be employed as R³, R⁵, and R⁶ is preferably an aryl group having a total number of carbon atoms of 6 to 10. Examples thereof include a 2-fluorophenyl group, a 4-chlorophenyl group, a 2,5-dichlorophenyl group, a hydroxyphenyl group, a carboxyphenyl group, a 3,5-dicarboxyphenyl group, and a 4-methylphenyl group.

In a case where both R⁵ and R⁶ are a substituent, R³ is preferably a hydrogen atom from the viewpoint of light resistance and heat resistance.

In a case where R³, R⁵, and R⁶ are all aryl groups, the aryl groups may be the same or different from each other.

The alkyl group that can be employed as R⁴ may be any one of an unsubstituted alkyl group or a substituted alkyl group having a substituent, may be linear or branched, and may have a cyclic structure.

Examples of the unsubstituted alkyl group that can be employed as R⁴ include a methyl group, an ethyl group, a normal propyl group, an isopropyl group, and a cyclohexyl group. The number of carbon atoms of the unsubstituted alkyl group that can be employed as R⁴ is preferably 1 to 8 and more preferably 1 to 4.

Examples of the substituent that can be contained in the substituted alkyl group as R⁴ include substituents included in the substituent group A.

Preferred examples of the substituent that can be contained in the substituted alkyl group as R⁴ include an aryl group (preferably, a phenyl group), a heterocyclic group, a carboxy group, a hydroxy group, an alkyl group (preferably, an alkyl group having 1 to 4 carbon atoms; for example, methyl, ethyl, normal propyl, or isopropyl), an alkoxy group (preferably, an alkoxy group having 1 to 4 carbon atoms; for example, methoxy, ethoxy, normal propoxy, or isopropoxy), an aryloxy group, an alkoxycarbonyl group (preferably, an alkoxycarbonyl groups having 2 to 5 carbon atoms; for example, methoxycarbonyl, ethoxycarbonyl, normal propoxycarbonyl, or isopropoxycarbonyl), an alkylamino group (preferably an alkylamino group having 1 to 4 carbon atoms; for example, a dimethylamino group), an alkylcarbonylamino group (preferably, an alkylcarbonylamino group having 1 to 4 carbon atoms; for example, a methylcarbonylamino group), a cyano group, and an acyl group (for example, an acetyl group, a propionyl group, a benzoyl group, or a mesyl group), as well as a monovalent group in which at least the two thereof are linked to each other.

The total number of carbon atoms in the substituted alkyl group that can be employed as R⁴ is preferably 1 to 18.

For example, a benzyl group, a carboxybenzyl group, a hydroxybenzyl group, a methoxycarbonylethyl group, an ethoxycarbonylmethyl group, a 2-cyanoethyl group, a 2-propionylaminoethyl group, a dimethylaminomethyl group, a methylcarbonylaminopropyl group, a di(methoxycarbonylmethyl)aminopropyl group, and a phenacyl group are exemplified.

The aryl group that can be employed as R⁴ may be any one of an unsubstituted aryl group or a substituted aryl group having a substituent.

The unsubstituted aryl group that can be employed as R⁴ is preferably an aryl group having 6 to 12 carbon atoms, and examples thereof include a phenyl group.

Examples of the substituent that can be contained in the substituted aryl group as R⁴ include substituents included in the substituent group A.

Preferred examples of the substituent that can be contained in the substituted aryl group as R⁴ include a halogen atom (for example, a chlorine atom, a bromine atom, or an iodine atom), a hydroxy group, a carboxy group, a sulfonamide group, an amino group, an alkyl group (preferably, an alkyl group having 1 to 4 carbon atoms; for example, methyl, ethyl, normal propyl, or isopropyl), an alkoxy group (preferably, an alkoxy group having 1 to 4 carbon atoms; for example, methoxy, ethoxy, normal propoxy, or isopropoxy), an alkoxycarbonyl group (preferably, an alkoxycarbonyl groups having 2 to 5 carbon atoms; for example, methoxycarbonyl, ethoxycarbonyl, normal propoxycarbonyl, or isopropoxycarbonyl), and a sulfonyloxy group, as well as a monovalent group in which at least the two thereof are linked to each other.

The amino group that can be contained in the substituted aryl group as R⁴ may be any one of an unsubstituted amino group (—NH₂) or a substituted amino group having a substituent (—NR^{a}₂ in the substituent group A).

In the amino group (—NR^{a}₂) that can be contained in the substituted aryl group as R⁴, examples of R^{a} include the same group as the substituted alkyl group as R⁴.

The substituted amino group is preferably an alkylamino group in which one or two hydrogen atoms in the amino group are substituted with an alkyl group.

Examples of the alkylamino group include a methylamino group, a dimethylamino group, a diethylamino group, and a pyrrolidino group. The number of carbon atoms in the alkylamino group is preferably 1 to 8 and more preferably 1 to 4.

Further, the alkyl group in the alkylamino group may be further substituted, and for example, a di(alkoxycarbonylalkyl)amino group is preferably mentioned. The di(alkoxycarbonylalkyl)amino group preferably has 6 to 10 carbon atoms and more preferably 6 to 8 carbon atoms.

The substituted aryl group that can be employed as R⁴ is preferably an aryl group having a total number of carbon atoms of 6 to 22. Examples thereof include a 4-chlorophenyl group, a 2,5-dichlorophenyl group, a hydroxyphenyl group, a 2,5-methoxyphenyl group, a 2-methoxy-5-ethoxycarbonylphenyl group, a 4-ethyloxycarbonylphenyl group, a 4-ethoxycarbonylphenyl group, a 4-butoxycarbonylphenyl group, a 4-octyloxycarbonylphenyl group, a 4-carboxyphenyl group, a 3,5-dicarboxyphenyl group, a 4-methanesulfonamidephenyl group, a 4-methylphenyl group, a 4-methoxyphenyl group, a 4-ethoxyphenyl group, a 4-(2-hydroxyethoxy)phenyl group, an N,N-dimethylaminophenyl group, an N,N-diethylaminophenyl group, a 4-(N-carboxymethyl-N-ethylamino)phenyl group, a 4-{N,N-di(ethoxycarbonylmethyl)amino}phenyl group, a 4-{di(ethoxycarbonylmethyl)amino}carbonylphenyl group, a 4-ethoxycarbonylphenyl group, a 4-methanesulfonyloxyphenyl group, a 4-acetylsulfamoylphenyl group, a 4-propionylsulfamoylphenyl group, and a 4-methanesulfoneamidephenyl group.

R⁵ and R⁶ may be bonded to each other to form a 6-membered ring. Hydrogen atoms may be eliminated during the formation of the ring to form an aromatic ring or an aliphatic ring having an unsaturated bond.

The 6-membered ring formed by R⁵ and R⁶ being bonded to each other is preferably a benzene ring.

In particular, from the viewpoint of light resistance, among R¹ and R² in General Formula (A1), it is preferable that R¹ is an alkyl group, and it is more preferable that R¹ is an alkyl group and R² is an alkyl group or an aryl group. In addition, from the same viewpoint, it is still more preferable that both R¹ and R² are each independently an alkyl group, and it is particularly preferable that both R¹ and R² are an alkyl group having 1 to 8 carbon atoms.

Further, in terms of heat resistance and light resistance, it is also preferable that both R¹ and R² in General Formula (A1) are an aryl group.

In a case where R¹ and R² each independently represent an aryl group, it is preferable that R³, R⁵, and R⁶ are each independently a hydrogen atom, an alkyl group, or an aryl group and at least one of R³ or R⁶ is a hydrogen atom. Among the above, from the viewpoint of heat resistance and light resistance, a case where R³ represents a hydrogen atom, and R⁵ and R⁶ each independently represent an alkyl group or an aryl group is more preferable. A case where R³ represents a hydrogen atom and R⁵ and R⁶ each independently represent an alkyl group is still more preferable. A case where R³ represents a hydrogen atom, R⁵ and R⁶ each independently represent an alkyl group, and R⁵ and R⁶ are bonded to each other to form a ring and fused with a pyrrole ring to form an indole ring together with the pyrrole ring is particularly preferable. That is, the coloring agent represented by General Formula (A1) is particularly preferably a coloring agent represented by General Formula (A2).

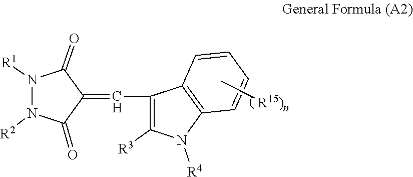

In General Formula (A2), R¹ to R⁴ respectively have the same meanings as R¹ to R⁴ in General Formula (A1), and the same applies to the preferred aspects thereof.

In General Formula (A2), R¹⁵ represents a substituent. Examples of the substituent that can be employed as R¹⁵ include substituents included in the substituent group A. R¹⁵ is preferably an alkyl group, an aryl group, a halogen atom, an acyl group, an amino group, or an alkoxycarbonyl group.

As the alkyl group and the aryl group, which can be employed as R¹⁵, the descriptions for the alkyl group and the aryl group, which can be employed as R³, R⁵, and R⁶, can be applied respectively.

Examples of the halogen atom that can be employed as R¹⁵ include a chlorine atom, a bromine atom, and an iodine atom.

Examples of the acyl group that can be employed as R¹⁵ include an acetyl group, a propionyl group, and a butyroyl group.

As the amino group that can be employed as R¹⁵, the description for the amino group that can be contained in the substituted aryl group as R⁴ can be applied. Further, a nitrogen-containing heterocyclic group having a 5-membered to 7-membered ring in which an alkyl group on the nitrogen atom of the amino group is bonded to form a ring is also preferable.

The alkoxycarbonyl group that can be employed as R¹⁵, is preferably an alkoxycarbonyl group having 2 to 5 carbon atoms, and examples thereof include methoxycarbonyl, ethoxycarbonyl, normal propoxycarbonyl, and isopropoxycarbonyl.

n represents an integer of 0 to 4. n is not particularly limited, and is, for example, preferably 0 or 1.

Specific examples of the coloring agent represented by General Formula (A1) are shown below. However, the present invention is not limited thereto.

In the specific examples below, Me represents a methyl group.

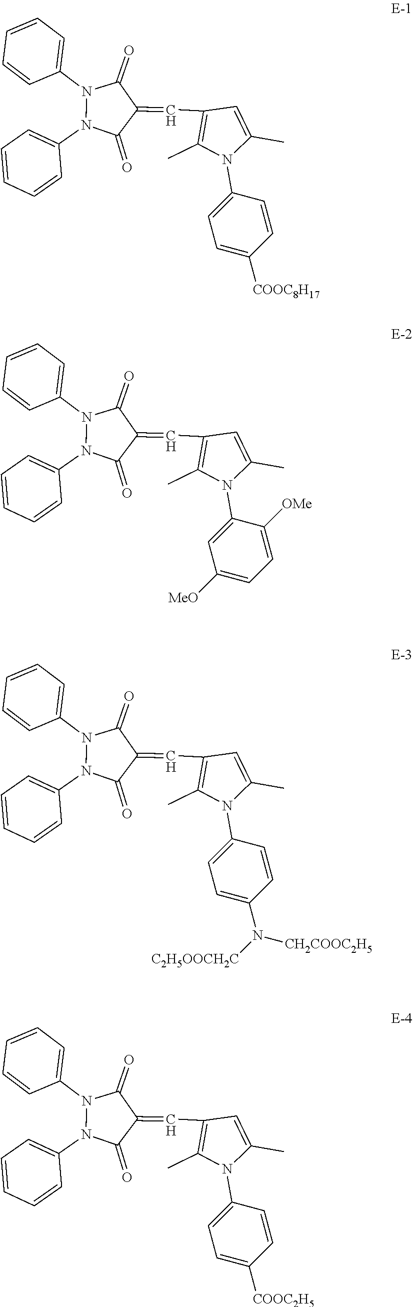

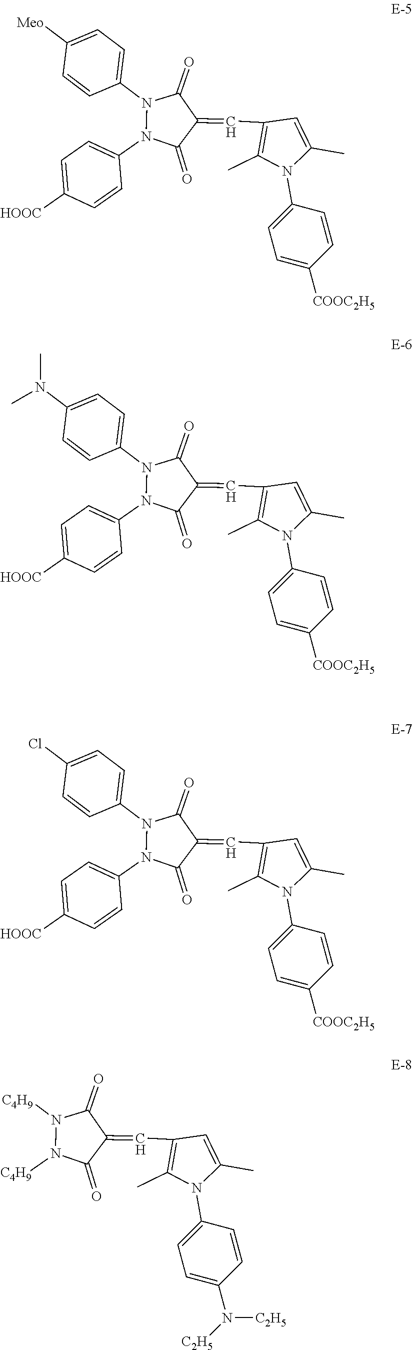

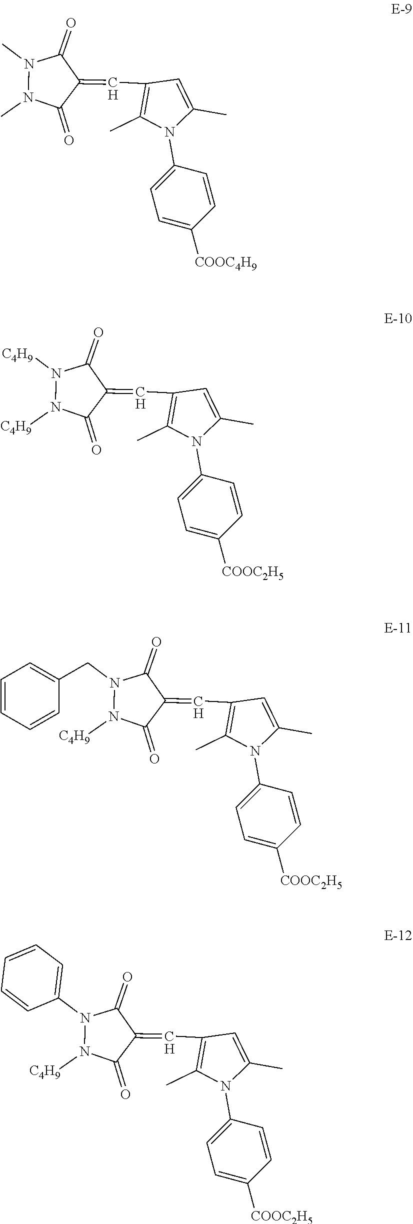

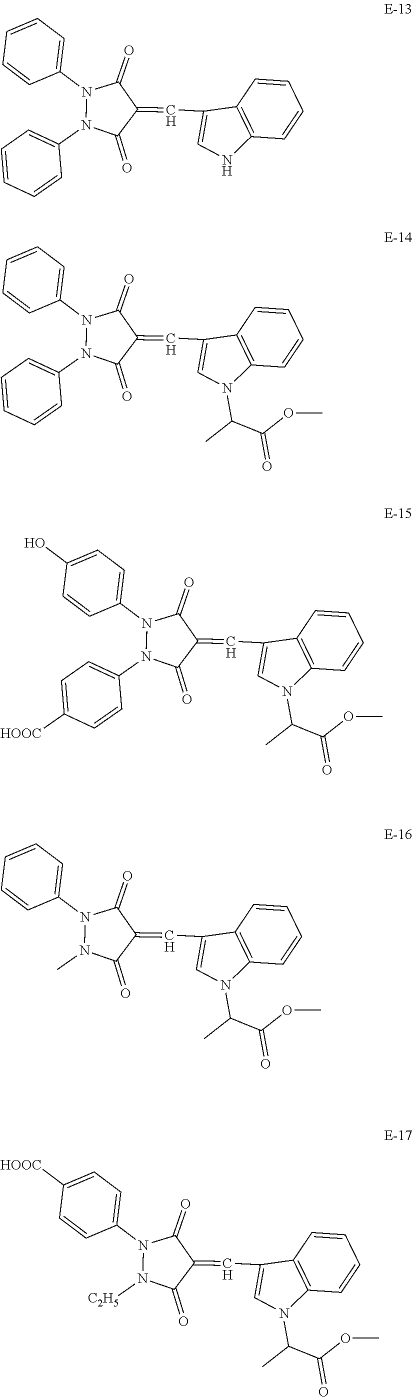 [SMILES: O=C1C(=Cc2c[nH]c3ccccc23)C(=O)N(c2ccccc2)N1c1ccccc1 ; COC(=O)C(C)n1cc(C=C2C(=O)N(c3ccccc3)N(c3ccccc3)C2=O)c2ccccc21 ; COC(=O)C(C)n1cc(C=C2C(=O)N(c3ccc(O)cc3)N(c3ccc(C(=O)O)cc3)C2=O)c2ccccc21 ; COC(=O)C(C)n1cc(C=C2C(=O)N(C)N(c3ccccc3)C2=O)c2ccccc21 ; CCN1C(=O)C(=Cc2cn(C(C)C(=O)OC)c3ccccc23)C(=O)N1c1ccc(C(=O)O)cc1]

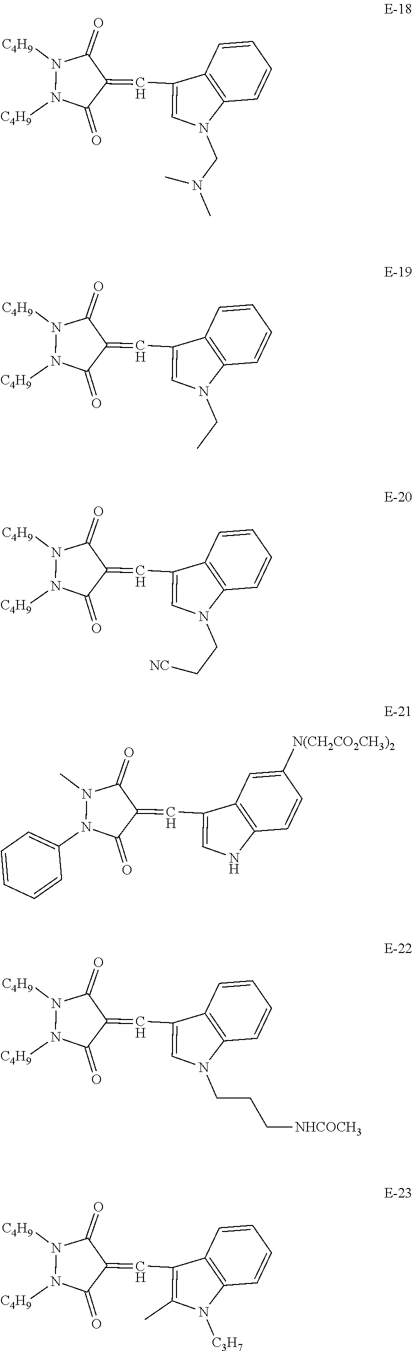

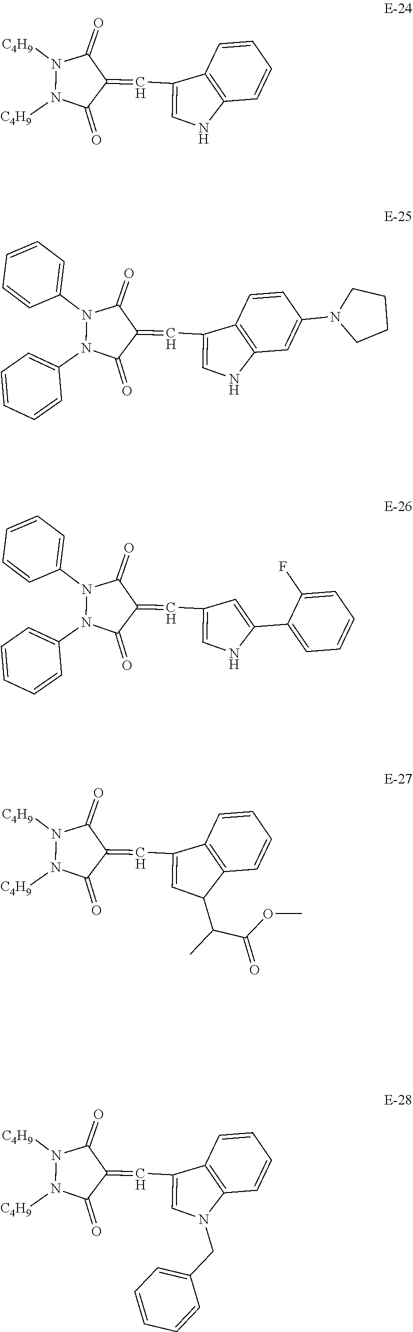

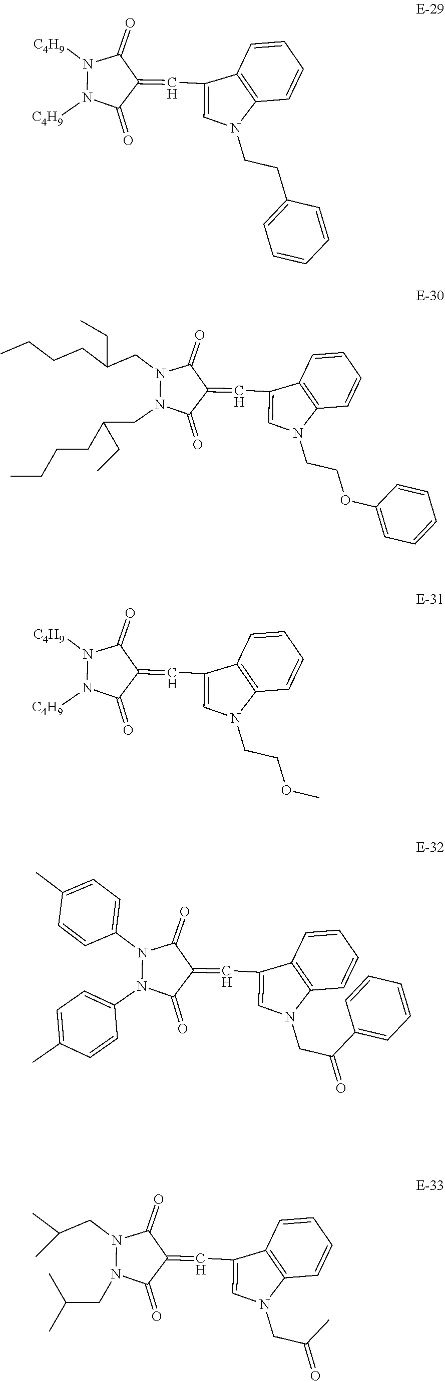

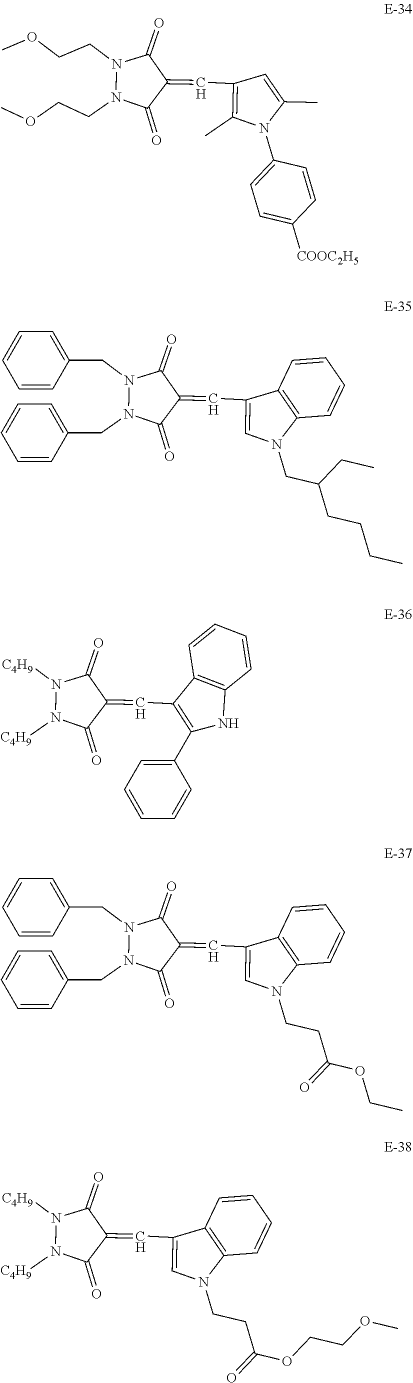

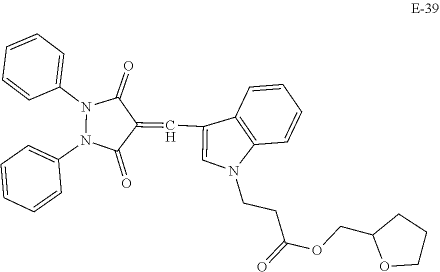 [SMILES: O=C(CCn1cc(C=C2C(=O)N(c3ccccc3)N(c3ccccc3)C2=O)c2ccccc21)OCC1CCCO1]

As the dye A, in addition to the coloring agent represented by General Formula (A1), the compounds described in paragraphs [0012] to [0067] of JP1993-53241A (JP-H5-53241A) and the compounds described in paragraphs [0011] to [0076] of JP2707371B can also be preferably used.

(Dye B and Dye C)

The dye B is not particularly limited as long as it has a main absorption wavelength band in a wavelength of 500 to 520 nm in the wavelength selective absorption filter, and various dyes can be used, where it is preferably a dye having a main absorption wavelength band in a wavelength of 500 to 515 nm in the wavelength selective absorption filter.

In addition, the dye C is not particularly limited as long as it has a main absorption wavelength band in a wavelength of 580 to 620 nm in the wavelength selective absorption filter, and various dyes can be used, where it is preferably a dye having a main absorption wavelength band in a wavelength of 580 to 610 nm in the wavelength selective absorption filter and more preferably a dye having a main absorption wavelength band in a wavelength of 585 to 605 nm in the wavelength selective absorption filter.

Specific examples of the dye B include individual coloring agents (dyes) which are based on, for example, pyrrole methine (PM), rhodamine (RH), boron dipyrromethene (BODIPY), and squarine (SQ).

Specific examples of the dye C include individual coloring agents (dyes) which are based on, for example, tetraazaporphyrin (TAP), squarine, and cyanine (CY).

Among these, the dye B and the dye C are preferably a squarine-based coloring agent, and more preferably a squarine-based coloring agent represented by General Formula (1) in that the absorption waveform in the main absorption wavelength band is sharp. In a case where a coloring agent having a sharp absorption waveform as described above is used as the dye B and the dye C, Relational Expression (I) can be satisfied at a preferred level, it is possible to achieve both reduction of reflectivity and suppression of a decrease in brightness at a more preferred level while suppressing a change in the tint of the reflected light.

That is, in the wavelength selective absorption layer, from the viewpoint of suppressing a change in tint, it is preferable that at least one of the dye B or the dye C is a squarine-based coloring agent (preferably, a squarine-based coloring agent represented by General Formula (1)), and it is more preferable that both the dye B and the dye C are a squarine-based coloring agent (preferably, a squarine-based coloring agent represented by General Formula (1)).

In the present invention, in the coloring agent represented by each General Formula, a cation is present in a delocalized manner, and thus a plurality of tautomer structures are present. Therefore, in the present invention, in a case where at least one tautomer structure of a certain coloring agent matches with each general formula, the certain coloring agent shall be a coloring agent represented by the general formula. Therefore, a coloring agent represented by a specific general formula can also be said to be a coloring agent having at least one tautomer structure that can be represented by the specific general formula. In the present invention, a coloring agent represented by a general formula may have any tautomer structure as long as at least one tautomer structure of the coloring agent matches with the general formula.

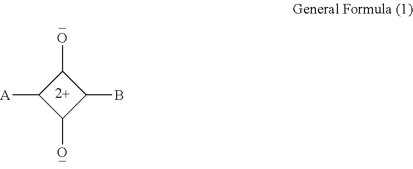

In General Formula (1), A and B each independently represent an aryl group which may have a substituent, a heterocyclic group which may have a substituent, or —CH=G. Here, G represents a heterocyclic group which may have a substituent.

The aryl group that can be employed as A or B is not particularly limited and may be a group consisting of a monocyclic ring or a group consisting of a fused ring. The aryl group preferably has 6 to 30 carbon atoms, more preferably 6 to 20 carbon atoms, and still more preferably 6 to 12 carbon atoms. Examples of the aryl group include groups respectively consisting of a benzene ring and a naphthalene ring, and a group consisting of a benzene ring is more preferable.

The heterocyclic group that can be employed as A or B is not particularly limited, and examples thereof include a group consisting of an aliphatic heterocyclic ring or an aromatic heterocyclic ring. A group consisting of an aromatic heterocyclic ring is preferable. Examples of the heteroaryl group that is an aromatic heterocyclic group include a heteroaryl group that can be employed as a substituent X described below. The aromatic heterocyclic group that can be employed as A or B is preferably a group of a 5-membered ring or a 6-membered ring and more preferably a group of a nitrogen-containing 5-membered ring. Specific examples thereof suitably include a group consisting of any one of a pyrrole ring, a furan ring, a thiophene ring, an imidazole ring, a pyrazole ring, a thiazole ring, an oxazole ring, a triazole ring, an indole ring, an indolenine ring, an indoline ring, a pyridine ring, a pyrimidine ring, a quinoline ring, a benzothiazole ring, a benzoxazole ring, or a pyrazolotriazole ring. Among these, a group consisting of any one of a pyrrole ring, a pyrazole ring, a thiazole ring, a pyridine ring, a pyrimidine ring, or a pyrazolotriazole ring is preferable. The pyrazolotriazole ring consists of a fused ring of a pyrazole ring and a triazole ring and may be a fused ring obtained by fusing at least one pyrazole ring and at least one triazole ring. Examples thereof include fused rings in General Formulae (4) and (5) described below.

A and B may be bonded to a squaric acid moiety (the 4-membered ring represented by General Formula (1)) at any moiety (ring-constituting atom) without particular limitation and is preferable to be bonded to a carbon atom.

G in —CH=G that can be employed as A or B represents a heterocyclic group which may have a substituent, and examples thereof suitably include examples shown in the heterocyclic group that can be employed as A or B. Among these, a group consisting of any one of a benzoxazole ring, a benzothiazole ring, an indoline ring, or the like is preferable.

At least one of A or B may have a hydrogen bonding group that forms an intramolecular hydrogen bond.

Each of A, B, and G may have the substituent X, and, in a case where A, B, or G has the substituent X, adjacent substituents may be bonded to each other to further form a ring structure. In addition, a plurality of substituents X may be present. In a case where adjacent substituents X are bonded to each other to further form a ring structure, the two substituents X may form a ring by interposing a heteroatom such as a boron atom therebetween. The boron atom may be further substituted with a substituent, and examples of the substituent include substituents such as an alkyl group and an aryl group. Examples of a ring formed by bonding the following two substituents X include a ring formed by bonding two —NR⁴R¹⁵ and a ring formed by bonding the following to two —NR⁴R¹⁵'s by interposing a boron atom therebetween.

Examples of the substituent X include substituents that can be employed as R¹ in General Formula (2) described below. Specific examples thereof include a halogen atom, a cyano group, a nitro group, an alkyl group (including a cycloalkyl group), an alkenyl group, an alkynyl group, an aryl group, a heteroaryl group, an aralkyl group, and a ferrocenyl group, —OR¹⁰, —C(═O)R¹¹, —C(═O)OR¹², —OC(═O)R¹³, —NR¹⁴R¹⁵, —NHCOR¹⁶, —CONR¹⁷R¹⁸, —NHCONR¹⁹R²⁰, —NHCOOR²¹, —SR²², —SO₂R²³, —SO₃R²⁴, —NHSO₂R²⁵, and SO₂NR²⁶R²⁷. Further, it is also preferable that the substituent X has a quencher moiety described later, in addition to the ferrocenyl group.

In General Formula (1), R¹⁰ to R²⁷ each independently represent a hydrogen atom, an aliphatic group, an aromatic group, or a heterocyclic group. The aliphatic group and the aromatic group that can be employed as R¹⁰ to R²⁷ are not particularly limited, and appropriately selected from an alkyl group, a cycloalkyl group, an alkenyl group, and an alkynyl group which are classified as aliphatic groups, and an aryl group which is classified as an aromatic group, in the substituent that can be employed as R¹ in General Formula (2) described later. The heterocyclic group that can be employed as R¹⁰ to R²⁷ may be aliphatic or aromatic, and it can be appropriately selected from heteroaryl groups or heterocyclic groups that can be employed as R¹ in General Formula (2) described below.

It is noted that in a case where R¹² of —COOR¹² is a hydrogen atom (that is, a carboxy group), the hydrogen atom may be dissociated (that is, a carbonate group) or may be in a salt state. In addition, in a case where R²⁴ of —SO₃R²⁴ is a hydrogen atom (that is, a sulfo group), the hydrogen atom may be dissociated (that is, a sulfonate group) or may be in a salt state.

Examples of the halogen atom that can be employed as the substituent X include a fluorine atom, a chlorine atom, a bromine atom, and an iodine atom.

The alkyl group that can be employed as the substituent X preferably has 1 to 20 carbon atoms, more preferably 1 to 15 carbon atoms, and still more preferably 1 to 8 carbon atoms. The alkenyl group preferably has 2 to 20 carbon atoms, more preferably 2 to 12 carbon atoms, and still more preferably 2 to 8 carbon atoms. The alkynyl group preferably has 2 to 40 carbon atoms, more preferably 2 to 30 carbon atoms, and particularly preferably 2 to 25 carbon atoms. The alkyl group, the alkenyl group, and the alkynyl group each may be linear, branched, or cyclic, and they are preferably linear or branched.

The aryl group that can be employed as the substituent X includes a monocyclic group or a fused ring group. The aryl group preferably has 6 to 30 carbon atoms, more preferably 6 to 20 carbon atoms, and still more preferably 6 to 12 carbon atoms.

An alkyl portion in the aralkyl group that can be employed as the substituent X is the same as that in the alkyl group. An aryl portion in the aralkyl group is the same as that in the aryl group. The aralkyl group preferably has 7 to 40 carbon atoms, more preferably 7 to 30 carbon atoms, and still more preferably 7 to 25 carbon atoms.

The heteroaryl group that can be employed as the substituent X includes a group consisting of a monocyclic ring or a fused ring, a group consisting of a monocyclic ring or a fused ring having 2 to 8 rings is preferable, and a group consisting of a monocyclic ring or a fused ring having 2 to 4 rings is more preferable. The number of heteroatoms constituting the ring of the heteroaryl group is preferably 1 to 3. Examples of the heteroatom constituting the ring of the heteroaryl group include a nitrogen atom, an oxygen atom, and a sulfur atom. The heteroaryl group is preferably a group consisting of a 5-membered ring or a 6-membered ring. The number of carbon atoms constituting the ring in the heteroaryl group is preferably 3 to 30, more preferably 3 to 18, and more preferably 3 to 12. Examples of the heteroaryl group include each group consisting of any one of a pyridine ring, a piperidine ring, a furan ring, a furfuran ring, a thiophene ring, a pyrrole ring, a quinoline ring, a morpholine ring, an indole ring, an imidazole ring, a pyrazole ring, a carbazole ring, a phenothiazine ring, a phenoxazine ring, an indoline ring, a thiazole ring, a pyrazine ring, a thiadiazine ring, a benzoquinoline ring, or a thiadiazole ring.

The ferrocenyl group that can be employed as the substituent X is preferably represented by General Formula (2M).

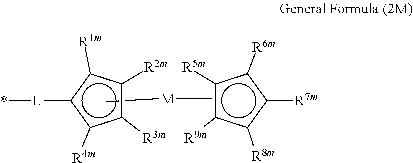

In General Formula (2M), L represents a single bond or a divalent linking group that does not conjugate with A, B, or G in General Formula (1). R^{1m} to R^{9m} each independently represent a hydrogen atom or a substituent. M represents an atom that can constitute a metallocene compound and represents Fe, Co, Ni, Ti, Cu, Zn, Zr, Cr, Mo, Os, Mn, Ru, Sn, Pd, Rh, V, or Pt. * represents a bonding site to A, B, or G.

In the present invention, in a case where L in General Formula (2M) is a single bond, a cyclopentadienyl ring directly bonded to A, B, or G (a ring having R^{1m} in General Formula (2M)) is not included in the conjugated structure which conjugates with A, B, or G.

The divalent linking group that can be employed as L is not particularly limited as long as it is a linking group that does not conjugate with A, B, or G, and it may have a conjugated structure in the inside thereof or at a cyclopentadiene ring side end part in General Formula (2M). Examples of the divalent linking group include an alkylene group having 1 to 20 carbon atoms, an arylene group having 6 to 20 carbon atoms, a divalent heterocyclic group obtained by removing two hydrogens from the heterocyclic ring, —CH═CH—, —CO—, —CS—, —NR—(R represents a hydrogen atom or a monovalent substituent), —O—, —S—, —SO₂—, or —N═CH—, or a divalent linking group formed by combining a plurality (preferably, 2 to 6) of these groups. The divalent linking group is preferably a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a divalent linking group in which two or more (preferably 2 to 6) selected from the above group are combined, and it is particularly preferably a group selected from the group consisting of an alkylene group having 1 to 4 carbon atoms, a phenylene group, —CO—, —NH—, —O—, and —SO₂—, or a linking group in which two or more (preferably 2 to 6) selected from the above group are combined. The divalent linking group combined is not particularly limited, and it is preferably a group containing —CO—, —NH—, —O—, or —SO₂—, and examples thereof include a linking group formed by combining two or more of —CO—, —NH—, —O—, or —SO₂—, or a linking group formed by combining at least one of —CO—, —NH—, —O—, or —SO₂— and an alkylene group or an arylene group. Examples of the linking group formed by combining two or more of —CO—, —NH—, —O—, or —SO₂— include —COO—, —OCO—, —CONH—, —NHCOO—, —NHCONH—, and —SO₂NH—. Examples of the linking group formed by combining at least one of —CO—, —NH—, —O—, or —SO₂— and an alkylene group or an arylene group include a group in which —CO—, —COO—, or —CONH— and an alkylene group or an arylene group are combined. The substituent that can be employed as R is not particularly limited, and it has the same meaning as the substituent X which may be contained in A in General Formula (2).

L is preferably a single bond or a group selected from the group consisting of an alkylene group having 1 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined.

L may have one or a plurality of substituents. The substituent which may be contained in L is not particularly limited, and for example, it has the same meaning as the substituent X. In a case where L has a plurality of substituents, the substituents bonded to adjacent atoms may be bonded to each other to further form a ring structure.

The alkylene group that can be employed as L may be linear, branched, or cyclic as long as the group has 1 to 20 carbon atoms, and examples thereof include methylene, ethylene, propylene, methylethylene, methylmethylene, dimethylmethylene, 1,1-dimethylethylene, butylene, 1-methylpropylene, 2-methylpropylene, 1,2-dimethylpropylene, 1,3-dimethylpropylene, 1-methylbutylene, 2-methylbutylene, 3-methylbutylene, 4-methylbutylene, 2,4-dimethylbutylene, 1,3-dimethylbutylene, pentylene, hexylene, heptylene, octylene, ethane-1,1-diyl, propane-2,2-diyl, cyclopropane-1,1-diyl, cyclopropane-1,2-diyl, cyclobutane-1,1-diyl, cyclobutane-1,2-diyl, cyclopentane-1,1-diyl, cyclopentane-1,2-diyl, cyclopentane-1,3-diyl, cyclohexane-1,1-diyl, cyclohexane-1,2-diyl, cyclohexane-1,3-diyl, cyclohexane-1,4-diyl, and methylcyclohexane-1,4-diyl.

In a case where a linking group containing at least one of —CO—, —CS—, —NR— (R is as described above), —O—, —S—, —SO₂—, or —N═CH— in the alkylene group is employed as L, the group such as —CO— may be incorporated at any site in the alkylene group, and the number of the groups incorporated is not particularly limited.

The arylene group that can be employed as L is not particularly limited as long as the group has 6 to 20 carbon atoms, and examples thereof include a group obtained by further removing one hydrogen atom from each group exemplified as the aryl group having 6 to 20 carbon atoms that can be employed as A in General Formula (1).

The heterocyclic group that can be employed as L is not particularly limited, and examples thereof include a group obtained by further removing one hydrogen atom from each group exemplified as the heterocyclic group that can be employed as A.

In General Formula (2M), the remaining partial structure excluding the linking group L corresponds to a structure (a metallocene structure portion) in which one hydrogen atom is removed from the metallocene compound. In the present invention, for the metallocene compound serving as the metallocene structure portion, a known metallocene compound can be used without particular limitation, as long as it is a compound conforming to the partial structure defined by General Formula (2M) (a compound in which a hydrogen atom is bonded instead of L). Hereinafter, the metallocene structure portion defined by General Formula (2M) will be specifically described.

In General Formula (2M), R^{1m} to R^{9m} each independently represent a hydrogen atom or a substituent. The substituents that can be employed as R^{1m} to R^{9m} are not particularly limited, and can be selected from, for example, the substituents that can be employed as R¹ in General Formula (3). R^{1m} to R^{9m} each are preferably a hydrogen atom, a halogen atom, an alkyl group, an acyl group, an alkoxy group, an amino group, or an amide group, more preferably a hydrogen atom, a halogen atom, an alkyl group, an acyl group, or an alkoxy group, still more preferably a hydrogen atom, a halogen atom, an alkyl group, or an acyl group, particularly preferably a hydrogen atom, a halogen atom, or an alkyl group, and most preferably a hydrogen atom.

As the alkyl group that can be employed as R^{1m} to R^{9m}, among the alkyl groups that can be employed as R¹, an alkyl group having 1 to 8 carbon atoms is preferable, and examples thereof include methyl, ethyl, propyl, isopropyl, butyl, sec-butyl, tert-butyl, isobutyl, pentyl, tert-pentyl, hexyl, octyl, and 2-ethylhexyl.

This alkyl group may have a halogen atom as a substituent. Examples of the alkyl group substituted with a halogen atom include, for example, chloromethyl, dichloromethyl, trichloromethyl, bromomethyl, dibromomethyl, tribromomethyl, fluoromethyl, difluoromethyl, trifluoromethyl, 2,2,2-trifluoroethyl, perfluoroethyl, perfluoropropyl, perfluorobutyl.

In addition, in the alkyl group that can be employed as R^{1m} or the like, at least one methylene group that forms a carbon chain may be substituted with —O— or —CO—. Examples of the alkyl group in which the methylene group is substituted with —O— include an alkyl group in which the end part methylene group of methoxy, ethoxy, propoxy, isopropoxy, butoxy, sec-butoxy, tert-butoxy, 2-methoxyethoxy, chloromethyloxy, dichloromethyloxy, trichloromethyloxy, bromomethyloxy, dibromomethyloxy, tribromomethyloxy, fluoromethyloxy, difluoromethyloxy, trifluoromethyloxy, 2,2,2-trifluoroethyloxy, perfluoroethyloxy, perfluoropropyloxy, or perfluorobutyloxy is substituted, as well as an alkyl group in which an internal methylene group of the carbon chain such as 2-methoxyethyl or the like is substituted. Examples of the alkyl group in which a methylene group is substituted with —CO— include, for example, acetyl, propionyl, monochloroacetyl, dichloroacetyl, trichloroacetyl, trifluoroacetyl, propane-2-one-1-yl, butane-2-one-1-yl.

In General Formula (2M), M represents an atom that can constitute a metallocene compound, and represents Fe, Co, Ni, Ti, Cu, Zn, Zr, Cr, Mo, Os, Mn, Ru, Sn, Pd, Rh, V, or Pt. Among these, M is preferably Fe, Ti, Co, Ni, Zr, Ru, or Os, more preferably Fe, Ti, Ni, Ru, or Os, still more preferably Fe or Ti, and most preferably Fe.

The group represented by General Formula (2M) is preferably a group formed by combining preferred ones of L, R^{1m} to R^{9m}, and M. Examples thereof include a group formed by combining, as L, a single bond, or a group selected from the group consisting of an alkylene group having 2 to 8 carbon atoms, an arylene group having 6 to 12 carbon atoms, —CH═CH—, —CO—, —NR— (R is as described above), —O—, —S—, —SO₂—, and —N═CH—, or a group in which two or more selected from the above group are combined; as R^{1m} to R^{9m}, a hydrogen atom, a halogen atom, an alkyl group, an acyl group, or an alkoxy group; and as M, Fe.

The alkyl group, the alkenyl group, the alkynyl group, the aralkyl group, the aryl group, and the heteroaryl group which can be employed as the substituent X and the aliphatic group, the aromatic group, and the heterocyclic group which can be employed as R¹⁰ to R²⁷ each may further have a substituent or may be unsubstituted. The substituent which may be further contained therein is not particularly limited, and it is preferably a substituent selected from an alkyl group, an aryl group, an amino group, an alkoxy group, an aryloxy group, an aromatic heterocyclic oxy group, an acyl group, an alkoxycarbonyl group, an aryloxycarbonyl group, an acyloxy group, an acylamino group, an alkoxycarbonylamino group, an aryloxycarbonylamino group, a sulfonylamino group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group, and it is more preferably a substituent selected from an alkyl group, an aryl group, an alkoxy group, an aryloxy group, an aromatic heterocyclic oxy group, an acyl group, an alkoxycarbonyl group, an aryloxycarbonyl group, an acyloxy group, an alkylthio group, an arylthio group, an aromatic heterocyclic thio group, a sulfonyl group, a ferrocenyl group, a hydroxy group, a mercapto group, a halogen atom, a cyano group, a sulfo group, or a carboxy group. This groups can be appropriately selected from the substituents that can be employed as R¹ in General Formula (2) described below.

One preferred embodiment of the coloring agent represented by General Formula (1) includes a coloring agent represented by General Formula (2).

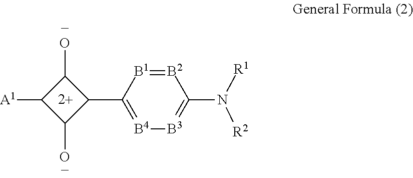

In General Formula (2), A¹ is the same as A in General Formula (1). Among these, a heterocyclic group which is a nitrogen-containing 5-membered ring is preferable.

In General Formula (2), R¹ and R² each independently represent a hydrogen atom or a substituent. R¹ and R² may be the same as or different from each other, and may be bonded to each other to form a ring.

The substituents that can be employed as R¹ and R² are not particularly limited, and examples thereof include an alkyl group (a methyl group, an ethyl group, a propyl group, an isopropyl group, a butyl group, a t-butyl group, an isobutyl group, a pentyl group, a hexyl group, an octyl group, a dodecyl group, a trifluoromethyl group, or the like), a cycloalkyl group (a cyclopentyl group, a cyclohexyl group, or the like), an alkenyl group (a vinyl group, an allyl group, or the like), an alkynyl group (an ethynyl group, a propargyl group, or the like), an aryl group (a phenyl group, a naphthyl group, or the like), a heteroaryl group (a furyl group, a thienyl group, a pyridyl group, a pyridazyl group, a pyrimidyl group, a pyrazyl group, a triazyl group, an imidazolyl group, a pyrazolyl group, a thiazolyl group, a benzoimidazolyl group, a benzoxazolyl group, a quinazolyl group, a phthalazyl group, or the like), a heterocyclic group (for example, a pyrrolidyl group, an imidazolidyl group, a morpholyl group, an oxazolidyl group, or the like), an alkoxy group (a methoxy group, an ethoxy group, a propyloxy group, or the like), a cycloalkoxy group (a cyclopentyloxy group, a cyclohexyloxy group, or the like), an aryloxy group (a phenoxy group, a naphthyloxy group, or the like), a heteroaryloxy group (an aromatic heterocyclic oxy group), an alkylthio a group (a methylthio group, an ethylthio group, a propylthio group, or the like), a cycloalkylthio group (a cyclopentylthio group, a cyclohexylthio group, or the like), an arylthio group (a phenylthio group, a naphthylthio group, or the like), a heteroarylthio group (an aromatic heterocyclic thio group), an alkoxycarbonyl group (a methyloxycarbonyl group, an ethyloxycarbonyl group, a butyloxycarbonyl group, an octyloxycarbonyl group, or the like), an aryloxycarbonyl group (a phenyloxycarbonyl group, a naphthyloxycarbonyl group, or the like), a phosphoryl group (dimethoxyphosphonyl or diphenylphosphoryl), a sulfamoyl a group (an aminosulfonyl group, a methylaminosulfonyl group, a dimethylaminosulfonyl group, a butylaminosulfonyl group, a cyclohexylaminosulfonyl group, an octylaminosulfonyl group, a phenylaminosulfonyl group, a 2-pyridylaminosulfonyl group, or the like), an ancyl a group (an acetyl group, an ethylcarbonyl group, a propylcarbonyl group, a cyclohexylcarbonyl group, an octylcarbonyl group, a 2-ethylhexylcarbonyl group, a phenylcarbonyl group, a naphthylcarbonyl group, a pyridylcarbonyl group, or the like), an acyloxy group (an acetyloxy group, an ethylcarbonyloxy group, a butylcarbonyloxy group, an octylcarbonyloxy group, a phenylcarbonyloxy group, or the like), an amide group (a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, a naphthylcarbonylamino group, or the like), a sulfonylamide group (a methylsulfonylamino group, an octylsulfonylamino group, a 2-ethylhexylsulfonylamino group, a trifluoromethylsulfonylamino group, or the like), a carbamoyl group (an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, a 2-pyridylaminocarbonyl group, or the like), a ureide group (a methylureide group, an ethylureide group, a pentylureide group, a cyclohexylureide group, an octylureide group, a dodecylureide group, a phenylureide group, a naphthylureide group, a 2-pyridylaminoureide group, or the like), an alkylsulfonyl group (a methylsulfonyl group, an ethylsulfonyl group, a butylsulfonyl group, a cyclohexylsulfonyl group, a 2-ethylhexylsulfonyl group, or the like), an arylsulfonyl group (a phenylsulfonyl group, a naphthylsulfonyl group, a 2-pyridylsulfonyl group, or the like), an amino group (an amino group, an ethylamino group, a dimethylamino group, a butylamino group, a dibutylamino group, a cyclopentylamino group, a 2-ethylhexylamino group, a dodecylamino group, an anilino group, a naphthylamino group, a 2-pyridylamino group, or the like), an alkylsulfonyloxy group (methanesulfonyloxy), a cyano group, a nitro group, halogen atoms (a fluorine atom, a chlorine atom, a bromine atom, or the like), and a hydroxy group.

Among these, an alkyl group, an alkenyl group, an aryl group, or a heteroaryl group is preferable, an alkyl group, an aryl group, or a heteroaryl group is more preferable, and an alkyl group is still more preferable.

The substituent that can be employed as R¹ and R² may further have a substituent. Examples of the substituent which may be further contained therein include the substituent that can be employed as R¹ and R², and the substituent X which may be contained in A, B, and G in General Formula described above. In addition, R¹ and R² may be bonded to each other to form a ring, and R¹ or R² and the substituent of B² or B³ may be bonded to each other to form a ring.

The ring that is formed in this case is preferably a heterocyclic ring or a heteroaryl ring, and it is preferably a 5-membered ring or a 6-membered ring although the size of the ring to be formed is not particularly limited. Further, the number of rings to be formed is not particularly limited, and it may be one or two or more. Examples of the form in which two or more rings are formed include a form in which the substituents of R¹ and B² and the substituents of R² and B³ are respectively bonded to each other to form two rings.

In General Formula (2), B¹, B², B³, and B⁴ each independently represent a carbon atom or a nitrogen atom. The ring including B¹, B², B³, and B⁴ is an aromatic ring. It is preferable that at least two or more of B¹ to B⁴ are a carbon atom, and it is more preferable that all of B¹ to B⁴ are a carbon atom.

The carbon atom that can be employed as B¹ to B⁴ has a hydrogen atom or a substituent. Among carbon atoms that can be employed as B¹ to B⁴, the number of carbon atoms having a substituent is not particularly limited; however, it is preferably zero, one, or two, and more preferably one. Particularly, it is preferable that B¹ and B⁴ are a carbon atom and at least one of them has a substituent.

The substituent possessed by the carbon atom that can be employed as B¹ to B⁴ is not particularly limited, and examples thereof include the above-described substituents that can be employed as R¹ and R². Among these, it is preferably an alkyl group, an alkoxy group, an alkoxycarbonyl group, an aryl group, an acyl group, an amide group, a sulfonylamide group, a carbamoyl group, an alkylsulfonyl group, an arylsulfonyl group, an amino group, a cyano group, a nitro group, a halogen atom, or a hydroxy group, and it is more preferably an alkyl group, an alkoxy group, an alkoxycarbonyl group, an aryl group, an acyl group, an amide group, a sulfonylamide group, a carbamoyl group, an amino group, a cyano group, a nitro group, a halogen atom, or a hydroxy group.

The substituent possessed by the carbon atom that can be employed as B¹ to B⁴ may further have a substituent. The substituents that may be further possessed include the substituents that may be contained in R¹ and R² in General Formula (2), and the substituent X which may be contained in A, B, and G in General Formula (1).

Examples of the substituent that can be possessed by the carbon atom that can be employed as B¹ and B⁴ still more preferably include an alkyl group, an alkoxy group, a hydroxy group, an amide group, a sulfonylamide group, or a carbamoyl group, and particularly preferably an alkyl group, an alkoxy group, a hydroxy group, an amide group, or a sulfonylamide group, and a hydroxy group, an amide group, or a sulfonylamide group is most preferable.

It is still more preferable that the substituent that can be possessed by the carbon atom that can be employed as B² and B³ is an alkyl group, an alkoxy group, an alkoxycarbonyl group, an acyl group, an amino group, a cyano group, a nitro group, or a halogen atom, and it is particularly preferable that the substituent as any one of B² or B³ is an electron withdrawing group (for example, an alkoxycarbonyl group, an acyl group, a cyano group, a nitro group, or a halogen atom).

The coloring agent represented by General Formula (2) is preferably a coloring agent represented by any one of General Formulae (3), (4), or (5).

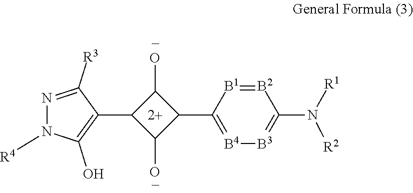

In General Formula (3), R¹ and R² each independently represent a hydrogen atom or a substituent, and they respectively have the same meanings as R¹ and R² in General Formula (2), where the same applies to the preferred ranges thereof.

In General Formula (3), B¹ to B⁴ each independently represent a carbon atom or a nitrogen atom, and they have respectively the same meanings as B¹ to B⁴ in General Formula (2), where the same applies to the preferred ranges thereof.

In General Formula (3), R³ and R⁴ each independently represent a hydrogen atom or a substituent. The substituent that can be employed as R³ and R⁴ is not particularly limited, and examples thereof include the same ones as the substituents that can be employed as R¹ and R².

However, the substituent that can be employed as R³ is preferably an alkyl group, an alkoxy group, an amino group, an amide group, a sulfonylamide group, a cyano group, a nitro group, an aryl group, a heteroaryl group, a heterocyclic group, an alkoxycarbonyl group, a carbamoyl group, or a halogen atom, more preferably an alkyl group, an aryl group, or an amino group, and still more preferably an alkyl group.

The substituent that can be employed as R⁴ is preferably an alkyl group, an aryl group, a heteroaryl group, a heterocyclic group, an alkoxy group, an alkoxycarbonyl group, an acyl group, an acyloxy group, an amide group, a carbamoyl group, an amino group, or a cyano group, more preferably an alkyl group, an alkoxycarbonyl group, an acyl group, a carbamoyl group, or an aryl group, and still more preferably an alkyl group.

The alkyl group that can be employed as R³ and R⁴ may be linear, branched, or cyclic, and it is preferably linear or branched. The alkyl group preferably has 1 to 12 carbon atoms and more preferably 1 to 8 carbon atoms. An example of the alkyl group is preferably a methyl group, an ethyl group, an n-propyl group, an isopropyl group, a tert-butyl group, a 2-ethylhexyl group, or a cyclohexyl group, and more preferably a methyl group or a tert-butyl group.

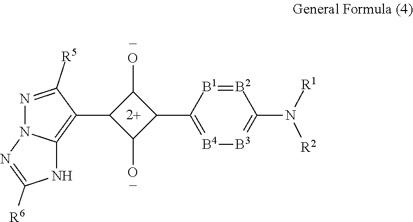

In General Formula (4), R¹ and R² each independently represent a hydrogen atom or a substituent, and they respectively have the same meanings as R¹ and R² in General Formula (2), where the same applies to the preferred ranges thereof.

In General Formula (4), B¹ to B⁴ each independently represent a carbon atom or a nitrogen atom, and they have respectively the same meanings as B¹ to B⁴ in General Formula (2), where the same applies to the preferred ranges thereof.

In General Formula (4), R⁵ and R⁶ each independently represent a hydrogen atom or a substituent. The substituent that can be employed as R⁵ and R⁶ is not particularly limited, and examples thereof include the same ones as the substituents that can be employed as R¹ and R².

However, the substituent that can be employed as R⁵ is preferably an alkyl group, an alkoxy group, an aryloxy group, an amino group, a cyano group, an aryl group, a heteroaryl group, a heterocyclic group, an acyl group, an acyloxy group, an amide group, a sulfonylamide group, an ureide group, or a carbamoyl group, more preferably an alkyl group, an alkoxy group, an acyl group, an amide group, or an amino group, and still more preferably an alkyl group.

The alkyl group that can be employed as R⁵ has the same meaning as the alkyl group that can be employed as R³ in General Formula (3), and the same applies to the preferred range thereof.

In General Formula (4), the substituent that can be employed as R⁶ is preferably an alkyl group, an alkenyl group, an aryl group, a heteroaryl group, a heterocyclic group, an alkoxy group, a cycloalkoxy group, an aryloxy group, an alkoxycarbonyl group, an acyl group, an acyloxy group, an amide group, a sulfonylamide group, an alkylsulfonyl group, an arylsulfonyl group, a carbamoyl group, an amino group, a cyano group, a nitro group, or a halogen atom, more preferably an alkyl group, an aryl group, a heteroaryl group, or a heterocyclic group, and still more preferably an alkyl group or an aryl group.

The alkyl group that can be employed as R⁶ has the same meaning as the alkyl group that can be employed as R⁴ in General Formula (3), and the same applies to the preferred range thereof.

The aryl group that can be employed as R⁶ is preferably an aryl group having 6 to 12 carbon atoms, and more preferably a phenyl group. This aryl group may have a substituent, examples of such substitution include a group included in the following substituent group A, and an alkyl group, a sulfonyl group, an amino group, an acylamino group, a sulfonylamino group, or the like, which have 1 to 10 carbon atoms, is particularly preferable. This substituent may further have a substituent. Specifically, the substituent is preferably an alkylsulfonylamino group.

-Substituent Group A-

A halogen atom, an alkyl group, an alkenyl group, an alkynyl group, an aryl group, a heterocyclic group, a cyano group, a hydroxy group, a nitro group, a carboxy group, an alkoxy group, an aminooxy group, an aryloxy group, a silyloxy group, a heterocyclic oxy group, an acyloxy group, a carbamoyloxy group, an amino group, an acylamino group, an aminocarbonylamino group, an alkoxycarbonylamino group, an aryloxycarbonylamino group, a sulfamoylamino group, a sulfonylamino group (including an alkyl or arylsulfonylamino group), a mercapto group, an alkylthio group, an arylthio group, a heterocyclic thio group, a sulfamoyl group, a sulfo group, an alkyl or arylsulfonyl group, a sulfonyl group (including an alkyl or arylsulfinyl group), an acyl group, an aryloxycarbonyl group, an alkoxycarbonyl group, a carbamoyl group, an aryl or heterocyclic azo group, an imide group, a phosphino group, a phosphinyl group, a phosphinyloxy group, a phosphinylamino group, a silyl group, and the like.

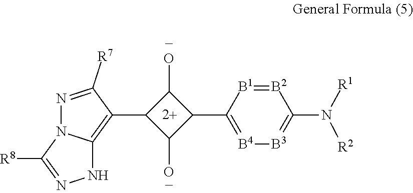

In General Formula (5), R¹ and R² each independently represent a hydrogen atom or a substituent, and they respectively have the same meanings as R¹ and R² in General Formula (2), where the same applies to the preferred ranges thereof.

In General Formula (5), B¹ to B⁴ each independently represent a carbon atom or a nitrogen atom, and they have respectively the same meanings as B¹ to B⁴ in General Formula (2), where the same applies to the preferred ranges thereof.

In General Formula (5), R⁷ and R⁸ each independently represent a hydrogen atom or a substituent. The substituent that can be employed as R⁷ and R⁸ is not particularly limited, and examples thereof include the same ones as the substituents that can be employed as R¹ and R². However, the preferred range, the more preferred range, and the still more preferred range of the substituent that can be employed as R⁷ are the same as those of the substituent that can be employed as R⁵ in General Formula (4). The alkyl group that can be employed as R⁵ has the same meaning as the alkyl group that can be employed as R³, and the same applies to the preferred range thereof.

In General Formula (5), the preferred range, the more preferred range, and the still more preferred range of the substituent that can be employed as R⁸ are the same as those of the substituent that can be employed as R⁶ in General Formula (4). The preferred ranges of the alkyl group and the aryl group that can be employed as R⁸ have the same meaning as the alkyl group and the aryl group that can be employed as R⁶ in General Formula (4), where the same applies to the preferred ranges thereof.

In the present invention, in a case where a squarine-based coloring agent is used as the dye C, any squarine-based coloring agent may be used without particular limitations as long as the squarine-based coloring agent is the squarine coloring agent represented by any one of General Formulae (1) to (5). Examples thereof include compounds described in, for example, JP2006-160618A, WO2004/005981A, WO2004/007447A, Dyes and Pigment, 2001, 49, p. 161 to 179, WO2008/090757A, WO2005/121098A, and JP2008-275726A.

Hereinafter, specific examples of the coloring agent represented by any one of General Formula (1) to General Formula (5) will be shown. However, the present invention is not limited thereto.

In the following specific examples, Me represents methyl, Et represents ethyl, Bu represents butyl, and Ph represents phenyl, respectively.

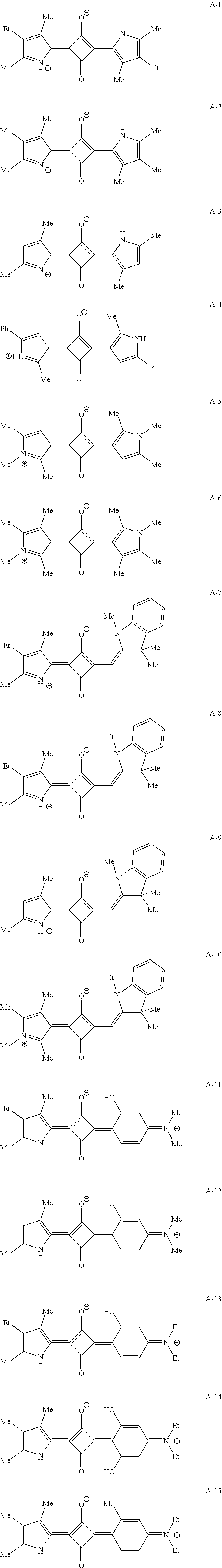

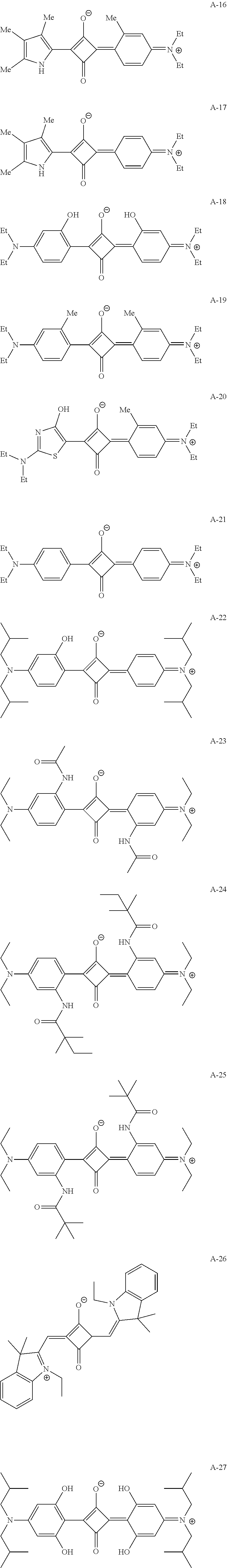

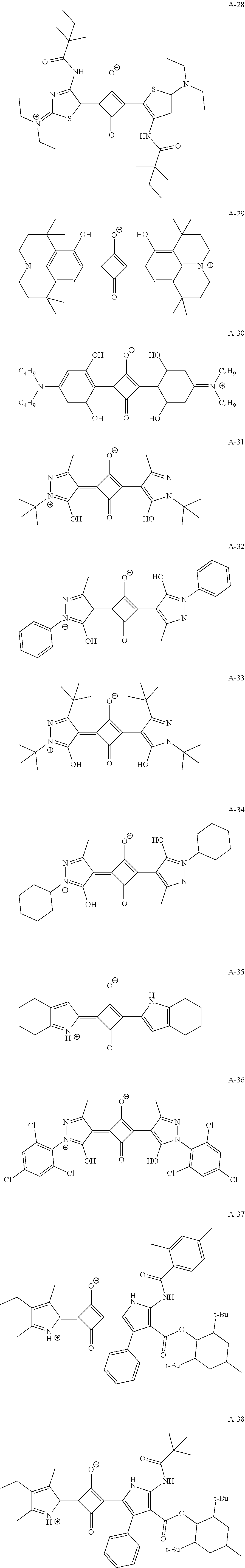

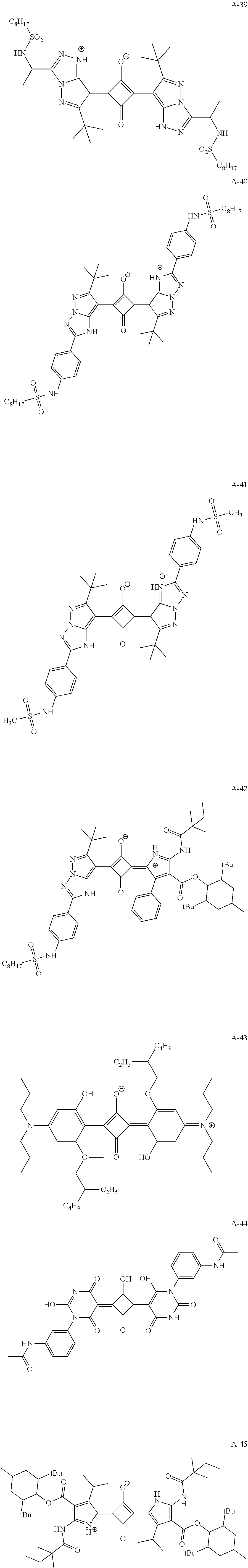

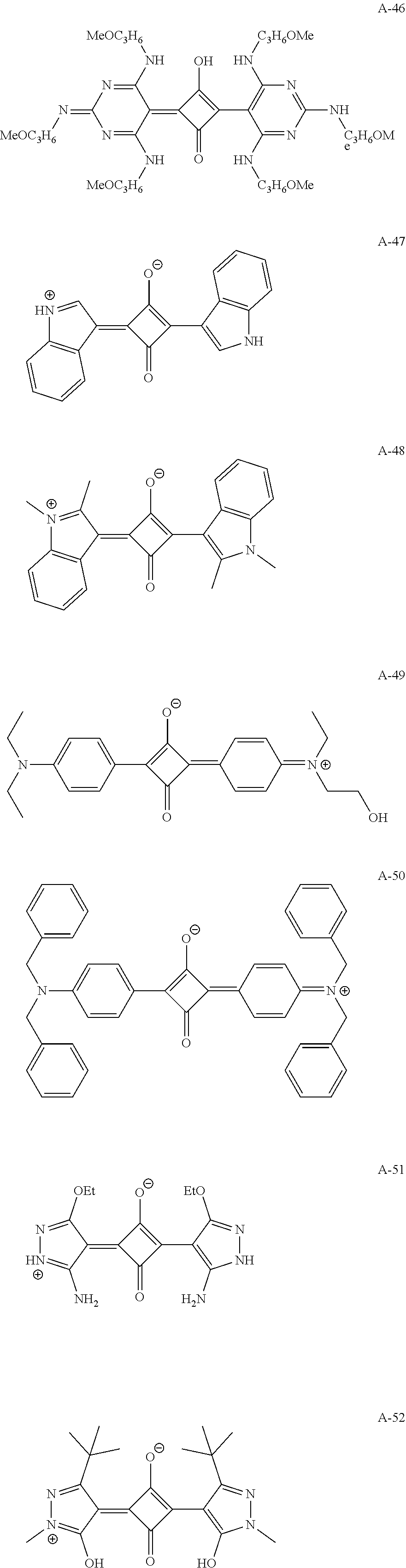

In addition to the above-described specific examples, specific examples of the coloring agents represented by any one of General Formulae (3) to (5) will be shown. The substituent B in the following tables represents the following structures. In the following structures and the following tables, Me represents methyl, Et represents ethyl, i-Pr represents i-propyl, Bu represents n-butyl, t-Bu represents t-butyl, and Ph represents phenyl, respectively. In the following structures, * indicates a bonding site to a 4-membered carbon ring in each General Formula.

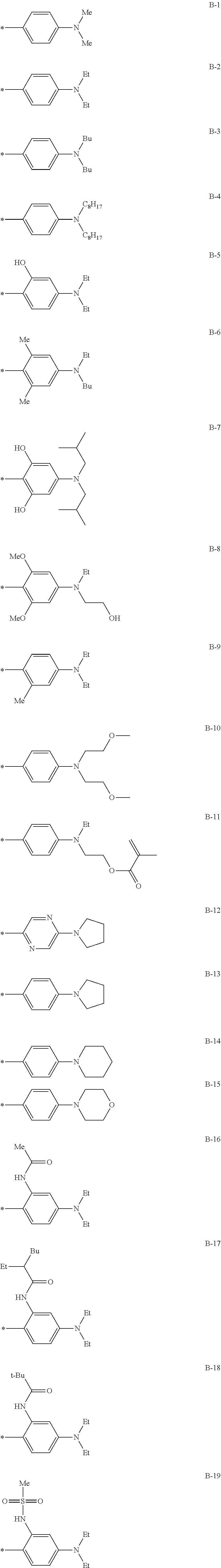

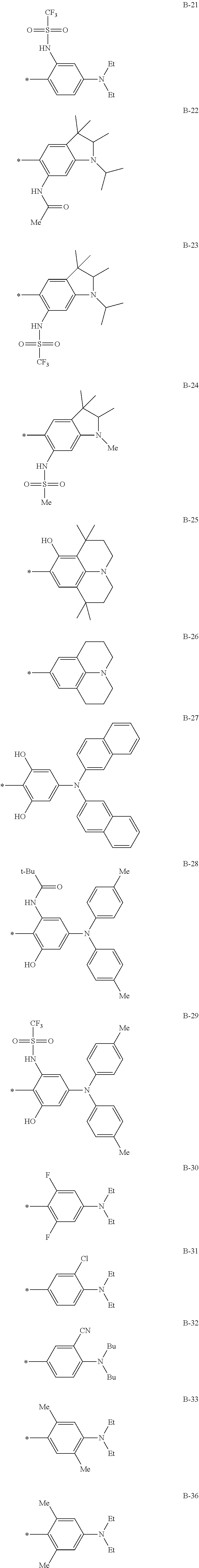

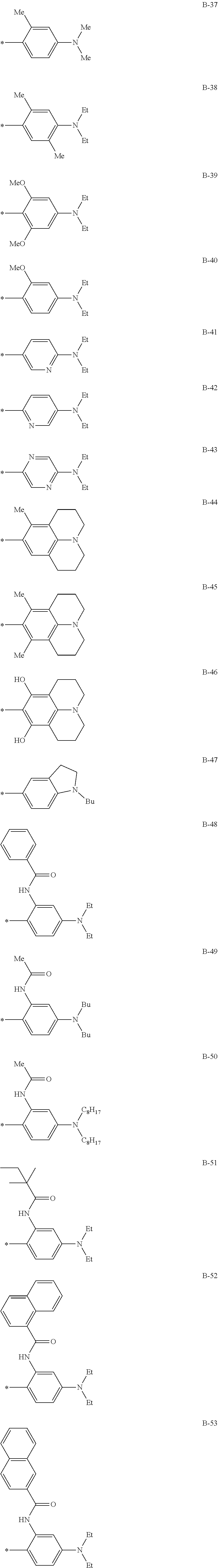

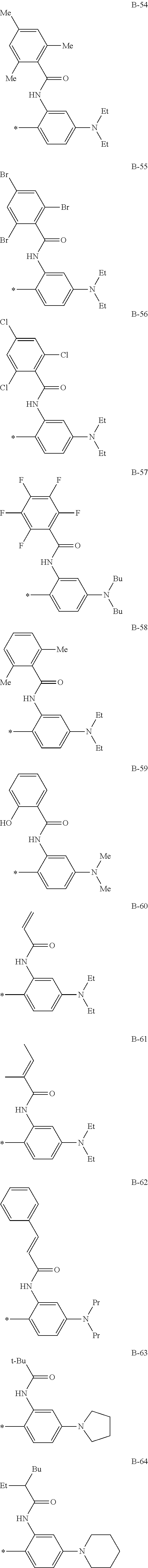

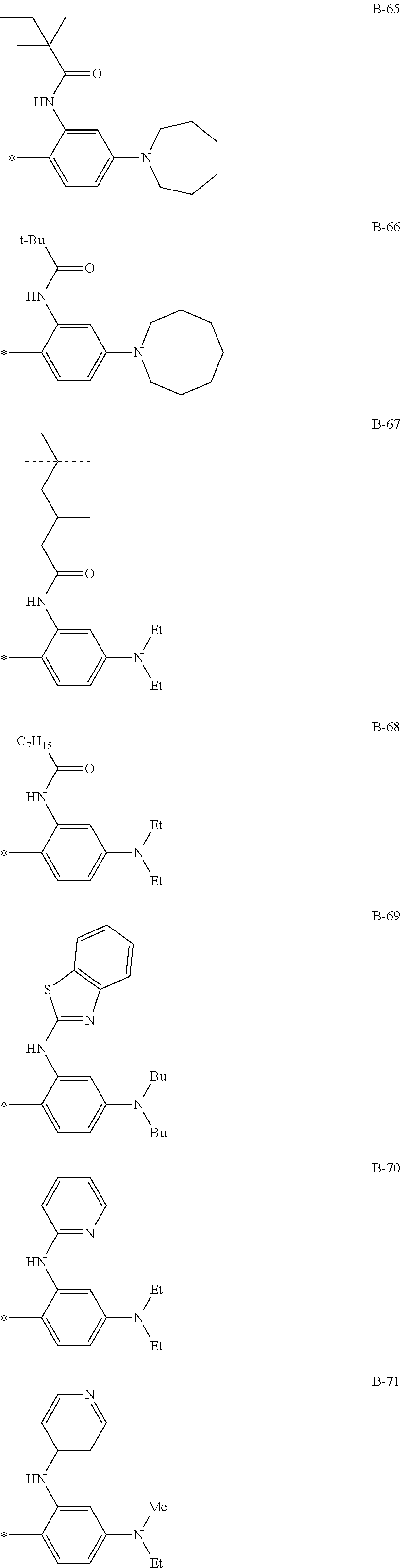

General Formula (3)

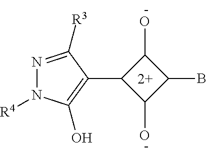

| Compound | | | |
|---|---|---|---|
| number | R³ | R⁴ | B |
| 3-1 | Me | Me | B-3 |
| 3-2 | Me | Me | B-4 |
| 3-3 | Me | Me | B-5 |
| 3-4 | Me | Me | B-10 |
| 3-5 | Me | Me | B-14 |
| 3-6 | Me | Me | B-16 |
| 3-7 | Me | Me | B-17 |
| 3-8 | Me | Me | B-18 |
| 3-9 | Me | Me | B-19 |
| 3-10 | Me | Me | B-20 |
| 3-11 | Me | Me | B-21 |
| 3-12 | Me | Me | B-22 |
| 3-13 | Me | Me | B-23 |
| 3-14 | Me | Me | B-26 |
| 3-15 | Me | Me | B-32 |
| 3-16 | Me | Me | B-33 |
| 3-17 | Me | Me | B-38 |
| 3-18 | Me | Me | B-49 |
| 3-19 | Et | 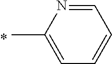 | B-28 |
| 3-20 | Me | 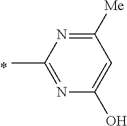 | B-29 |
| 3-21 | H | H | B-23 |
| 3-22 | Et | t-Bu | B-21 |
| 3-23 | t-Bu | Me | B-18 |
| 3-24 | CF₃ | i-Pr | B-12 |
| 3-25 | COOEt | Et | B-6 |
| 3-26 | CN | Ph | B-11 |
| 3-27 | NMe₂ | Me | B-2 |
| 3-28 | i-Pr | Me | B-17 |
| 3-29 | OEt | Bu | B-27 |
| 3-30 | NH₂ | i-Pr | B-9 |
| 3-31 | t-Bu | Me | B-17 |
| 3-32 | t-Bu | Bu | B-21 |
| 3-33 | CF₃ | Me | B-18 |
| 3-34 | OEt | Et | B-33 |
| 3-35 | NMe₂ | i-Pr | B-2 |
| 3-36 | Et | Me | B-17 |
| 3-37 | Bu | Me | B-18 |
| 3-38 | NH₂ | Ph | B-19 |
| 3-39 | OEt | 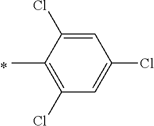 | B-25 |
| 3-40 | Me | 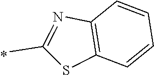 | B-2 |
| 3-41 | Me | Ph | B-17 |
| 3-42 | Me | Ph | B-21 |
| 3-43 | Me | Ph | B-36 |
| 3-44 | Me | t-Bu | B-17 |
| 3-45 | Me | t-Bu | B-18 |
| 3-46 | Me | t-Bu | B-10 |
| 3-47 | OEt | Me | B-17 |
| 3-48 | OEt | Me | B-10 |
| 3-49 | Me | 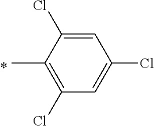 | B-17 |
| 3-50 | Me | 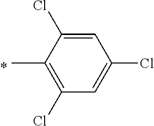 | B-19 |
| 3-51 | Me | 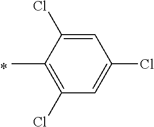 | B-21 |
| 3-52 | Me | 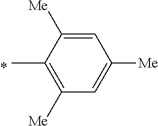 | B-17 |
| 3-53 | Me | 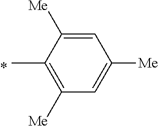 | B-20 |
| 3-54 | Me | 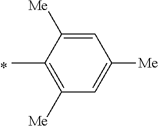 | B-21 |
| 3-55 | t-Bu | Me | B-17 |
| 3-56 | t-Bu | Me | B-10 |
| 3-57 | t-Bu | Me | B-44 |
| 3-58 | t-Bu | t-Bu | B-17 |
| 3-59 | t-Bu | t-Bu | B-10 |
| 3-60 | t-Bu | t-Bu | B-6 |
| 3-61 | NBu₂ | Me | B-17 |
| 3-62 | NBu₂ | Me | B-10 |
| 3-63 | t-Bu | 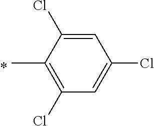 | B-17 |
| 3-64 | t-Bu | 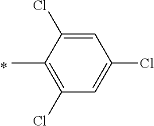 | B-19 |
| 3-65 | t-Bu | 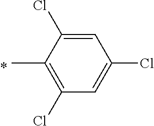 | B-21 |
| 3-66 | t-Bu | 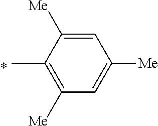 | B-17 |
| 3-67 | t-Bu | 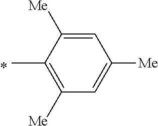 | B-20 |
| 3-68 | t-Bu | 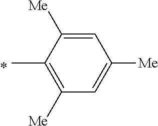 | B-21 |
| 3-69 | Me | t-Bu | B-51 |
| 3-70 | Me | t-Bu | B-52 |
| 3-71 | Me | t-Bu | B-54 |
| 3-72 | Me | t-Bu | B-55 |
| 3-73 | Me | t-Bu | B-58 |
| 3-74 | Me | t-Bu | B-60 |
| 3-75 | Me | t-Bu | B-65 |
| 3-76 | Me | t-Bu | B-67 |
| 3-77 | Me | t-Bu | B-68 |
| 3-78 | H | t-Bu | B-51 |
| 3-79 | Et | t-Bu | B-53 |
| 3-80 | Pr | 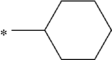 | B-64 |
| 3-81 | iPr | iPr | B-66 |
| 3-82 | Me | 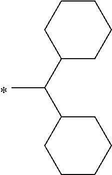 | B-51 |
| 3-83 | Et | Bu | B-56 |
| 3-84 | Me | iPr | B-66 |
| 3-85 | Me | 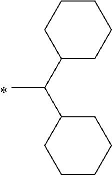 | B-54 |
| 3-86 | Me | 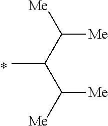 | B-57 |
| 3-87 | Et | 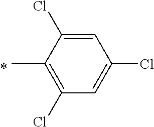 | B-60 |
| 3-88 | Me | iPr | B-65 |
| 3-89 | Me | t-Bu | B-69 |
| 3-90 | Me | 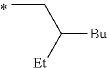 | B-50 |
| 3-91 | Me | 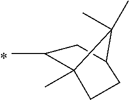 | B-61 |
| 3-92 | Me | 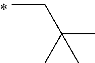 | B-51 |
| 3-93 | Me | 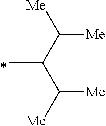 | B-51 |
| 3-94 | Me | 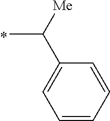 | B-67 |
| 3-95 | Me | 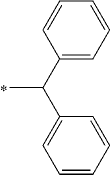 | B-51 |
| 3-96 | Me | 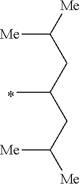 | B-51 |

General Formula (4)

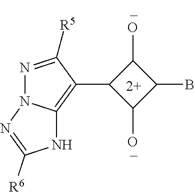

| Compound | | | |
|---|---|---|---|
| number | R⁵ | R⁶ | B |
| 4-1 | t-Bu | 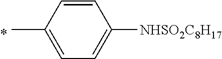 | B-2 |
| 4-2 | t-Bu | 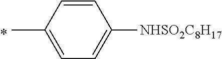 | B-6 |
| 4-3 | t-Bu | 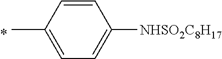 | B-10 |
| 4-4 | Me | 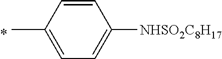 | B-4 |
| 4-5 | t-Bu | 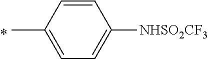 | B-6 |
| 4-6 | t-Bu | 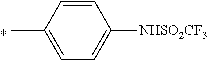 | B-14 |
| 4-7 | NHCOCH₃ | 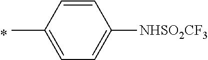 | B-1 |
| 4-8 | t-Bu | 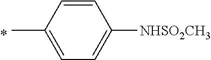 | B-6 |
| 4-9 | t-Bu | 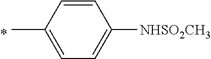 | B-16 |
| 4-10 | OEt | 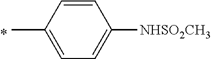 | B-11 |
| 4-11 | t-Bu | 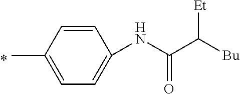 | B-6 |
| 4-12 | t-Bu | 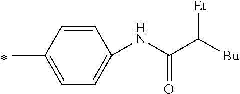 | B-12 |
| 4-13 | OEt | 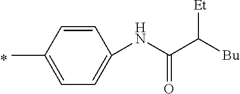 | B-31 |
| 4-14 | H | H | B-22 |
| 4-15 | Me | Me | B-23 |
| 4-16 | Me | Me | B-17 |
| 4-17 | Me | Et | B-18 |
| 4-18 | Ph | Ph | B-8 |
| 4-19 | Et | t-Bu | B-17 |
| 4-20 | OEt | t-Bu | B-3 |
| 4-21 | OEt | Bu | B-26 |
| 4-22 | OEt | 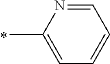 | B-2 |
| 4-23 | CF3 | t-Bu | B-19 |
| 4-24 | NHCOCH₃ | t-Bu | B-2 |
| 4-25 | NHCOCH₃ | Me | B-1 |
| 4-26 | NMe₂ | t-Bu | B-6 |
| 4-27 | NMe₂ | Et | B-17 |
| 4-28 | H | Me | B-2 |
| 4-29 | t-Bu | t-Bu | B-18 |
| 4-30 | t-Bu | Me | B-17 |
| 4-31 | t-Bu | 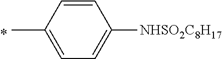 | B-51 |
| 4-32 | t-Bu | 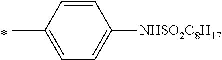 | B-52 |
| 4-33 | t-Bu | 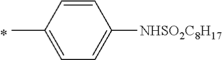 | B-54 |
| 4-34 | Me | 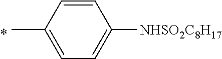 | B-55 |
| 4-35 | t-Bu | 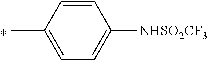 | B-60 |
| 4-36 | Me | Me | B-65 |
| 4-37 | Me | Et | B-67 |
| 4-38 | Ph | Ph | B-48 |
| 4-39 | Et | t-Bu | B-54 |
| 4-40 | Me | Me | B-51 |

General Formula (5)

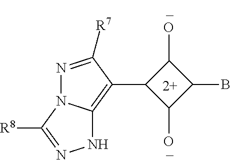

| Compound | | | |
|---|---|---|---|
| number | R⁷ | R⁸ | B |
| 5-1 | t-Bu | 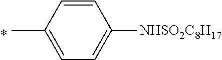 | B-2 |
| 5-2 | Me | 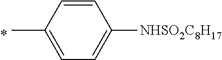 | B-6 |
| 5-3 | t-Bu | 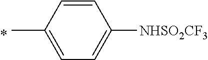 | B-4 |
| 5-4 | Me | 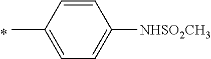 | B-10 |
| 5-5 | t-Bu | 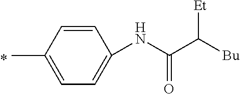 | B-6 |
| 5-6 | t-Bu | 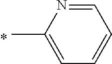 | B-14 |
| 5-7 | Me | 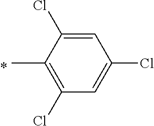 | B-1 |
| 5-8 | Me | 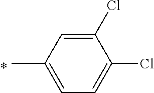 | B-6 |
| 5-9 | Me | 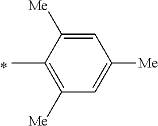 | B-16 |
| 5-10 | t-Bu | 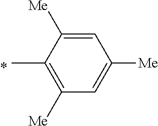 | B-11 |
| 5-11 | Me | Me | B-17 |
| 5-12 | Me | t-Bu | B-18 |
| 5-13 | Ph | Ph | B-8 |
| 5-14 | Ph | 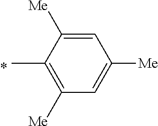 | B-17 |
| 5-15 | Et | Ph | B-17 |
| 5-16 | OEt | t-Bu | B-3 |
| 5-17 | OEt | Bu | B-26 |
| 5-18 | CF3 | t-Bu | B-19 |
| 5-19 | NHCOCH3 | t-Bu | B-2 |
| 5-20 | NHCOCH3 | 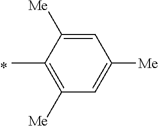 | B-1 |
| 5-21 | t-Bu | 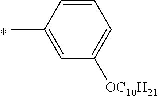 | B-2 |
| 5 22 | Me | 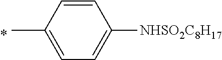 | B-51 |
| 5-23 | t-Bu | 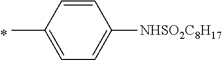 | B-52 |
| 5-24 | Me | 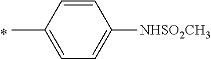 | B-55 |
| 5-25 | t-Bu | 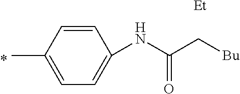 | B-60 |
| 5-26 | Me | Me | B-65 |
| 5-27 | Me | t-Bu | B-67 |
| 5-28 | Ph | Ph | B-50 |
| 5-29 | Ph | 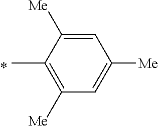 | B-23 |
| 5-30 | Et | Ph | B-59 |

One preferred embodiment of the coloring agent represented by General Formula (1) includes a coloring agent represented by General Formula (6).

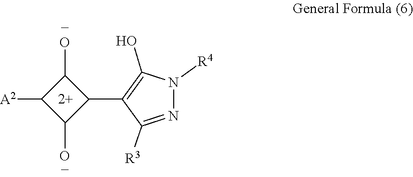

In General Formula (6), R³ and R⁴ each independently represent a hydrogen atom or a substituent and they respectively have the same meanings as R³ and R⁴ in General Formula (3), where the preferred ones thereof are also the same.

In General Formula (6), A² has the same meaning as A in General Formula (1). Among these, a heterocyclic group which is a nitrogen-containing 5-membered ring is preferable.

The coloring agent represented by General Formula (6) is preferably a coloring agent represented by any one of General Formula (7), (8), or (9).

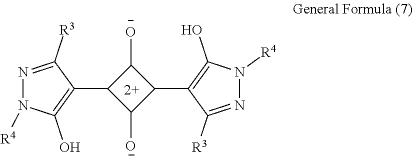

In General Formula (7), R³ and R⁴ each independently represent a hydrogen atom or a substituent, and they respectively have the same meanings as R³ and R⁴ in General Formula (3), where the same applies to the preferred ranges thereof. Two R³'s and two R⁴'s may be the same or different from each other.

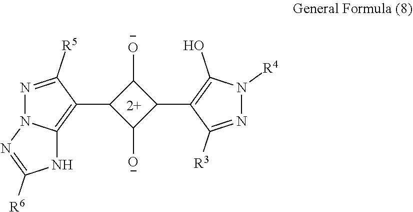

In General Formula (8), R³ and R⁴ each independently represent a hydrogen atom or a substituent, and they respectively have the same meanings as R³ in General Formula (3), where the same applies to the preferred ranges thereof.

In General Formula (8), R⁵ and R⁶ each independently represent a hydrogen atom or a substituent, and they respectively have the same meanings as R⁵ and R⁶ in General Formula (4), where the same applies to the preferred ranges thereof.

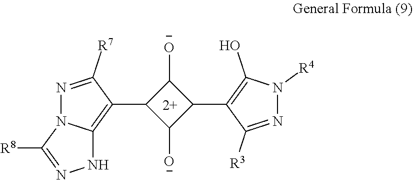

In General Formula (9), R³ and R⁴ each independently represent a hydrogen atom or a substituent, and they respectively have the same meanings as R³ in General Formula (3), where the same applies to the preferred ranges thereof.

In General Formula (9), R⁷ and R⁸ each independently represent a hydrogen atom or a substituent, and they respectively have the same meanings as R⁷ and R¹ in General Formula (5), where the same applies to the preferred ranges thereof.

In the present invention, in a case where a squarine-based coloring agent is used as the dye B, any squarine-based coloring agent may be used without particular limitations as long as the squarine-based coloring agent is the squarine coloring agent represented by any one of General Formulae (6) to (9). Examples thereof include the compounds described in JP2002-97383A and JP2015-68945A.

Hereinafter, specific examples of the coloring agent represented by any one of General Formulae (6) to (9) will be shown. However, the present invention is not limited thereto.

In the following specific examples, Me represents methyl, Et represents ethyl, i-Pr represents i-propyl, t-Bu represents t-butyl, and Ph represents phenyl, respectively. In the following structures, * indicates a bonding site to a 4-membered carbon ring in each General Formula.

General Formula (7)

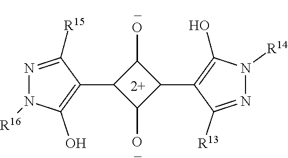

| Compound | | | | |
|---|---|---|---|---|
| number | R¹³ | R¹⁴ | R¹⁵ | R¹⁶ |
| 7-1 | Me | Me | Me | Me |
| 7-2 | Et | Me | Et | Me |
| 7-3 | Me | 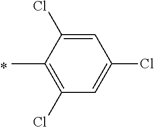 | Me | 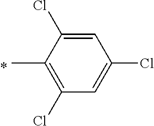 |
| 7-4 | t-Bu | 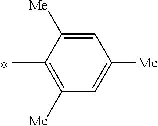 | t-Bu | 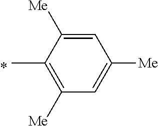 |
| 7-5 | NMe₂ | Me | NMe₂ | Me |
| 7-6 | CN | Me | CN | Me |
| 7-7 | OEt | Me | OEt | Me |
| 7-8 | Me | 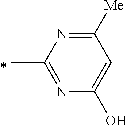 | Me | 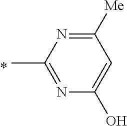 |
| 7-9 | Et | 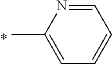 | Et | 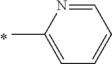 |
| 7-10 | i-Pr | 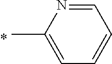 | i-Pr | 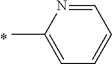 |
| 7-11 | t-Bu | t-Bu | t-Bu | t-Bu |
| 7-12 | CF₃ | Ph | CF₃ | Ph |
| 7-13 | COOEt | Me | COOEt | Me |
| 7-14 | NH₂ | Me | NH₂ | Me |
| 7-15 | Me | Me | Me | 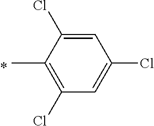 |
| 7-16 | Me | Me | t-Bu | t-Bu |
| 7-17 | Me | Me | NMe2 | Me |
| 7-18 | Me | Me | Me | Ph |
| 7-19 | Et | Me | Et | 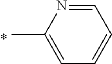 |
| 7-20 | COOEt | Me | Me | 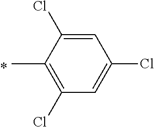 |

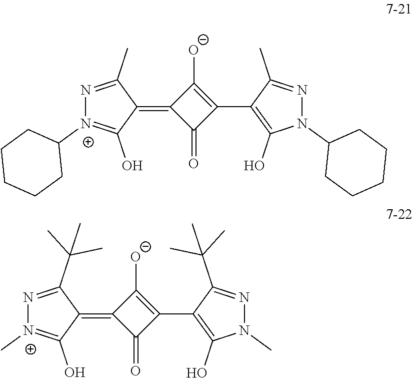

General Formula (8)

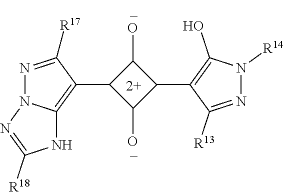

| Compound | | | | |
|---|---|---|---|---|
| number | R¹³ | R14 | R¹⁷ | R¹⁸ |
| 8-1 | Me | Me | Me | Me |
| 8-2 | Me | Me | t-Bu | 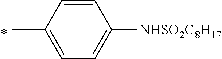 |
| 8-3 | Me | Me | t-Bu | 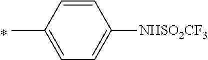 |
| 8-4 | Me | Me | t-Bu | 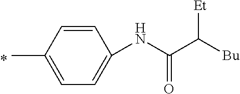 |
| 8-5 | Me | 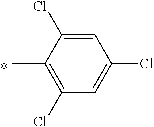 | Me | Me |
| 8-6 | Me | 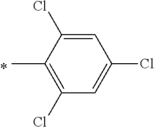 | t-Bu | 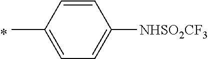 |
| 8-7 | Me | Ph | t-Bu | 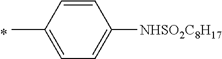 |
| 8-8 | Me | 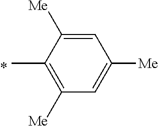 | Me | Me |
| 8-9 | Et | Me | Me | Me |
| 8-10 | i-Pr | Me | Me | Me |
| 8-11 | t-Bu | Me | Me | Me |
| 8-12 | Me | Me | OEt | Bu |
| 8-13 | COOEt | Me | Me | Me |
| 8-14 | NH₂ | Me | Me | Me |
| 8-15 | Me | Me | CF₃ | t-Bu |

General Formula (9)

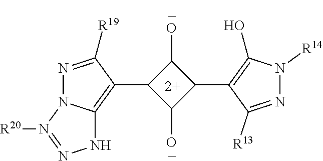

| Compound | | | | |
|---|---|---|---|---|
| number | R¹³ | R¹⁴ | R¹⁹ | R²⁰ |
| 9-1 | Me | Me | Me | Me |
| 9-2 | Me | Me | t-Bu | 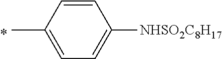 |
| 9-3 | Me | Me | Me | 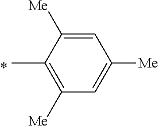 |
| 9-4 | Me | Me | Me | 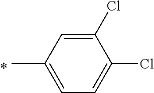 |
| 9-5 | Me | 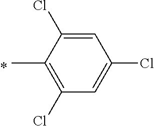 | Me | Me |
| 9-6 | Me | 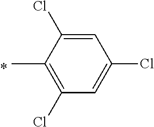 | Me | 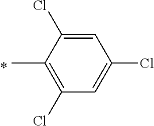 |
| 9-7 | t-Bu | Me | t-Bu | 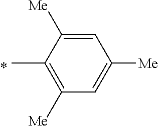 |
| 9-8 | t-Bu | Me | Me | Me |
| 9-9 | Et | Me | t-Bu | Me |
| 9-10 | i-Pr | Me | Me | 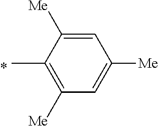 |

(Quencher-Embedded Coloring Agent)

The squarine-based coloring agent represented by General Formula (1) may be a quencher-embedded coloring agent in which a quencher moiety is linked to a coloring agent by a covalent bond with a linking group being interposed therebetween. The quencher-embedded coloring agent can also be preferably used as the coloring agent of at least one of the dye B or C. That is, the quencher-embedded coloring agent is counted as the dye B or dye C according to the wavelength having the main absorption wavelength band.

Examples of the quencher moiety include the ferrocenyl group in the above-described substituent X. Further, examples thereof include the quencher moiety in the quencher compounds described in paragraphs [0199] to [0212] and paragraphs [0234] to [0310] of WO2019/066043A.

Among the squarine-based coloring agents represented by General Formula (1), specific examples of the coloring agent corresponding to the quencher-embedded coloring agent are shown below. However, the present invention is not limited thereto.

In the following specific examples, Me represents methyl, Et represents ethyl, and Bu represents butyl, respectively.

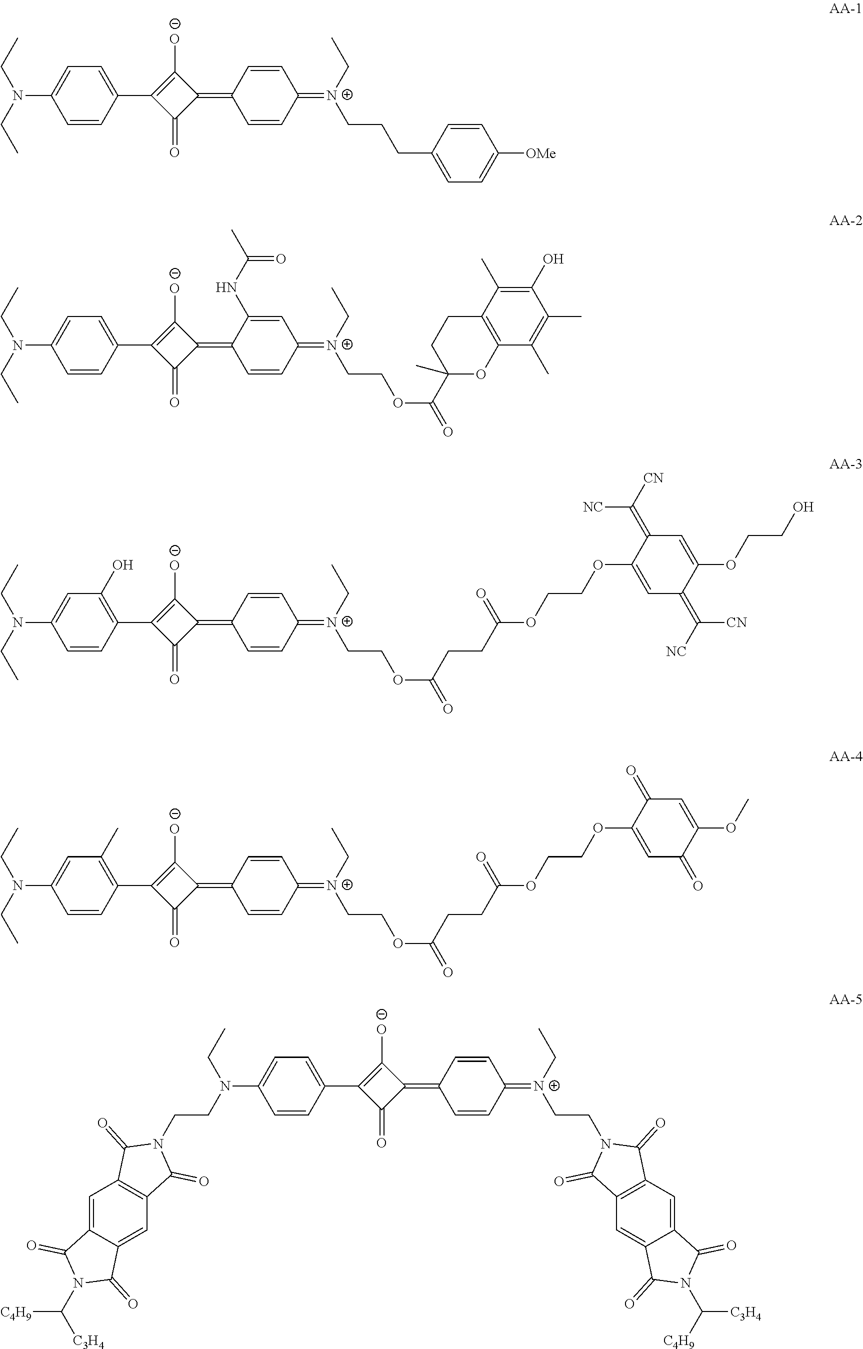

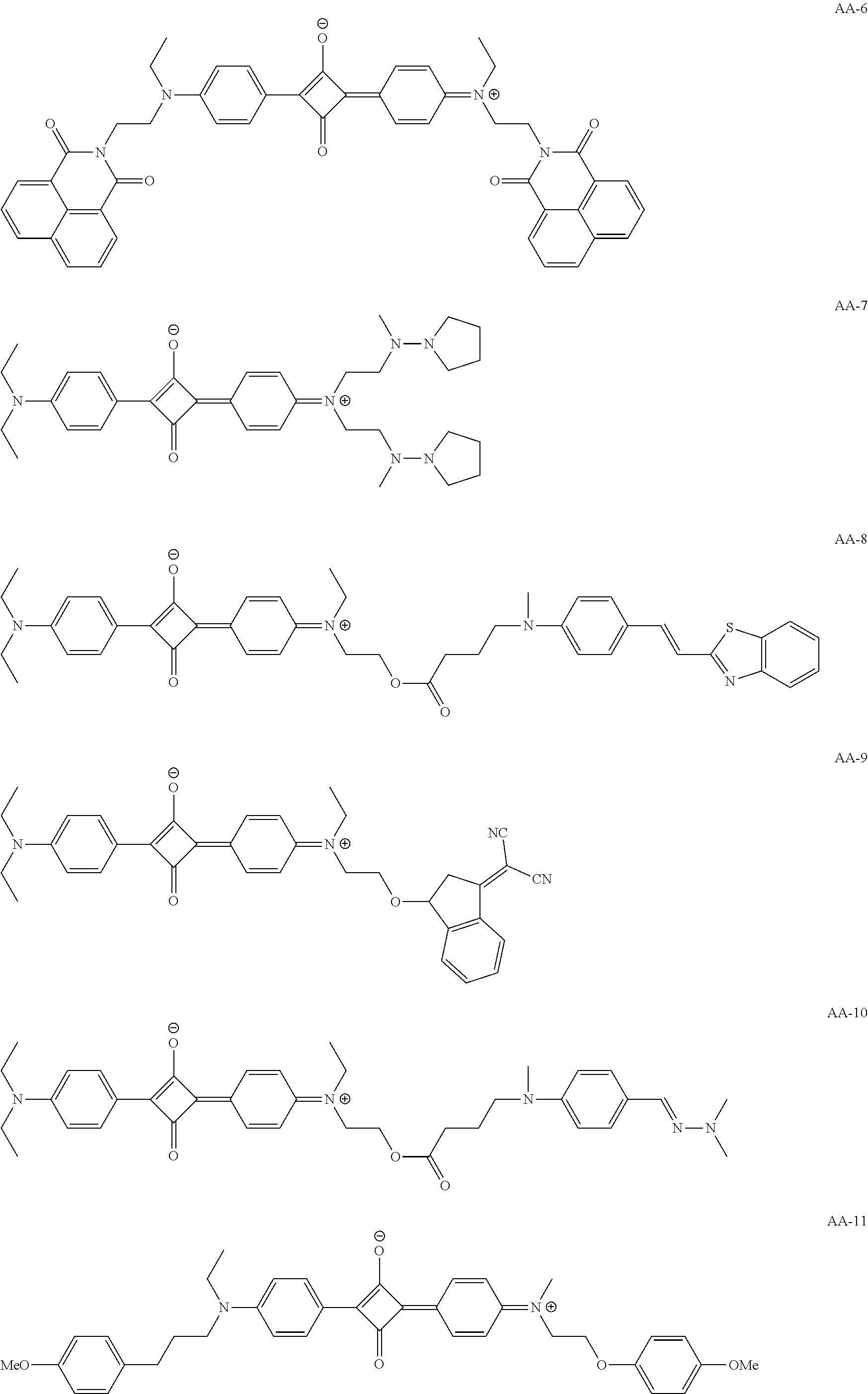

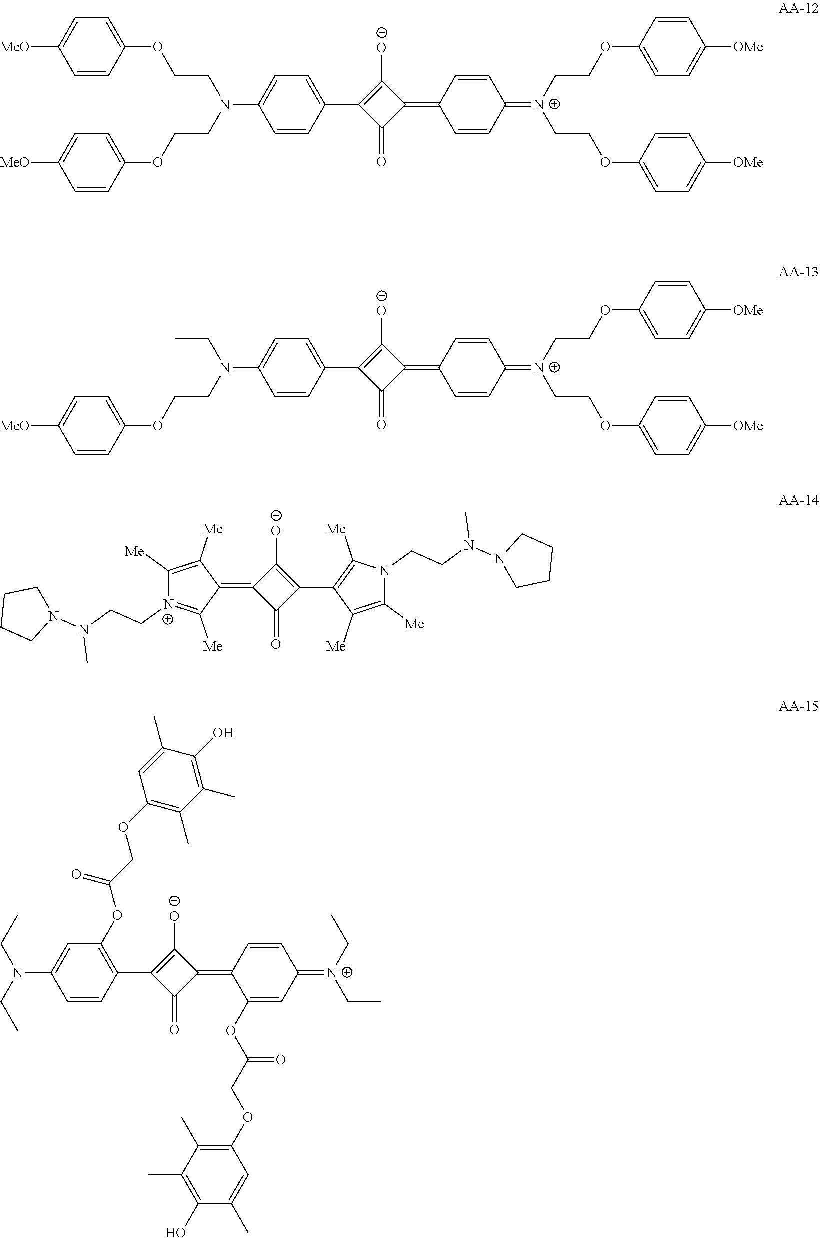 [SMILES: COc1ccc(OCCN(CCOc2ccc(OC)cc2)c2ccc(C3=C([O-])C(=C4C=CC(=[N+](CCOc5ccc(OC)cc5)CCOc5ccc(OC)cc5)C=C4)C3=O)cc2)cc1 ; CCN(CCOc1ccc(OC)cc1)c1ccc(C2=C([O-])C(=C3C=CC(=[N+](CCOc4ccc(OC)cc4)CCOc4ccc(OC)cc4)C=C3)C2=O)cc1 ; CC1=C(C)[N+](CCN(C)N2CCCC2)=C(C)/C1=C1\C(=O)C(c2c(C)c(C)n(CCN(C)N3CCCC3)c2C)=C1[O-] ; CCN(CC)c1ccc(C2=C([O-])/C(=C3\C=CC(=[N+](CC)CC)C=C3OC(=O)COc3cc(C)c(O)c(C)c3C)C2=O)c(OC(=O)COc2cc(C)c(O)c(C)c2C)c1]

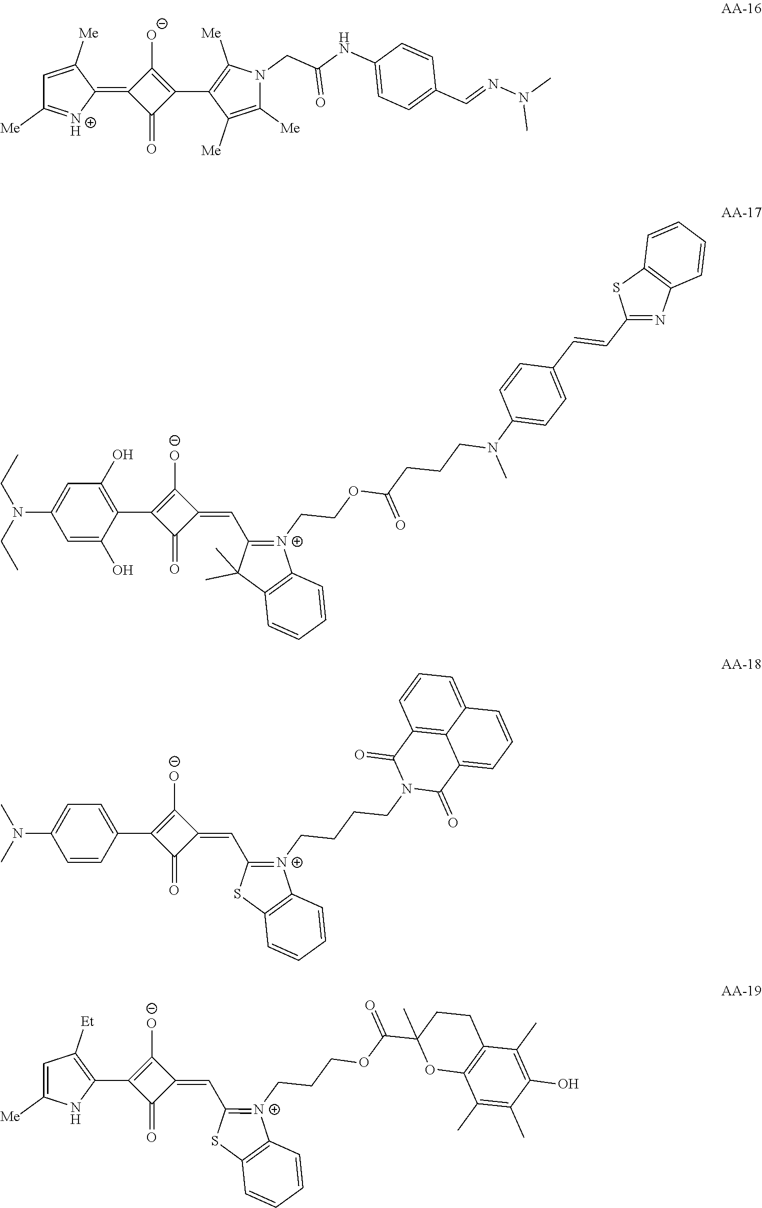

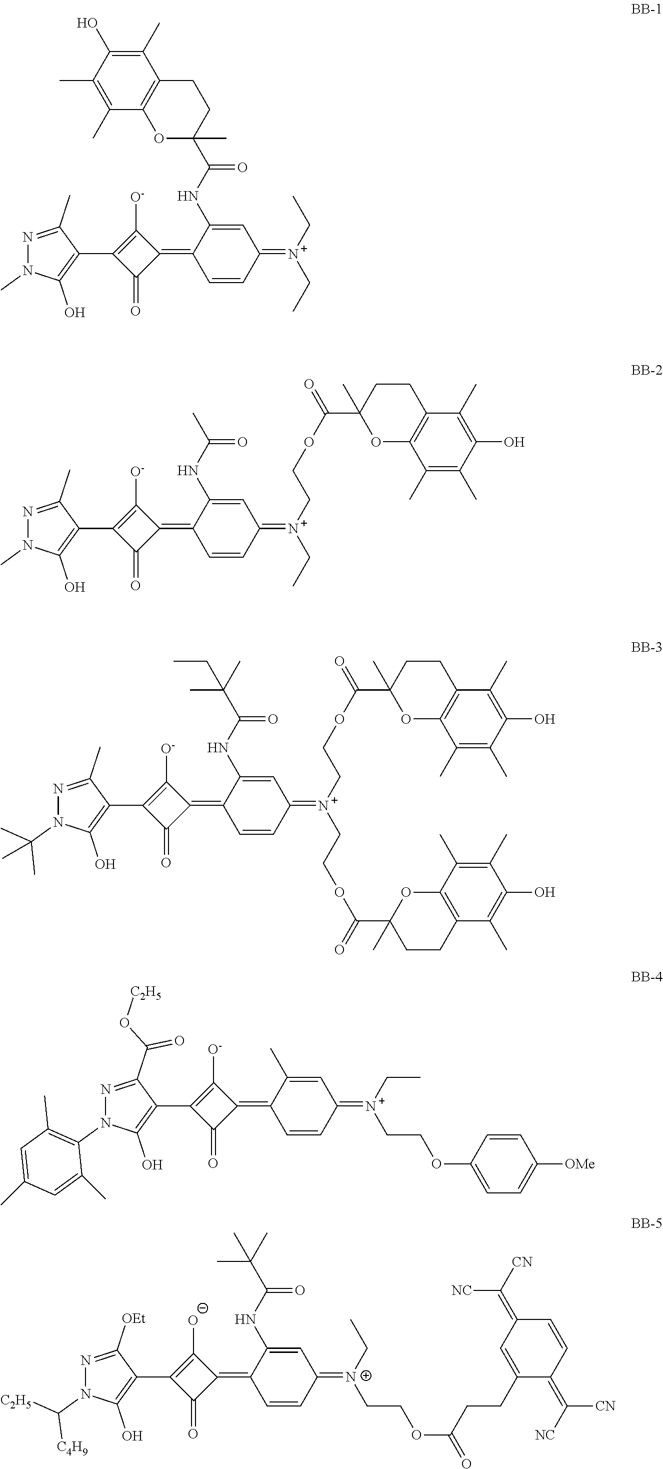

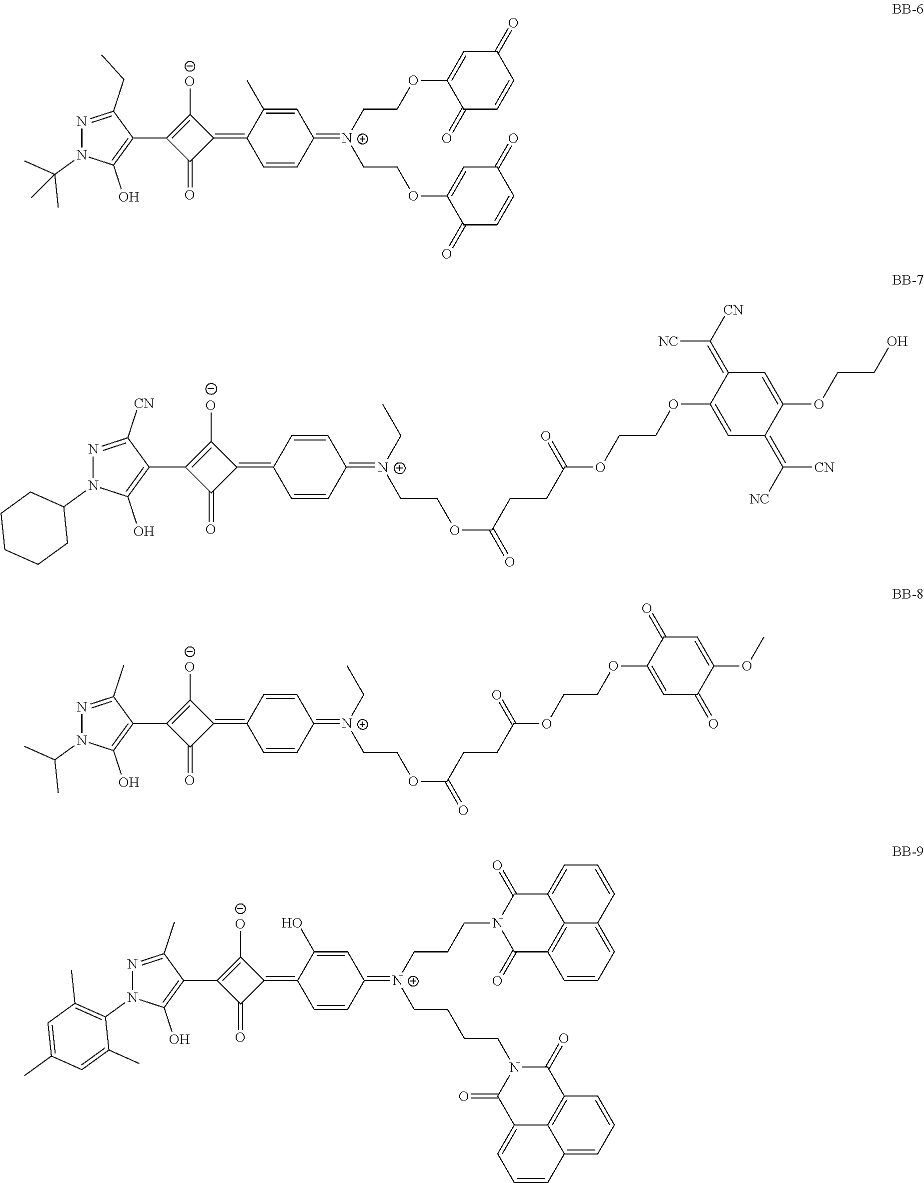

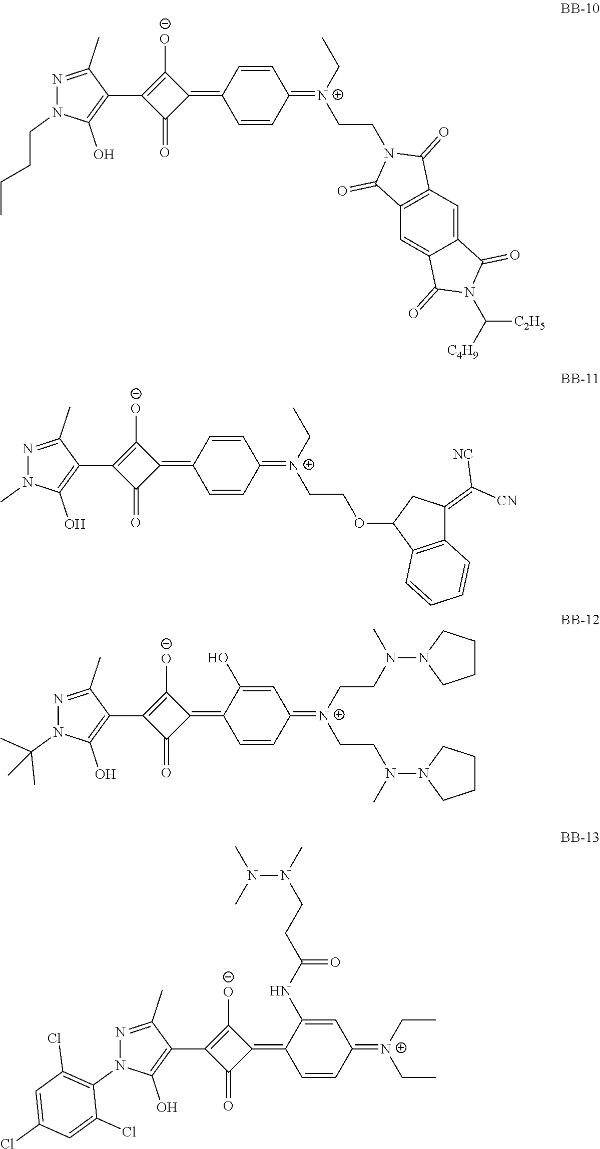

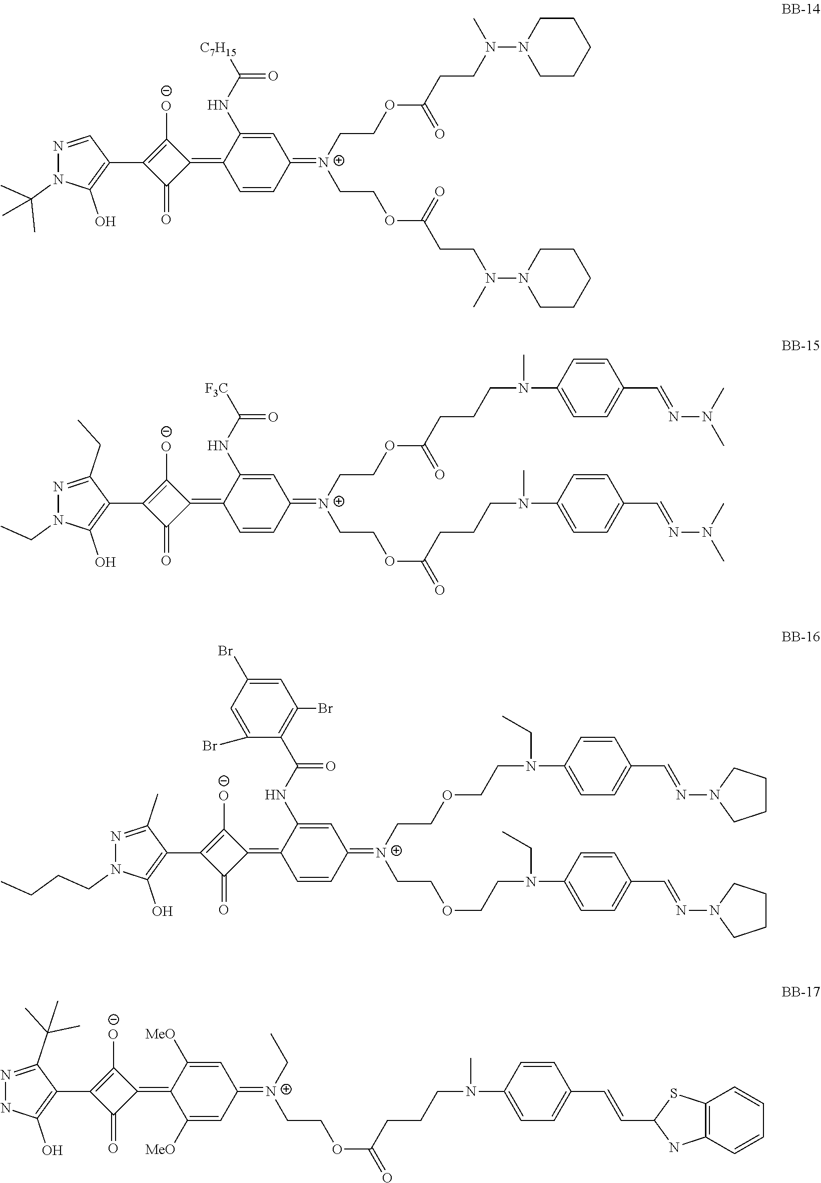

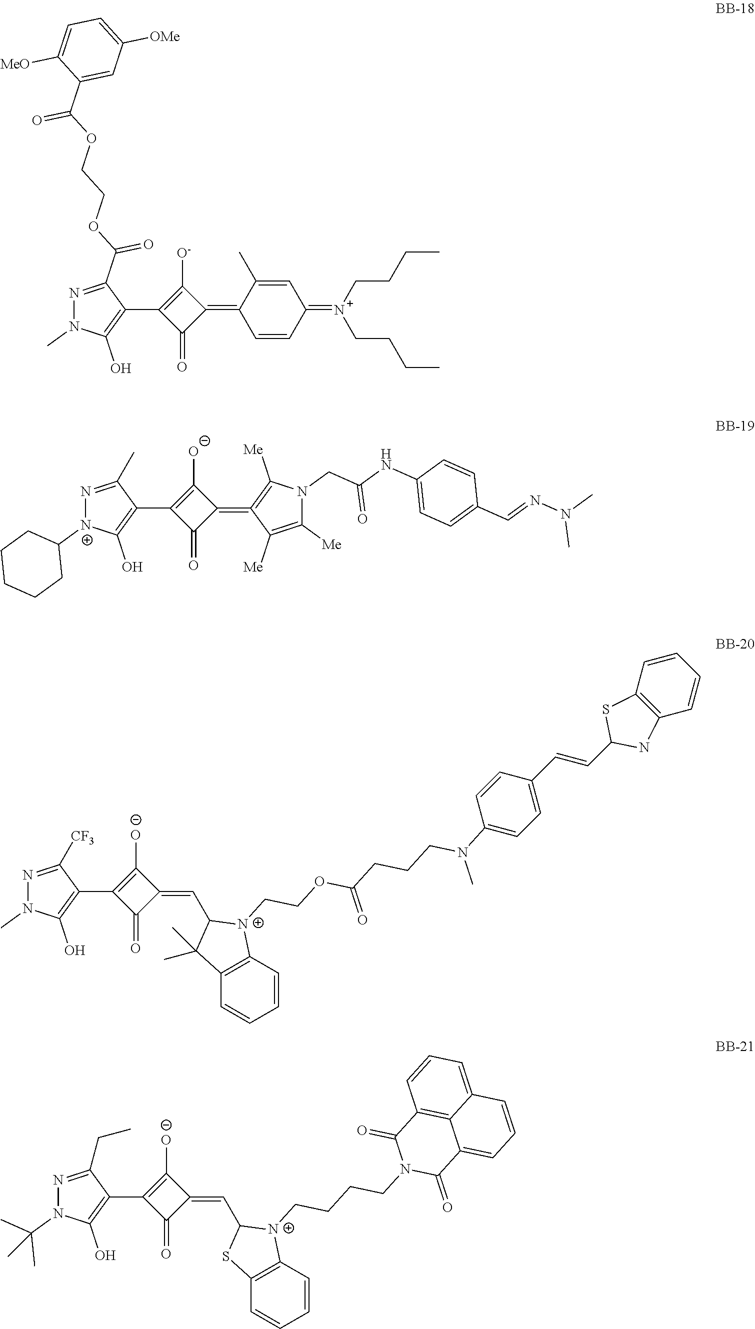

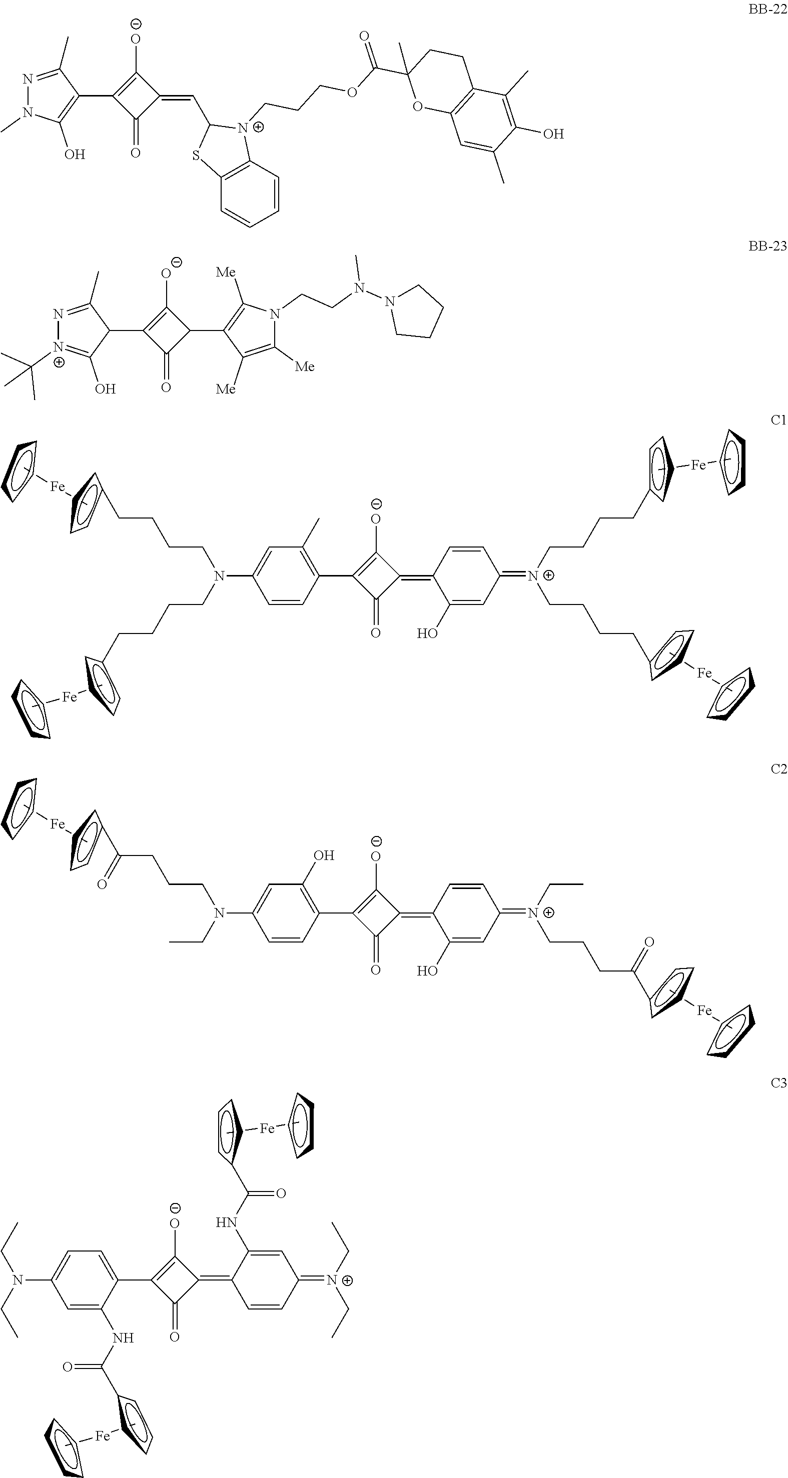

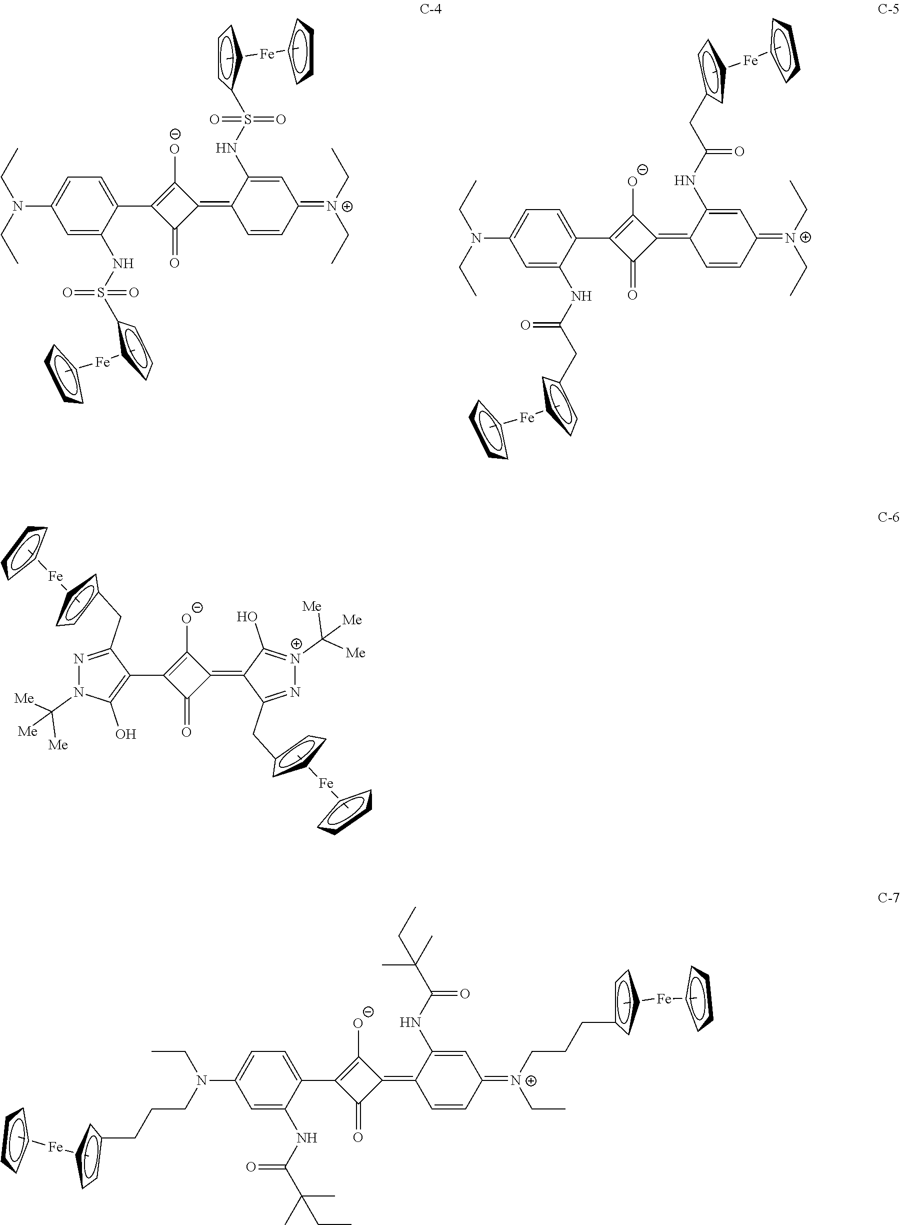

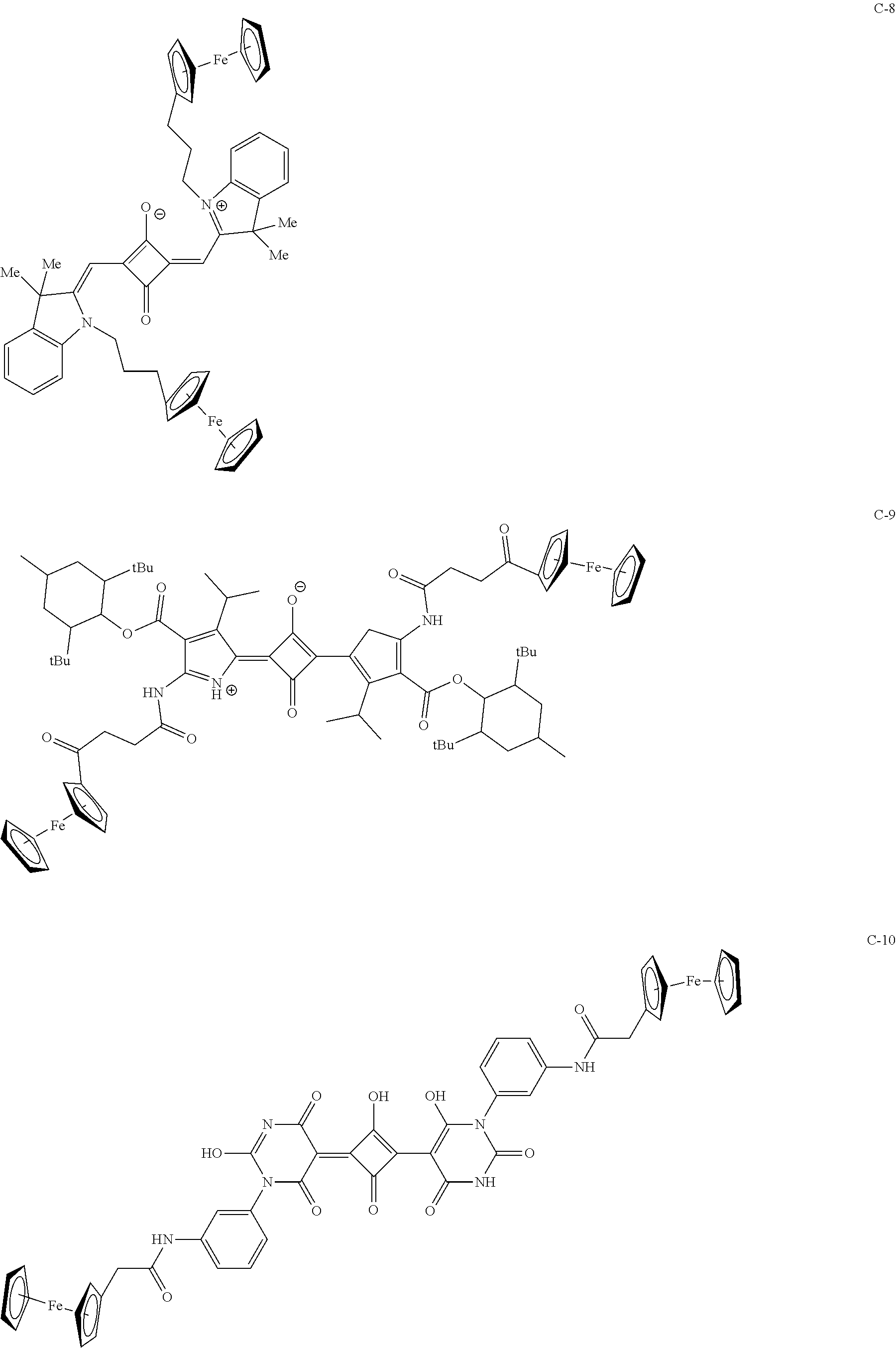

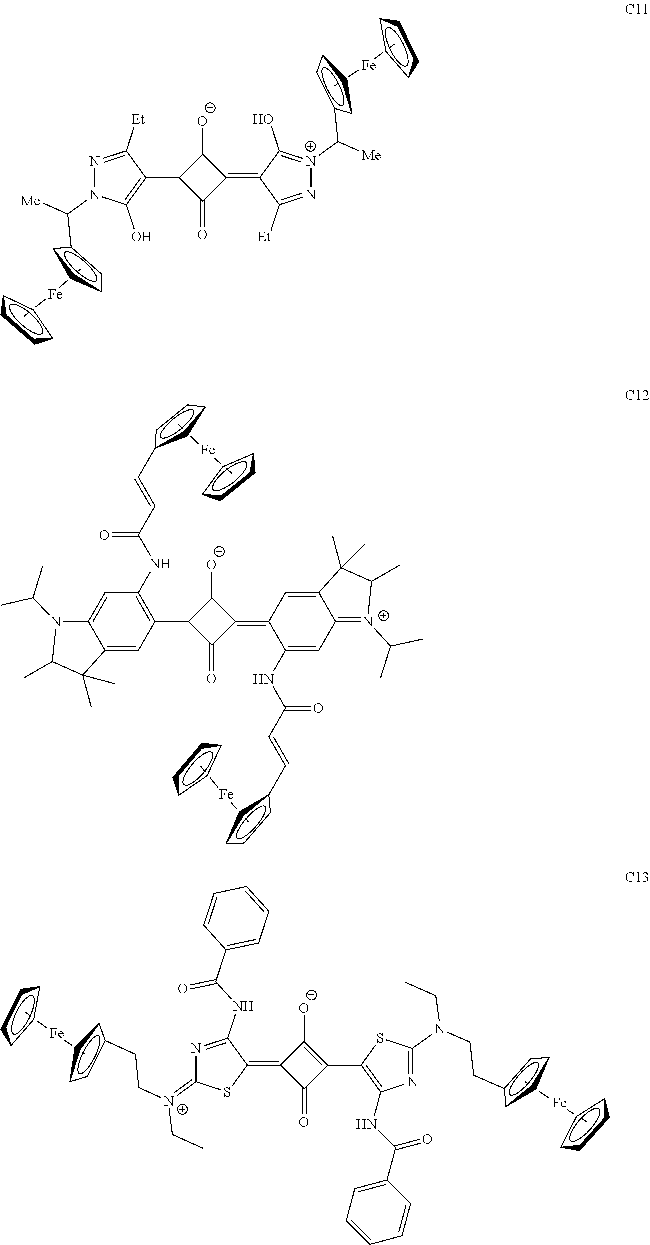

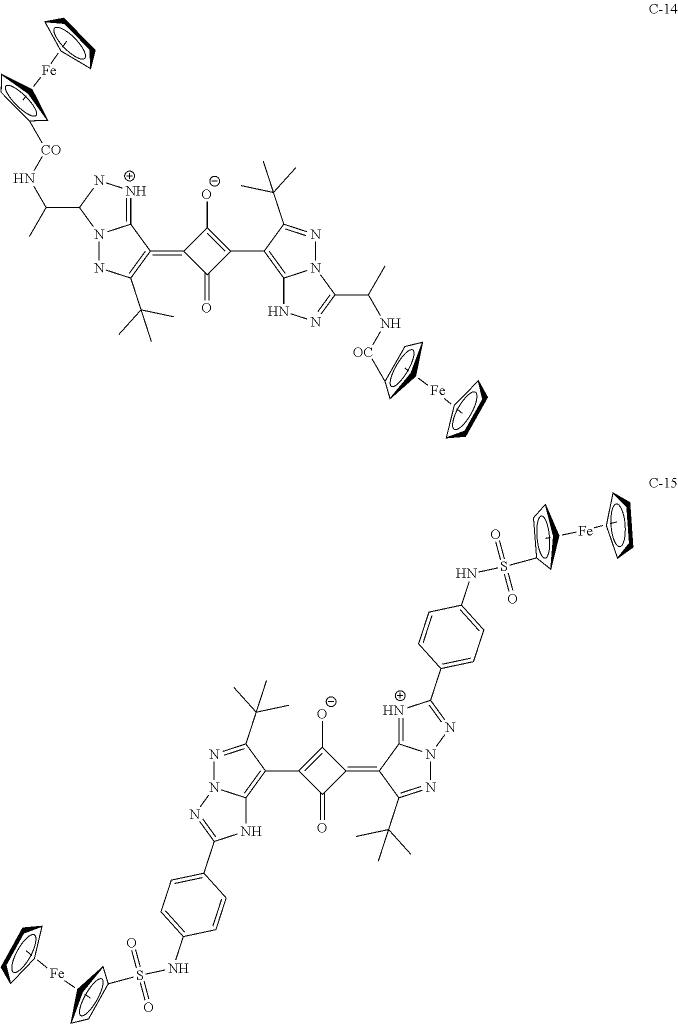

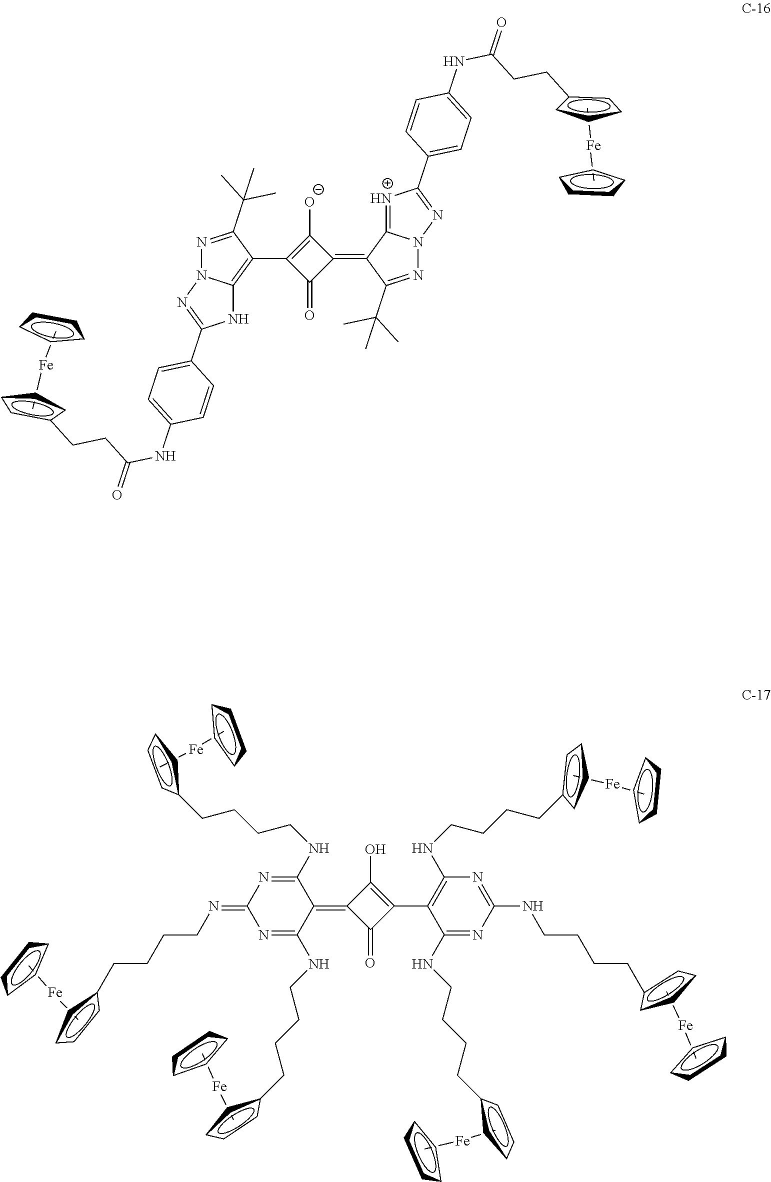

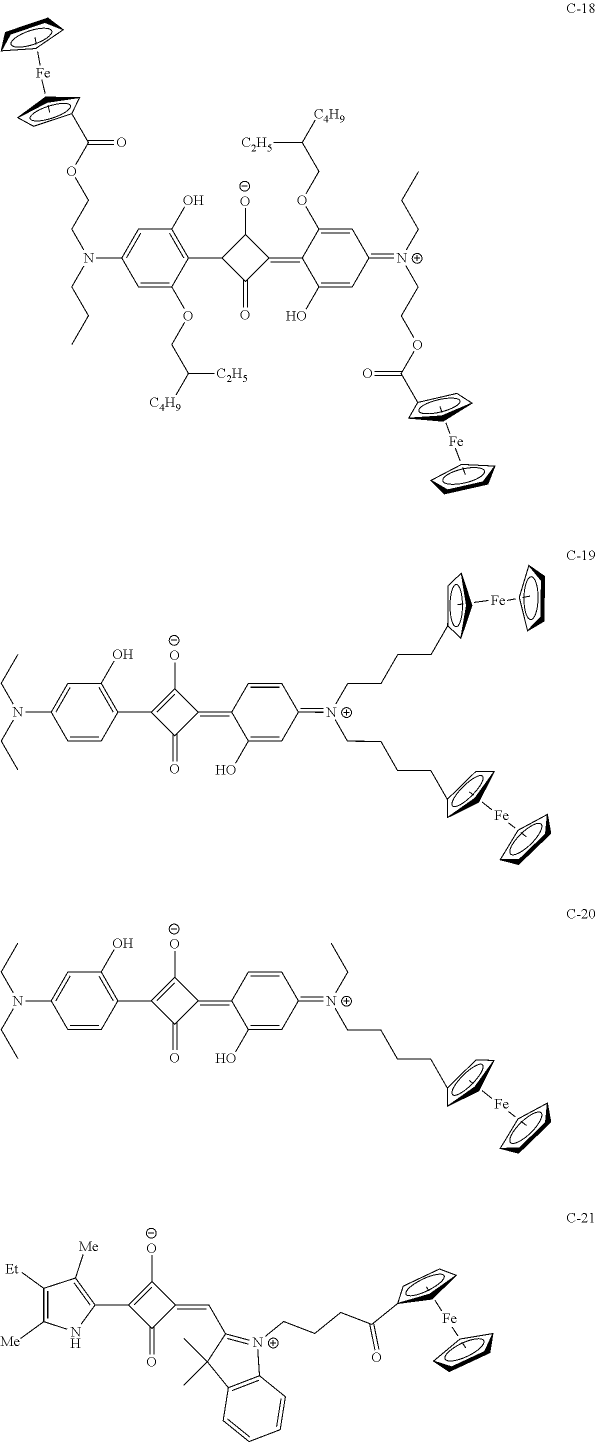

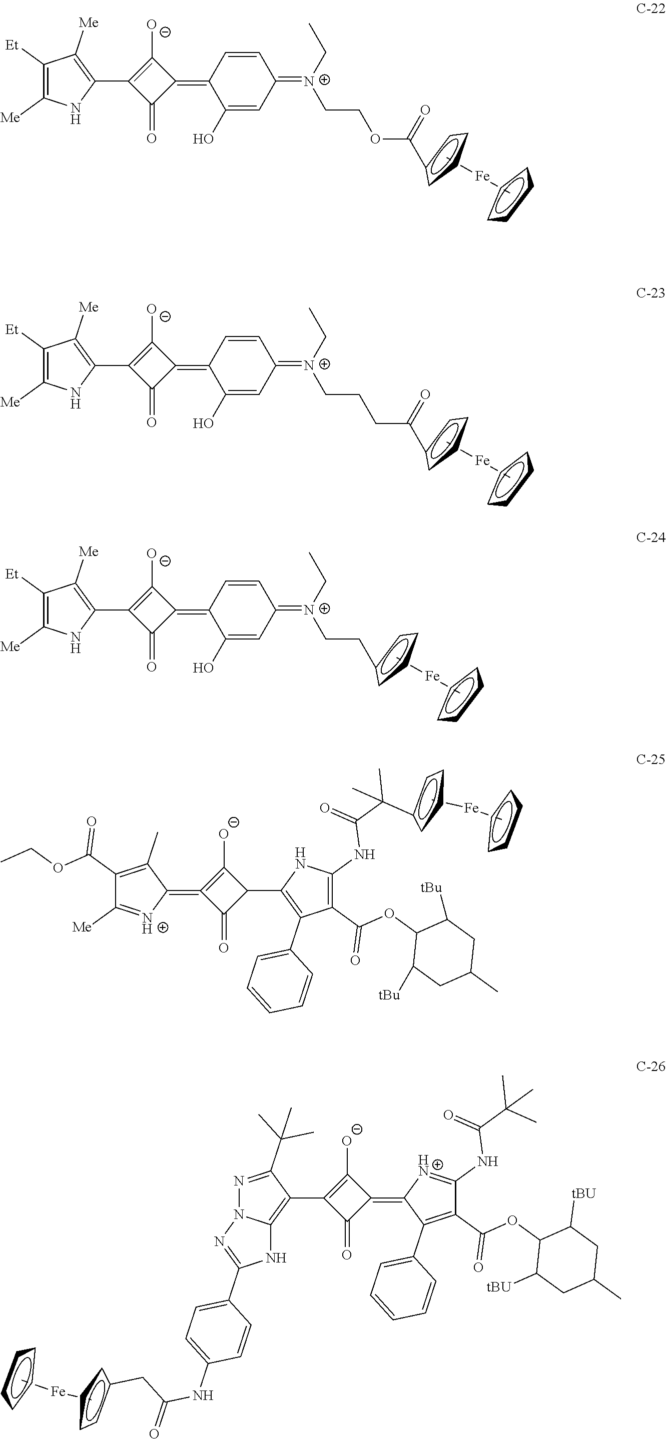

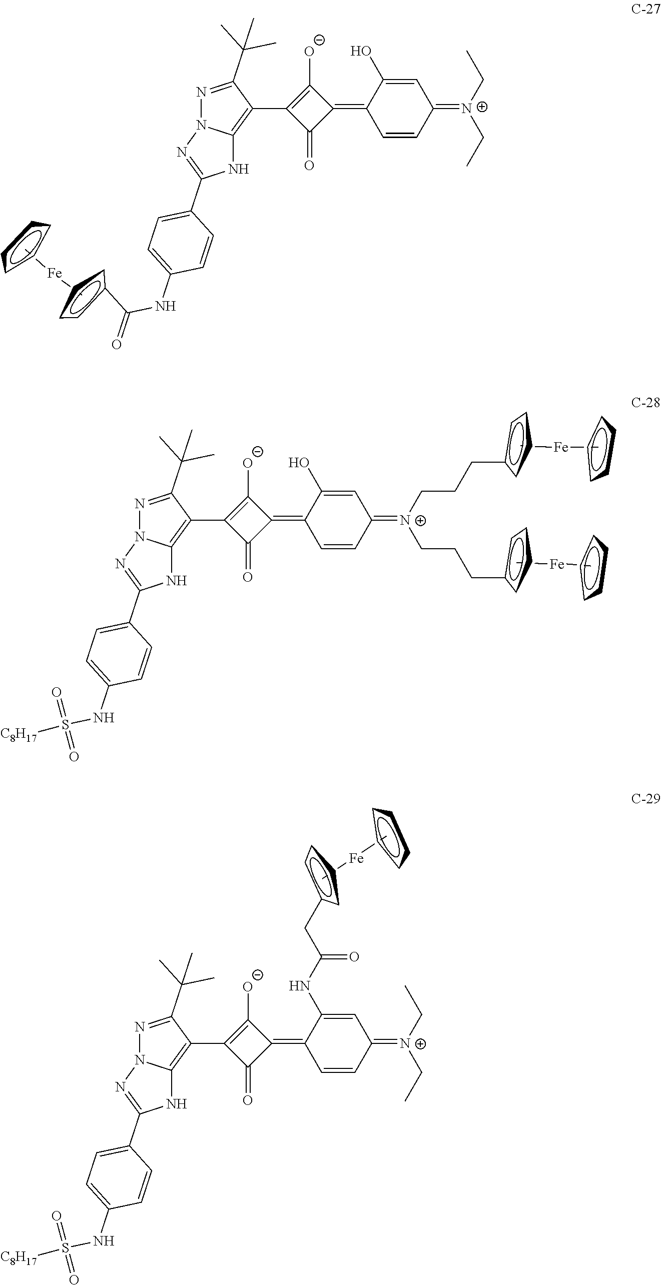

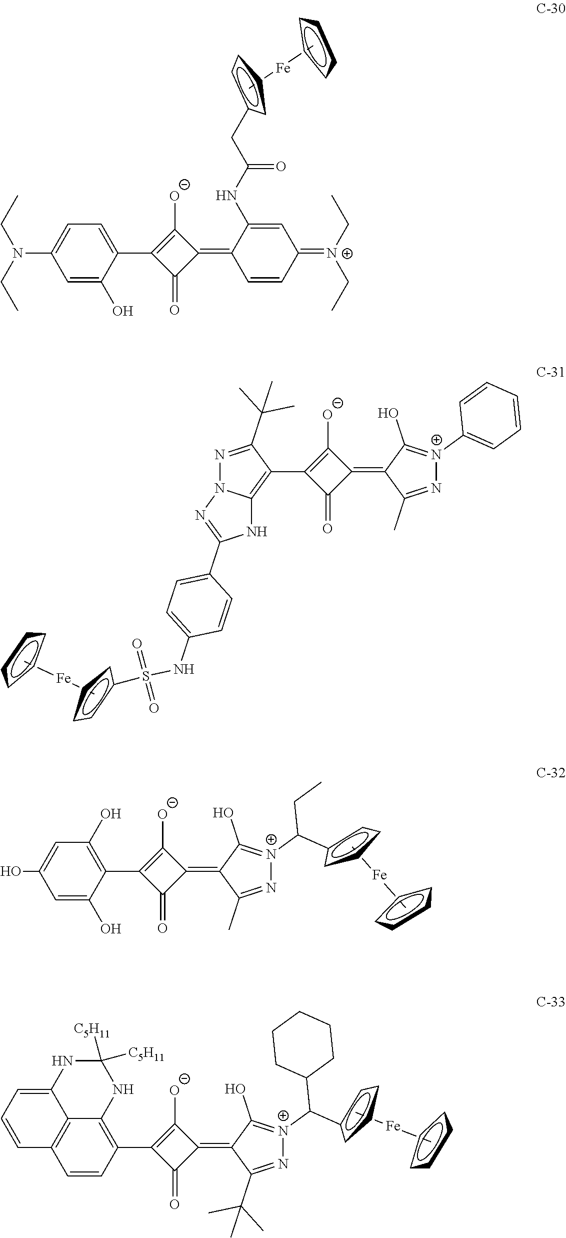

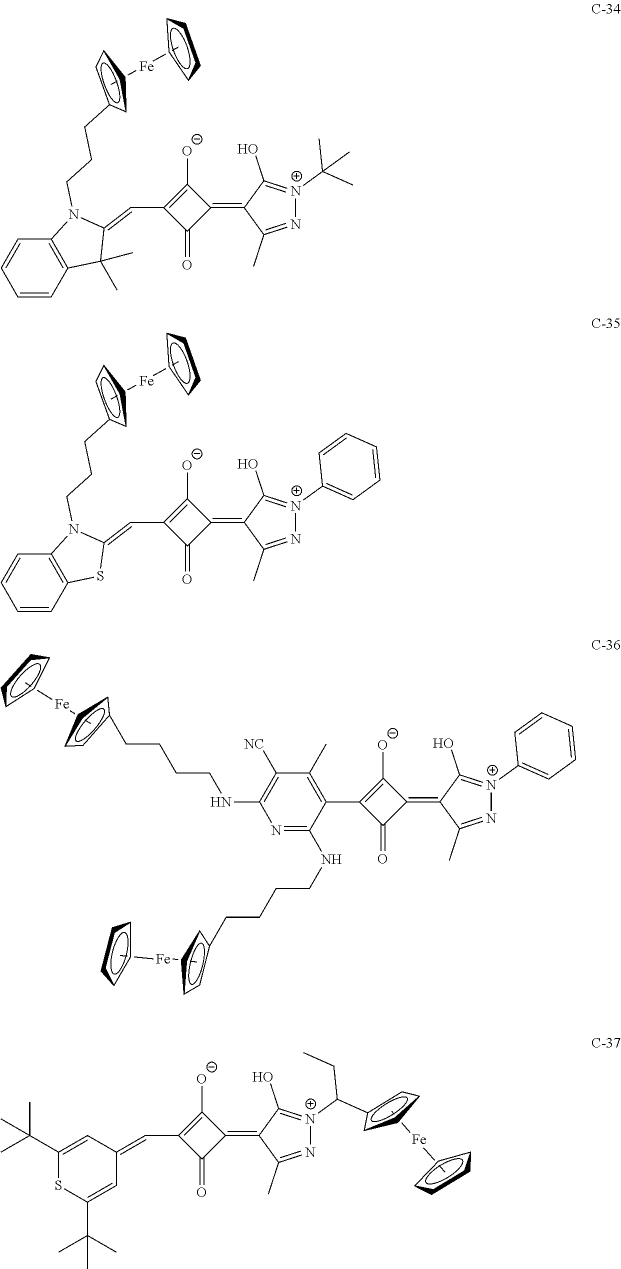

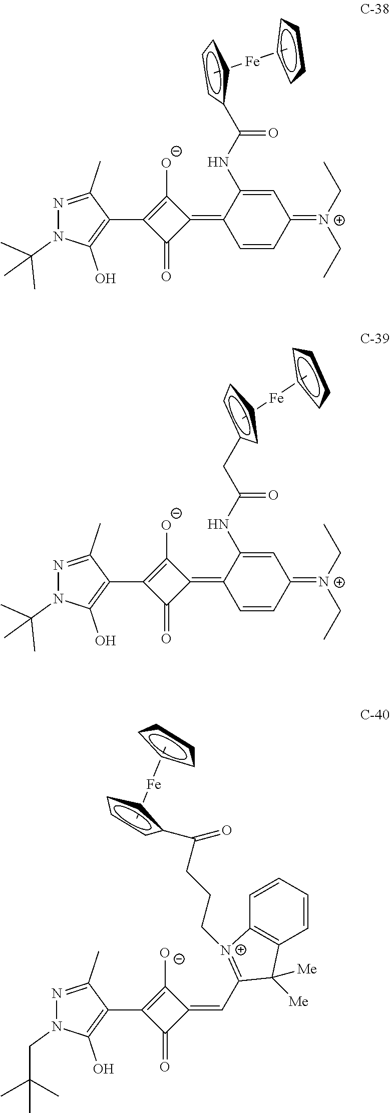

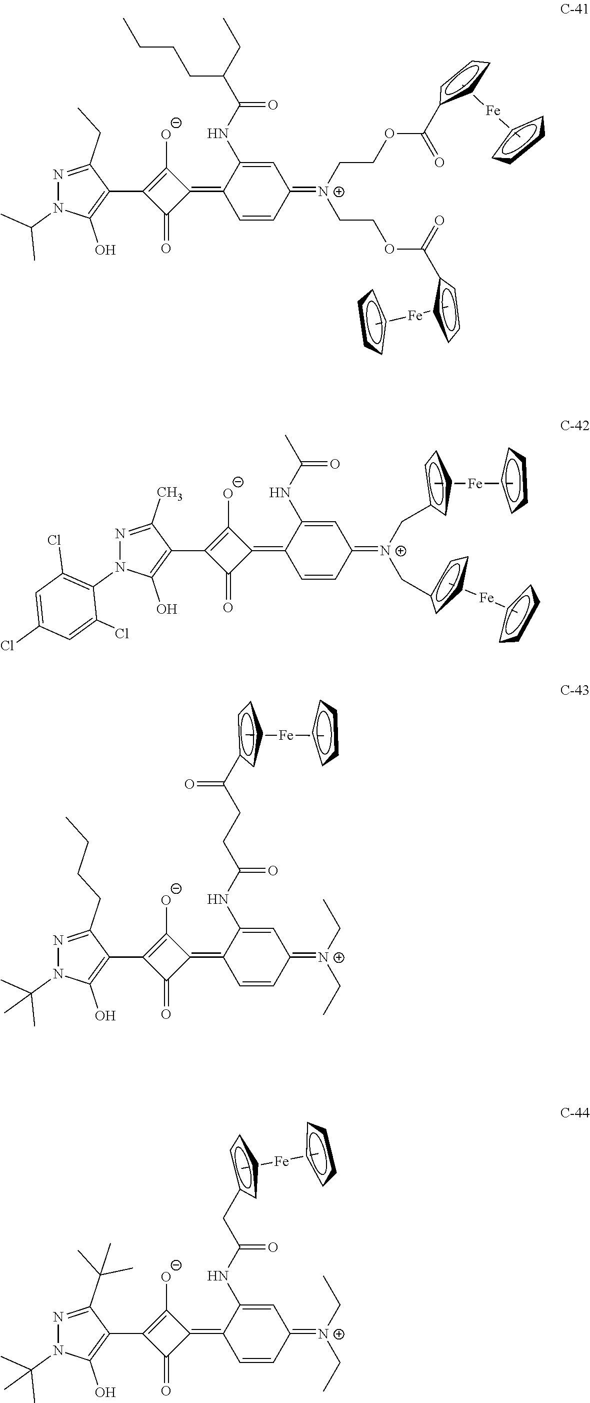

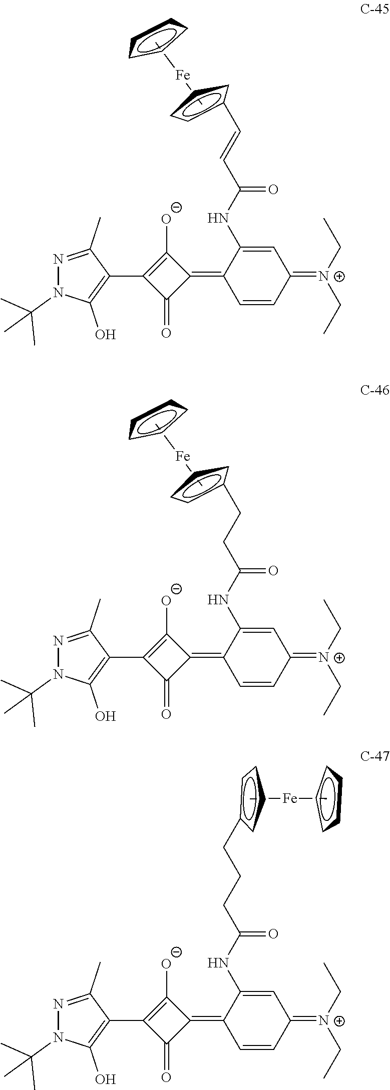

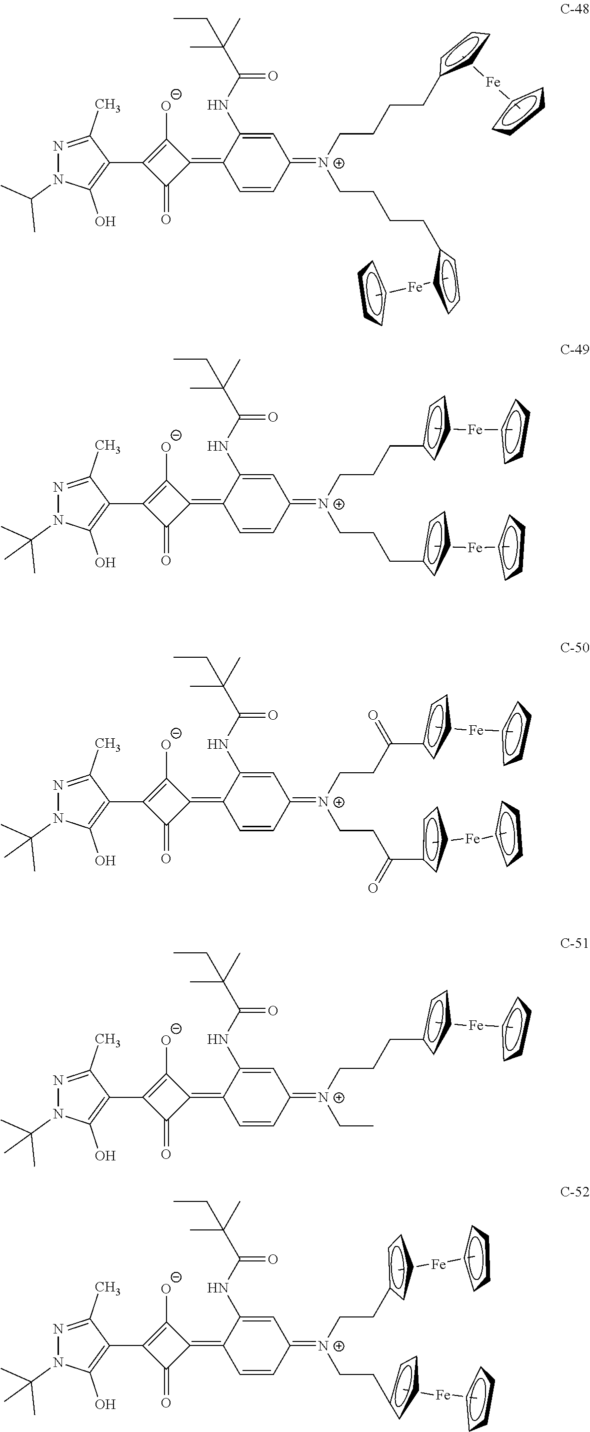

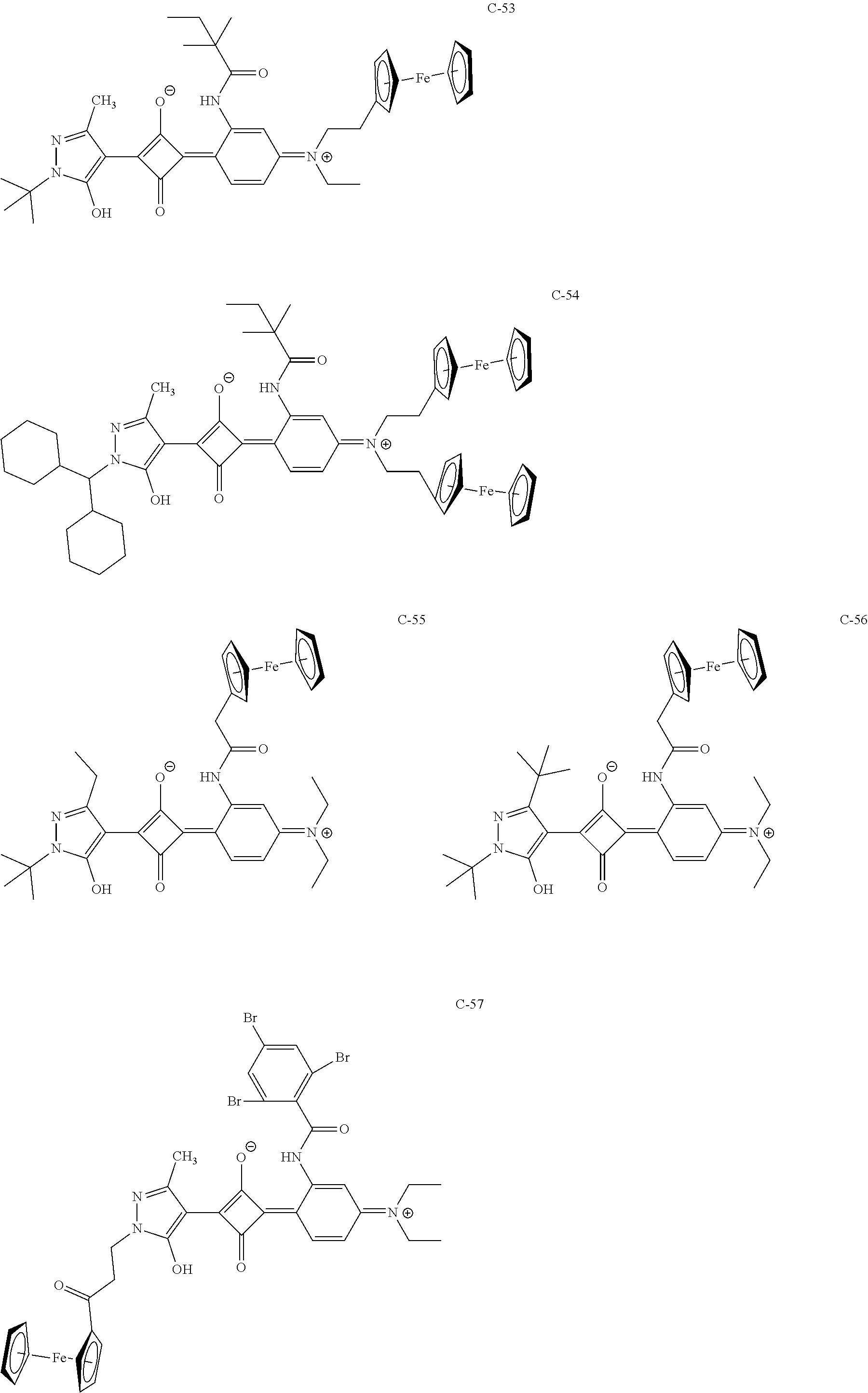

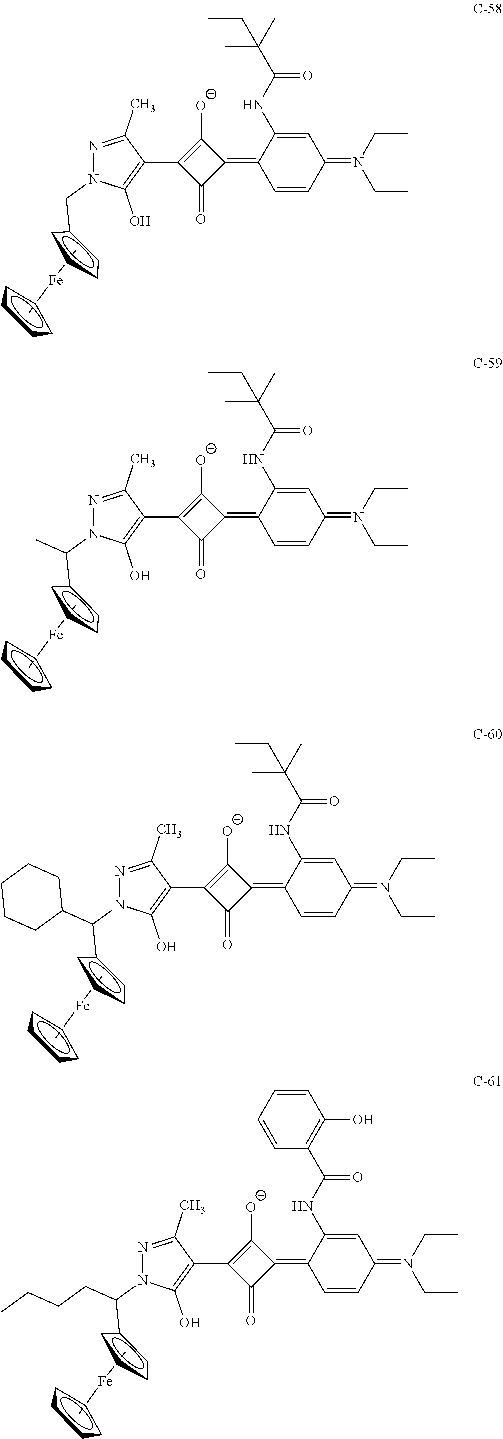

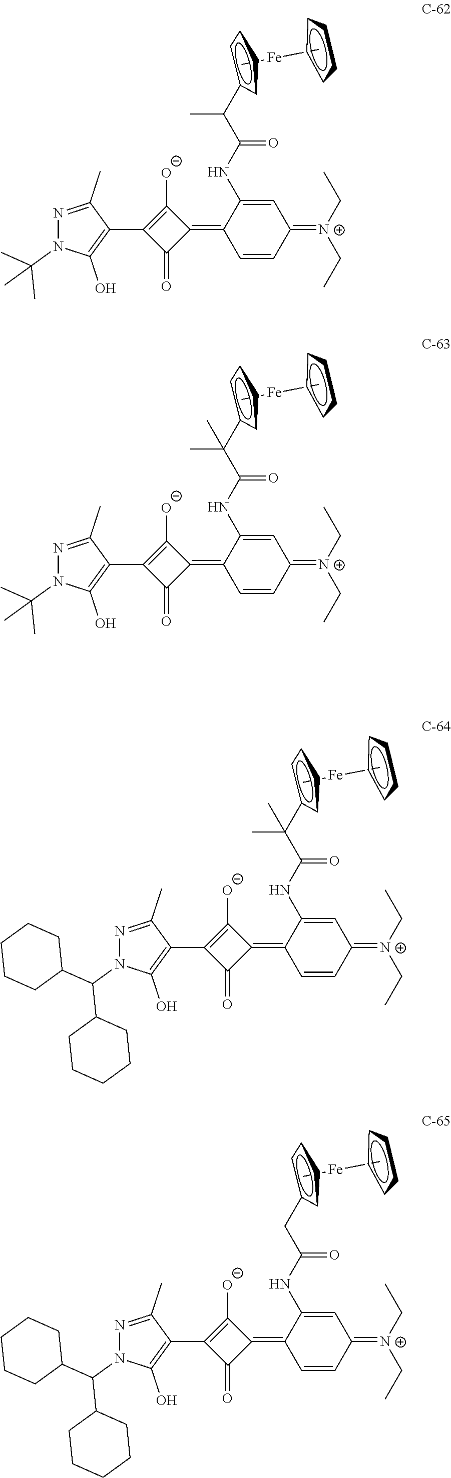

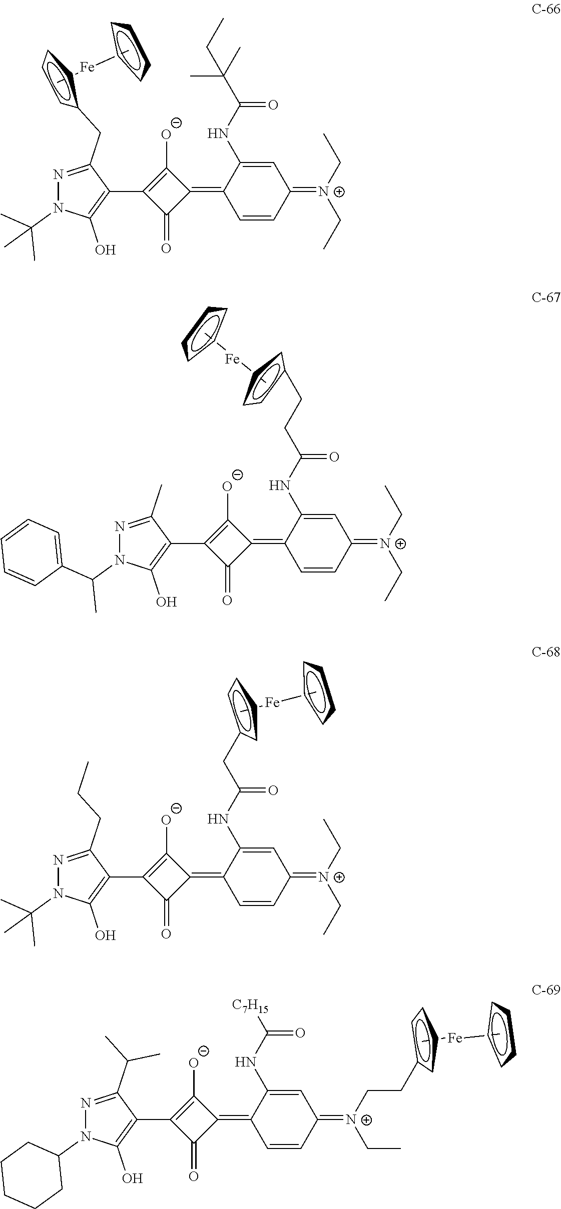

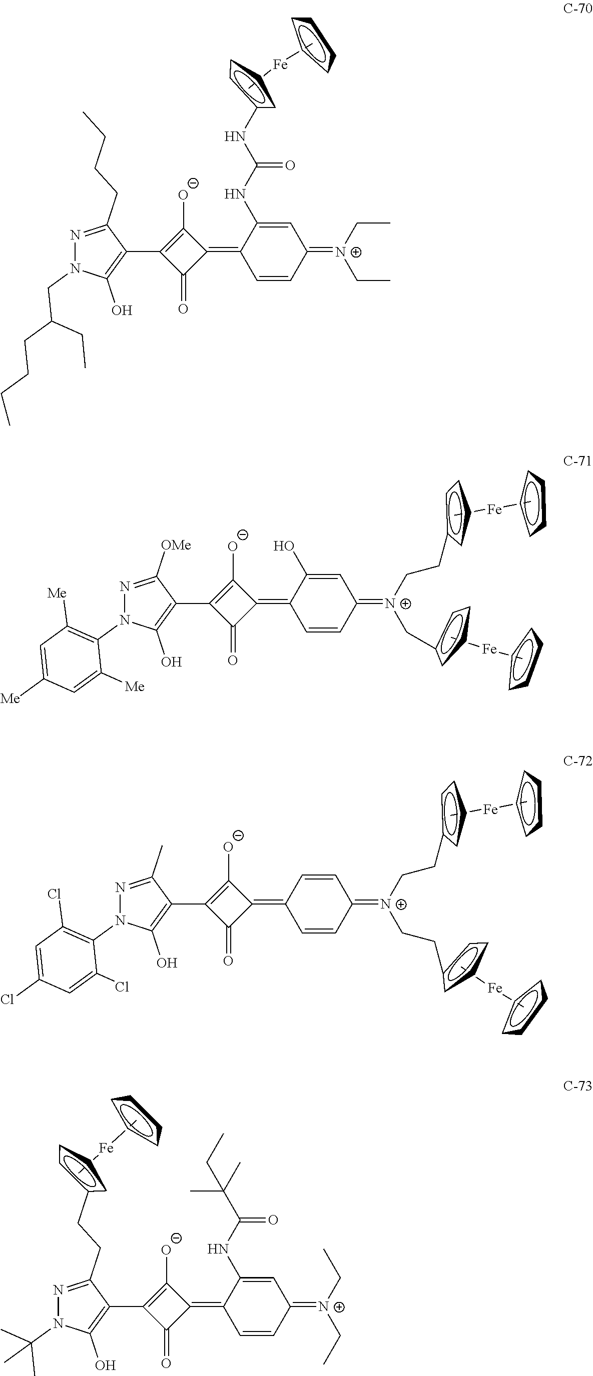

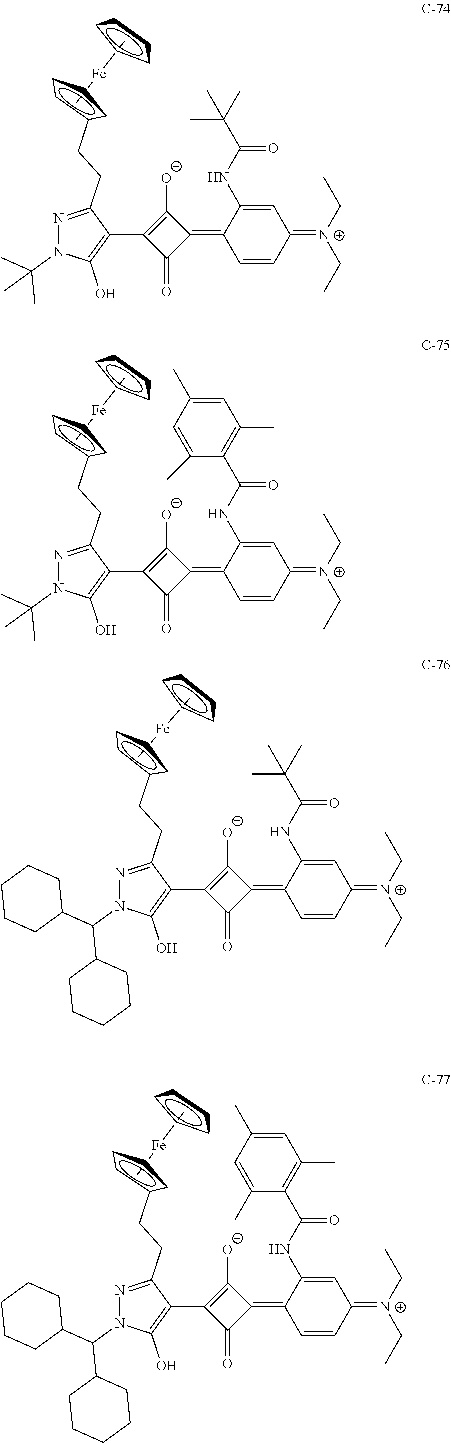

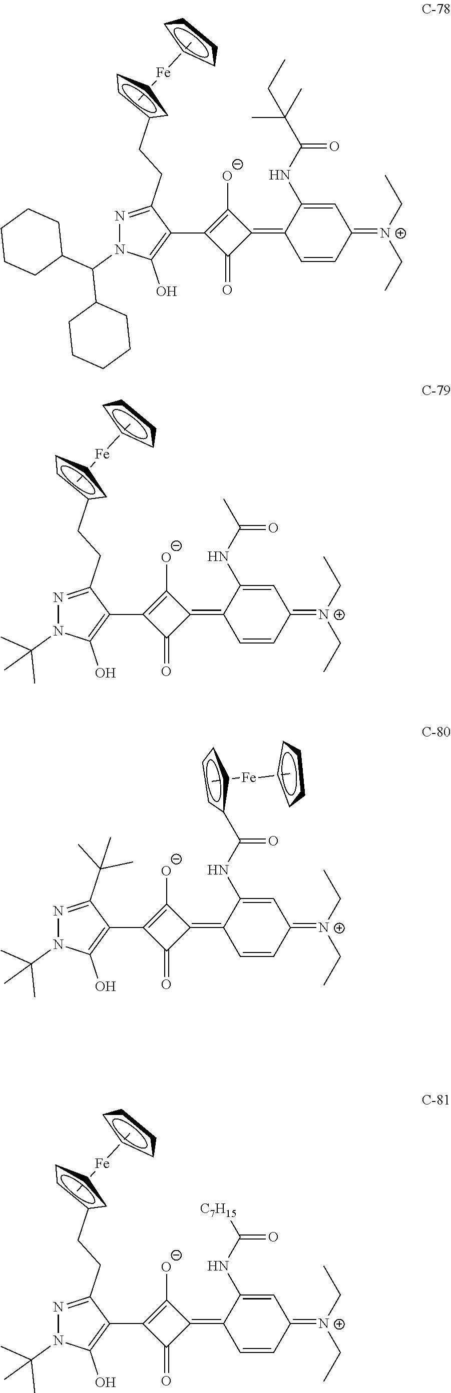

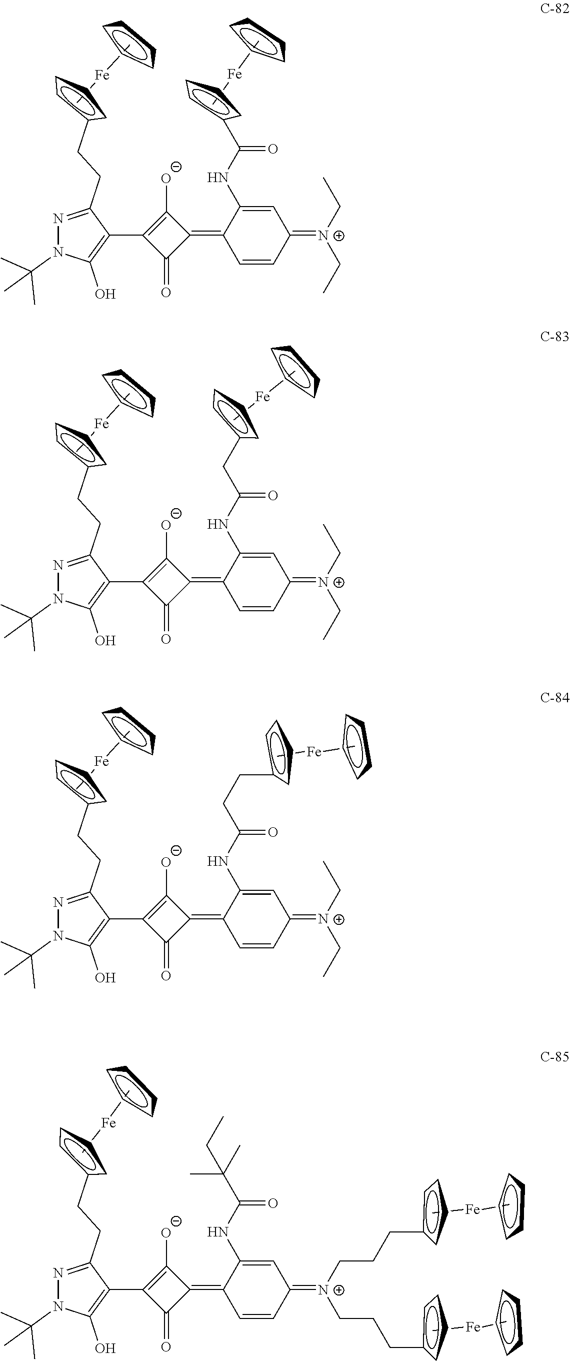

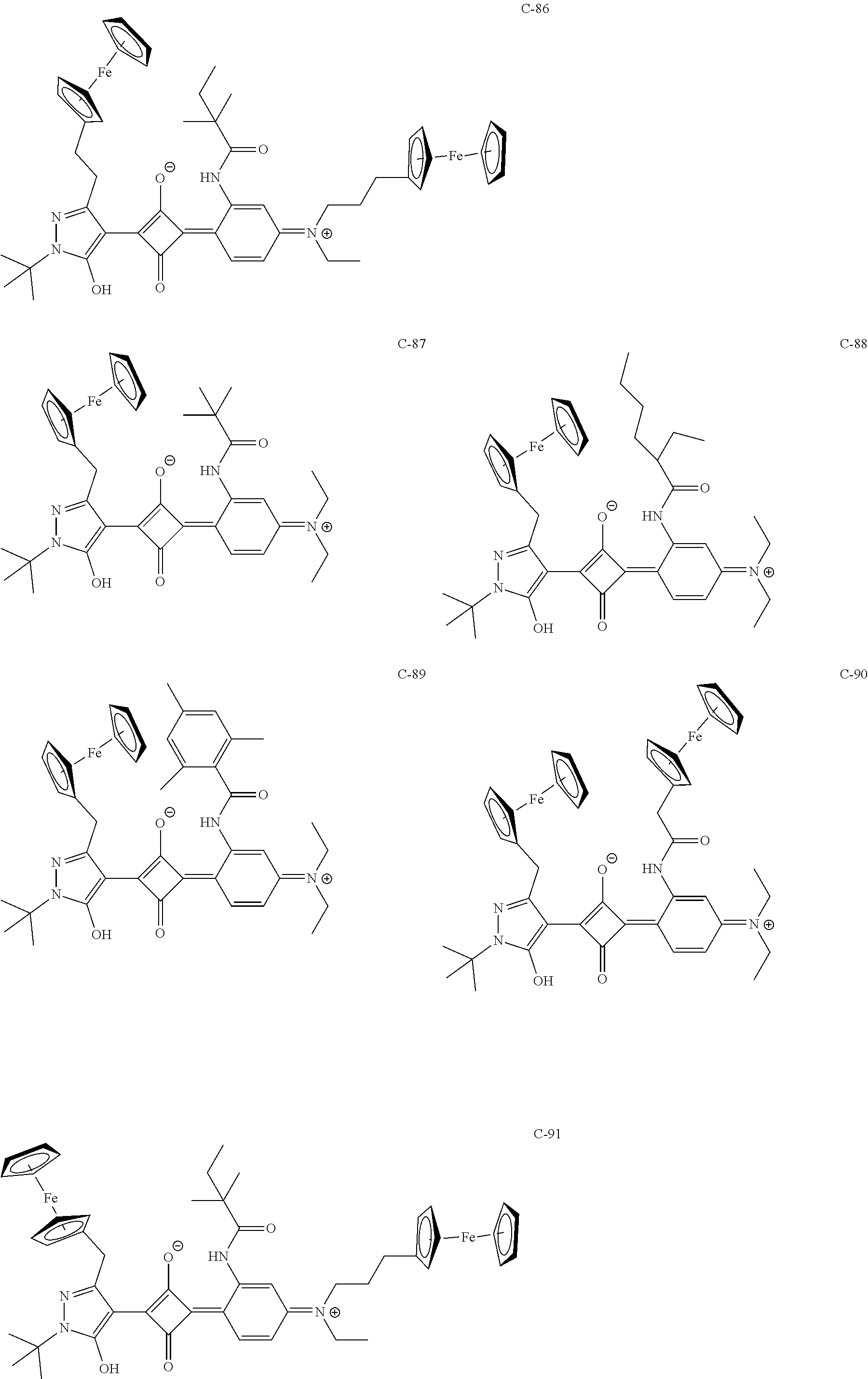

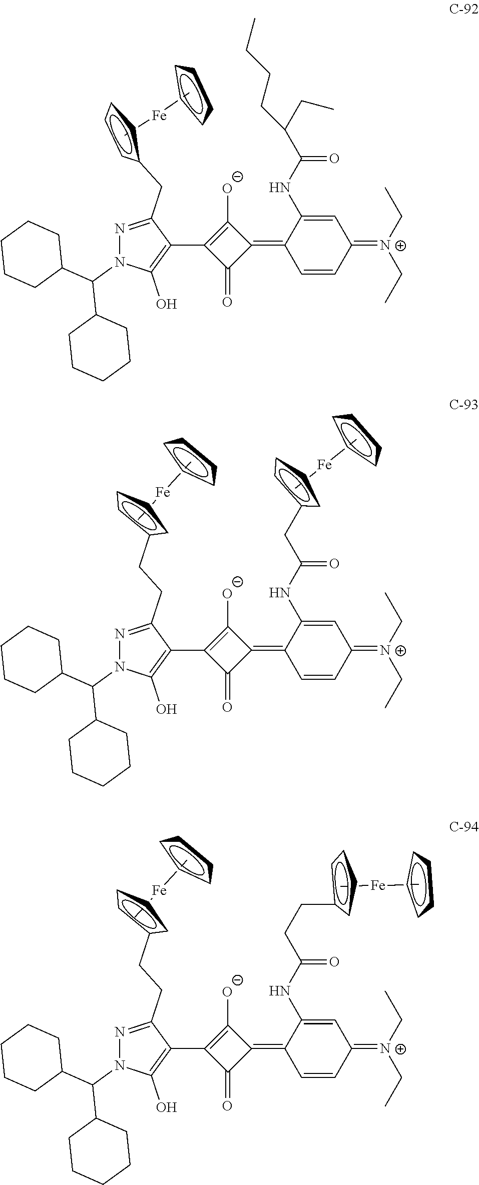

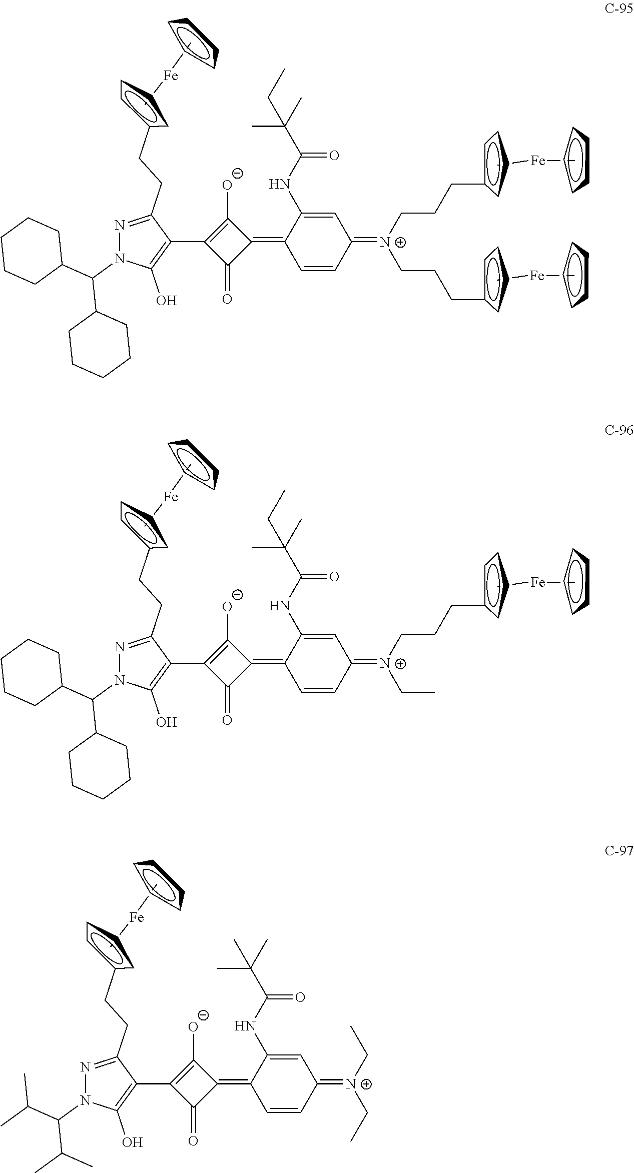

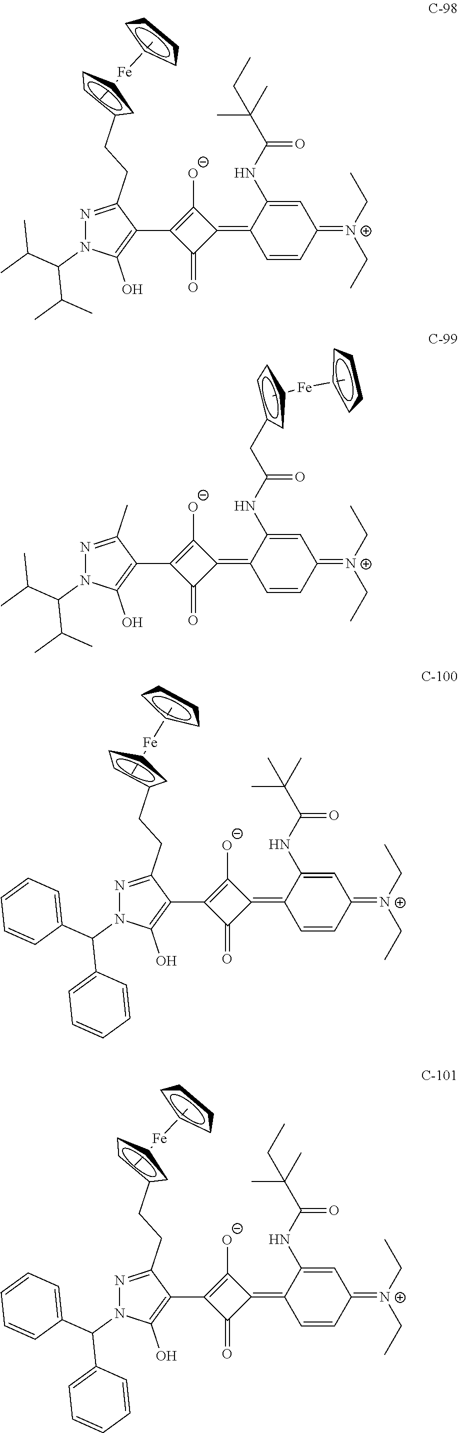

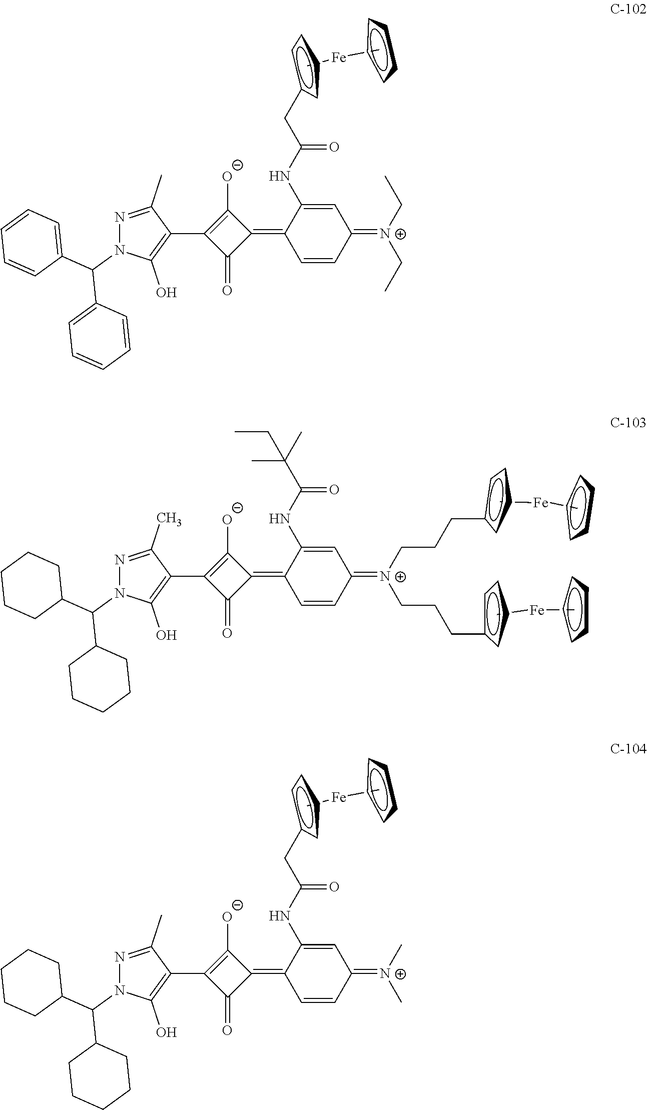

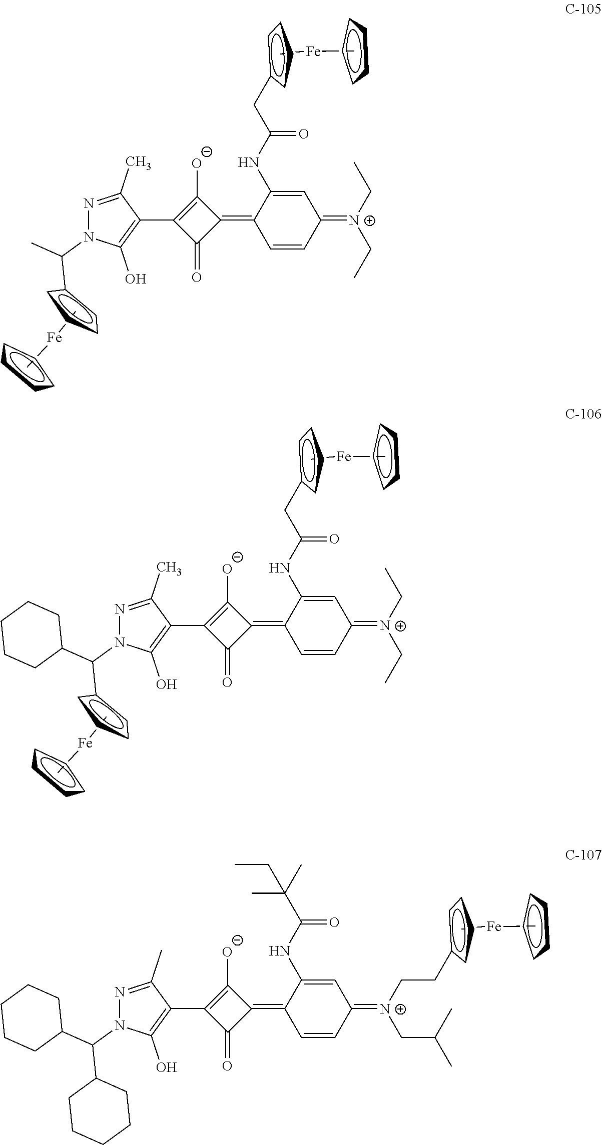

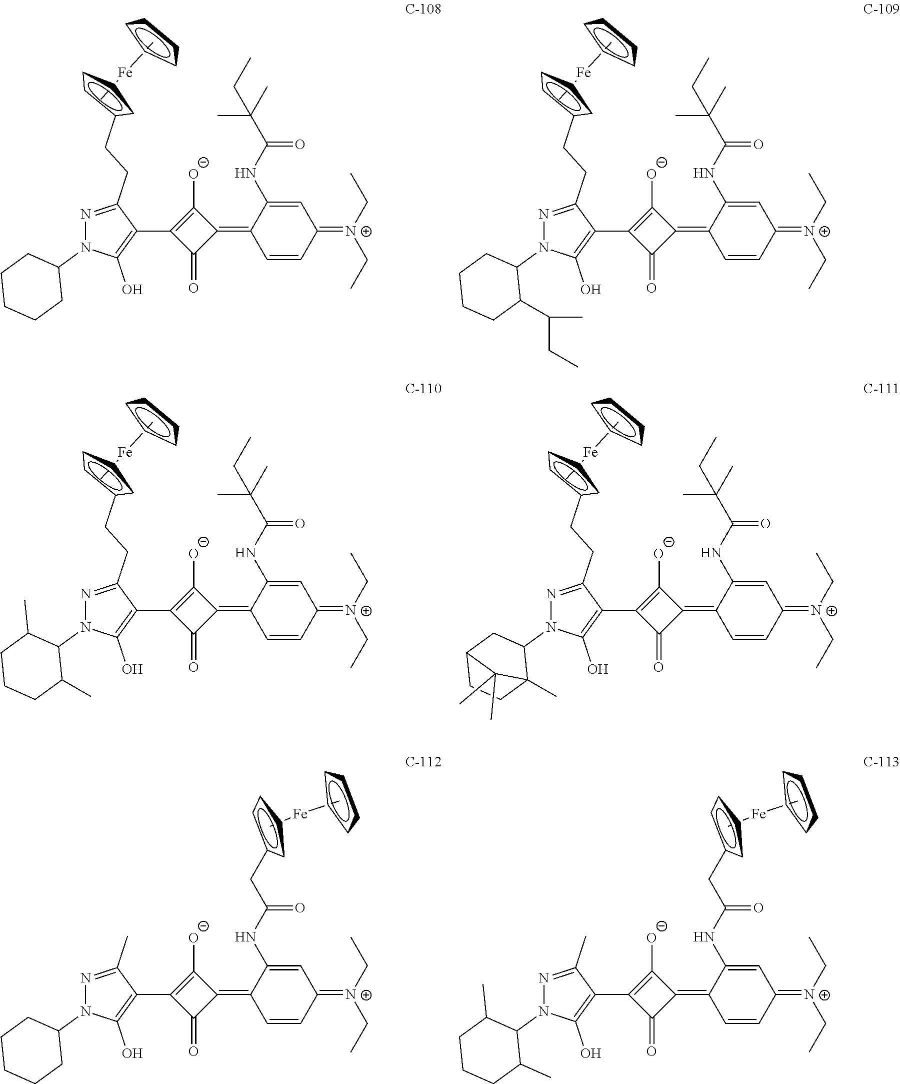

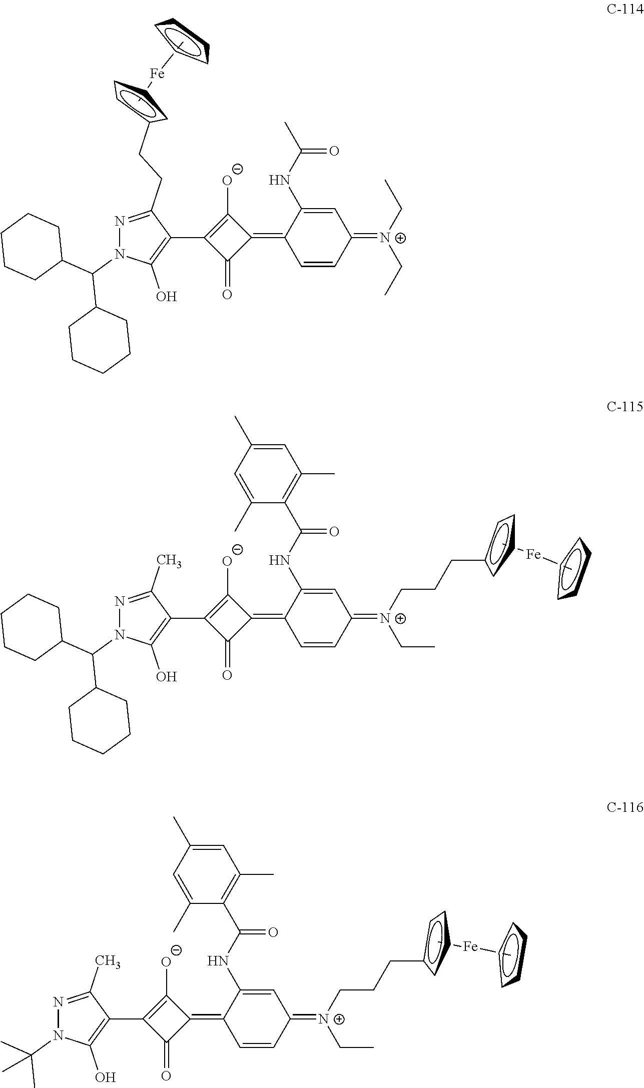

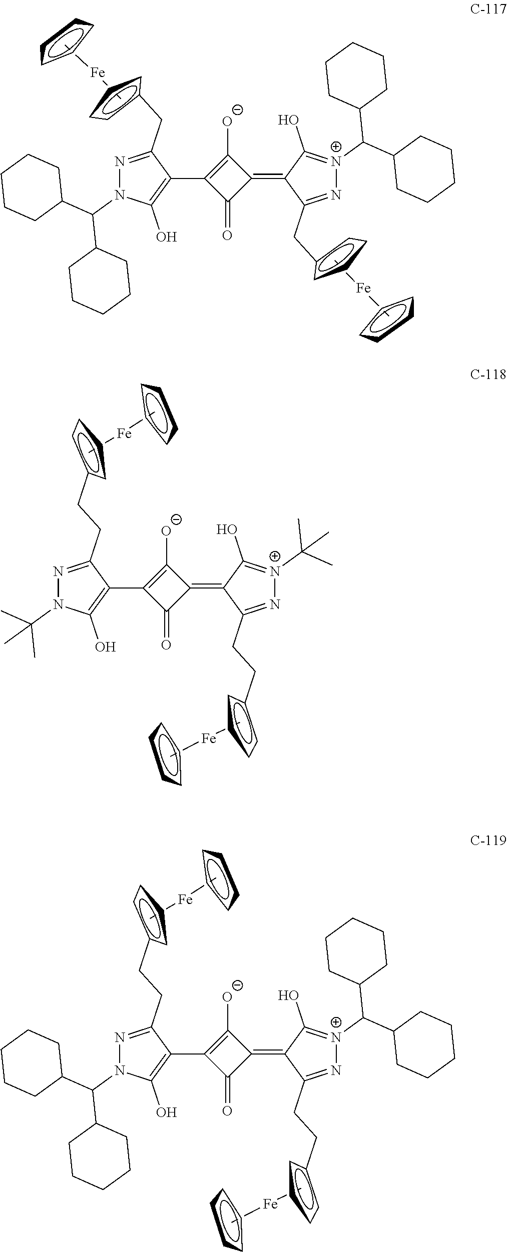

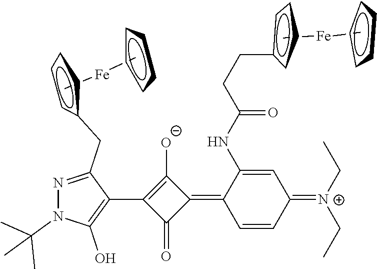

The total content of the dyes A to C in the wavelength selective absorption layer is not particularly limited as long as the effect of the present invention is exhibited, and it is preferably 0.01% by mass or more, more preferably 0.05% by mass or more, still more preferably 0.10% by mass or more, particularly preferably 0.15% by mass or more, especially preferably 0.20% by mass or more, and most preferably 1.0% by mass or more. In a case where the total content of the dyes A to C in the wavelength selective absorption layer is equal to or larger than the above-described preferred lower limit value, a good antireflection effect can be obtained.

In addition, from the viewpoint of suppressing a decrease in brightness and suppressing a change in tint, the total content of the dyes A to C in the wavelength selective absorption layer is generally 70% by mass or less, and it is preferably 50% by mass or less, more preferably 40% by mass or less, still more preferably 20% by mass or less, and particularly preferably 10% by mass or less.

The content of each of the dyes A to C that can be contained in the wavelength selective absorption layer is preferably as follows.

The content of the dye A in the wavelength selective absorption layer is preferably 0.01% to 45% by mass, more preferably 0.1% to 30% by mass, still more preferably 0.5% to 10% by mass, and particularly preferably 0.5% to 5% by mass.

The content of the dye B in the wavelength selective absorption layer is preferably 0.01% to 45% by mass, more preferably 0.1% to 30% by mass, still more preferably 0.1% to 10% by mass, and particularly preferably 0.1% to 5% by mass.

The content of the dye C in the wavelength selective absorption layer is preferably 0.01% to 30% by mass, more preferably 0.1% to 25% by mass, still more preferably 0.5% to 10% by mass, and particularly preferably 0.5% to 5% by mass.

The content proportion between the dyes A to C in the wavelength selective absorption layer is preferably 1:0.01 to 10:0.05 to 20 and more preferably 1:0.1 to 5:0.1 to 10 in terms of a mass ratio of the dye A:the dye B:the dye C.

It is noted that in a case where at least one of the dye B or C is a quencher-embedded coloring agent, the content of the quencher-embedded coloring agent in the wavelength selective absorption layer is preferably 0.1% by mass or more from the viewpoint of suppressing external light reflection. The upper limit value thereof is preferably 45% by mass or less.

<Resin>

The resin contained in the wavelength selective absorption layer (hereinafter, also referred to as a “matrix resin”) is not particularly limited as long as it can disperse (preferably dissolve) the above-described dye. In addition, in a case where the wavelength selective absorption layer contains an antifading agent for a dye described later, the resin contained in the wavelength selective absorption layer is not particularly limited as long as it can disperse (preferably dissolve) the antifading agent for this dye to be described later, and can suppress the decrease in light resistance of the dye due to the antifading agent. It is preferable that it is possible to satisfy the suppression of external light reflection and the suppression of a decrease in brightness, and moreover, it is possible to suppress a change in the tint of the reflected light at an excellent level (maintain the original tint of the image of the self-luminous display device at an excellent level).

In a case where at least one of the dye B or C is a squarine-based coloring agent represented by General Formula (1), the matrix resin is preferably a low-polarity matrix resin in which the squarine-based coloring agent can exhibit sharper absorption. In a case where the squarine-based coloring agent exhibits a sharper absorption, it is possible to satisfy Relational Expression (I) at a preferred level, and it is possible to achieve both antireflection and suppression of decrease in brightness at a more excellent level while suppressing a change in the tint of the reflected light. Here, the low polarity means that an fd value defined by Relational Expression α is preferably 0.50 or more.

fd=δd/(δd+δp+δh) Relational Expression α

In Relational Expression α, δd, δp, and δh respectively indicate a term corresponding to a London dispersion force, a term corresponding to a dipole-dipole force, and a term corresponding to a hydrogen bonding force with respect to a solubility parameter δt calculated according to the Hoy method. A specific calculation method of fd will be described later. That is, fd indicates a ratio of δd to the sum of δd, δp, and δh.

In a case where the fd value is set to 0.50 or more, a sharper absorption waveform can be easily obtained.

Further, in a case where the wavelength selective absorption layer contains two or more matrix resins, the fd value is calculated as follows.

fd=Σ(wᵢ·fdᵢ)

Here, wᵢ represents the mass fraction of the i-th matrix resin, and fdᵢ represents the fd value of the i-th matrix resin.

-Term δd Corresponding to London Dispersion Force-

The term δd corresponding to the London dispersion force refers to δd obtained for the Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

-Term δp Corresponding to Dipole-Dipole Force-

The term δp corresponding to the dipole-dipole force refers to δp obtained for Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

-Term δh Corresponding to Hydrogen Bonding Force-

The term δh corresponding to the hydrogen bonding force refers to δh obtained for the Amorphous Polymers described in the column “2) Method of Hoy (1985, 1989)” on pages 214 to 220 of the document “Properties of Polymers 3^{rd}, ELSEVIER, (1990)”, and is calculated according to the description in the column of the document.

In addition, in a case where the matrix resin is a resin exhibiting a certain hydrophobicity, the moisture content of the wavelength selective absorption layer can be set to a low moisture content, for example, 0.5% or lower, which is preferable in terms of improving the light resistance of the wavelength selective absorption layer.

The resin may contain any conventional component in addition to a polymer. However, the fd of the matrix resin is a calculated value for the polymer constituting the matrix resin.

Preferred examples of the matrix resin include a polystyrene resin and a cyclic polyolefin resin, and the polystyrene resin is more preferable. In general, the fd value of the polystyrene resin is 0.45 to 0.60, and the fd value of the cyclic polyolefin resin is 0.45 to 0.70. As described above, it is preferable to use the resin having an fd value of 0.50 or more.

Further, for example, in addition to these preferable resins, it is also preferable to use a resin component that imparts functionality to the wavelength selective absorption layer, such as an extensible resin component and a peelability control resin component, which will be described later. That is, in the present invention, the matrix resin is used in the meaning of including the extensible resin component and the peelability control resin component in addition to the above-described resins.

It is preferable that the matrix resin includes a polystyrene resin in terms of sharpening the absorption waveform of the coloring agent.

(Polystyrene Resin)

The polystyrene contained in the polystyrene resin means a polymer containing a styrene component. The polystyrene preferably contains 50% by mass or more of the styrene component. The wavelength selective absorption layer may contain one kind of polystyrene or two or more kinds thereof. Here, the styrene component is a structural unit derived from a monomer having a styrene skeleton in the structure thereof.

The polystyrene more preferably contains 70% by mass or more of the styrene component, and still more preferably 85% by mass or more of the styrene component, in terms of controlling the photo-elastic coefficient and the hygroscopicity to values in ranges preferable for the wavelength selective absorption layer. It is also preferable that the polystyrene is composed of only a styrene component.

Among polystyrenes, examples of the polystyrene composed of only the styrene component include a homopolymer of a styrene compound and a copolymer of two or more kinds of styrene compounds. Here, the styrene compound is a compound having a styrene skeleton in the structure thereof and is meant to include, in addition to styrene, a compound in which a substituent is introduced within a range where an ethylenically unsaturated bond of styrene can act as a reactive (polymerizable) group.

Specific examples of the styrene compound include the following styrenes: alkylstyrene such as α-methylstyrene, o-methylstyrene, m-methylstyrene, p-methylstyrene, 3,5-dimethylstyrene, 2,4-dimethylstyrene, o-ethylstyrene, p-ethylstyrene, and tert-butyl styrene; and substituted styrene having a hydroxy group, an alkoxy group, a carboxy group, or a halogen atom introduced into the benzene nucleus of styrene, such as hydroxystyrene, tert-butoxy styrene, vinyl benzoic acid, o-chlorostyrene, and p-chlorostyrene. Among these, the polystyrene is preferably a homopolymer of styrene (that is, polystyrene) from the viewpoints of availability and material cost.

The constitutional component other than the styrene component that may be contained in the polystyrene is not particularly limited. That is, the polystyrene may be a styrene-diene copolymer, a styrene-polymerizable unsaturated carboxylic acid ester copolymer, or the like. In addition, it is also possible to use a mixture of polystyrene and synthetic rubber (for example, polybutadiene and polyisoprene). Further, high impact polystyrene (HIPS) obtained by subjecting styrene to graft polymerization with synthetic rubber is also preferable. Further, a polystyrene obtained by dispersing a rubber-like elastic body in a continuous phase of a polymer including a styrene component (for example, a copolymer of a styrene component and a (meth)acrylate ester component), and subjecting the copolymer to graft polymerization with a rubber-like elastic body (referred to as graft type high impact polystyrene “graft HIPS”) is also preferable. Furthermore, a so-called styrene-based elastomer can also be suitably used.

In addition, the polystyrene may be hydrogenated (may be a hydrogenated polystyrene). The hydrogenated polystyrene is not particularly limited, and it is preferably a hydrogenated styrene-diene-based copolymer such as a hydrogenated styrene-butadiene-styrene block copolymer (SEBS) obtained by hydrogenating a styrene-butadiene-styrene block copolymer (SBS) or hydrogenated styrene-isoprene-styrene block copolymer (SEPS) obtained by hydrogenating a styrene-isoprene-styrene block copolymer (SIS). Only one of these hydrogenated polystyrenes may be used, or two or more thereof may be used.

In addition, the polystyrene may be modified polystyrene. The modified polystyrene is not particularly limited, and examples thereof include polystyrene having a reactive group such as a polar group introduced therein. Specific examples thereof preferably include acid-modified polystyrene such as maleic acid-modified and epoxy-modified polystyrene.

As the polystyrene, a plurality of kinds of polystyrene resins having different compositions, molecular weights, and the like may be used in combination.

The polystyrene-based resin can be obtained using method, for example, an anion, bulk, suspension, emulsification, or solution polymerization method. In addition, in the polystyrene, at least a part of the unsaturated double bond of the benzene ring of the conjugated diene and the styrene monomer may be hydrogenated. The hydrogenation rate can be measured by a nuclear magnetic resonance apparatus (NMR).

As the polystyrene resin, a commercially available product may be used, and examples thereof include “CLEAREN 530L” and “CLEAREN 730L” manufactured by Denki Kagaku Kogyo Kabushiki Kaisha, “TUFPRENE 126S” and “ASAPRENE T411” manufactured by Asahi Kasei Corporation, “KRATON D1102A”, “KRATON D1116A” manufactured by Kraton Polymers Japan Ltd., “STYROLUX S” and “STYROLUX T” manufactured by Styrolution Group, “ASAFLEX 840” and “ASAFLEX 860” manufactured by Asahi Kasei Chemicals Corporation (all are SBS), “679”, “H1F77”, and “SGP-10” manufactured by PS Japan Corporation, “DIC STYRENE XC-515” and “DIC STYRENE XC-535” manufactured by DIC Corporation (all are GPPS), “475D”, “H0103”, and “HT478” manufactured by PS Japan Corporation, and “DIC STYRENE GH-8300-5” manufactured by DIC Corporation (all are HIPS). Examples of the hydrogenated polystyrene-based resin include “TUFTEC H series” manufactured by Asahi Kasei Chemicals Corporation, and “KRATON G series” manufactured by Shell Japan Ltd. (all are SEBS), “DYNARON” manufactured by JSR Corporation (hydrogenated styrene-butadiene random copolymer), and “SEPTON” manufactured by Kuraray Co., Ltd. (SEPS). Examples of the modified polystyrene-based resin include “TUFTEC M series” manufactured by Asahi Kasei Chemicals Corporation, “EPOFRIEND” manufactured by Daicel Corporation, “Polar Group Modified DYNARON” manufactured by JSR Corporation, and “RESEDA” manufactured by ToaGosei Co., Ltd.

The wavelength selective absorption layer preferably contains a polyphenylene ether resin in addition to the polystyrene resin. By containing the polystyrene resin and the polyphenylene ether resin together, the toughness of the wavelength selective absorption layer can be improved, and the occurrence of defects such as cracks can be suppressed even in a harsh environment such as high temperature and high humidity.

As the polyphenylene ether resin, ZYLON S201A, ZYLON 202A, ZYLON S203A, and the like, manufactured by Asahi Kasei Corporation, can be preferably used. In addition, a resin in which the polystyrene resin and the polyphenylene ether resin are mixed in advance may also be used. As the mixed resin of the polystyrene resin and the polyphenylene ether resin, for example, ZYLON 1002H, ZYLON 1000H, ZYLON 600H, ZYLON 500H, ZYLON 400H, ZYLON 300H, ZYLON 200H, and the like manufactured by Asahi Kasei Corporation can be preferably used.

In a case where the polystyrene resin and the polyphenylene ether resin are contained in the wavelength selective absorption layer, the mass ratio of both resins is preferably 99/1 to 50/50, more preferably 98/2 to 60/40, and still more preferably 95/5 to 70/30, in terms of the polystyrene resin/polyphenylene ether resin. In a case where the formulation ratio of the polyphenylene ether resin is set in the above-described preferred range, the wavelength selective absorption layer can have sufficient toughness, and a solvent can be appropriately volatilized in a case where a film formation is carried out with a solution.

(Cyclic Polyolefin Resin)

The cyclic olefin compound that forms the cyclic polyolefin contained in the cyclic polyolefin resin is not particularly limited as long as the compound has a ring structure including a carbon-carbon double bond, and examples thereof include a norbornene compound and a monocyclic olefin compound, a cyclic conjugated diene compound, and a vinyl alicyclic hydrocarbon compound, which are not the norbornene compound.

Examples of the cyclic polyolefin include (1) polymers including a structural unit derived from a norbornene compound; (2) polymers including a structural unit derived from a monocyclic olefin compound other than the norbornene compound; (3) polymers including a structural unit derived from a cyclic conjugated diene compound; (4) polymers including a structural unit derived from a vinyl alicyclic hydrocarbon compound; and hydrides of polymers including a structural unit derived from each of the compounds (1) to (4).

In the present invention, ring-opening polymers of the respective compounds are included in the polymers including a structural unit derived from a norbornene compound and the polymers including a structural unit derived from a monocyclic olefin compound.

The cyclic polyolefin is not particularly limited; however, it is preferably a polymer having a structural unit derived from a norbornene compound, which is represented by General Formula (A-II) or (A-III). The polymer having the structural unit represented by General Formula (A-II) is an addition polymer of a norbornene compound, and the polymer having the structural unit represented by General Formula (A-III) is a ring-opening polymer of a norbornene compound.

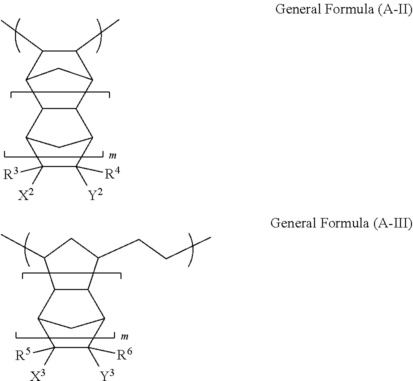

In General Formulae (A-II) and (A-III), m is an integer of 0 to 4, and preferably 0 or 1.

In General Formulae (A-II) and (A-III), R³ to R⁶ each independently represent a hydrogen atom or a hydrocarbon group having 1 to 10 carbon atoms.

The hydrocarbon group in General Formulae (A-I) to (A-III) is not particularly limited as long as the hydrocarbon group is a group consisting of a carbon atom and a hydrogen atom, and examples thereof include an alkyl group, an alkenyl group, an alkynyl group, and an aryl group (an aromatic hydrocarbon group). Among these, an alkyl group or an aryl group is preferable.

In General Formula (A-II) or (A-III), X² and X³, and Y² and Y³ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ or —(CH₂)ₙW, or (—CO)₂O or (—CO)₂NR¹⁵ which is formed by X² and Y² or X³ and Y³ being bonded to each other.

Here, R¹¹ to R¹⁵ each independently represent a hydrogen atom or a hydrocarbon group having 1 to 20 carbon atoms, Z represents a hydrocarbon group or a hydrocarbon group substituted with halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10, preferably 0 to 8, and more preferably 0 to 6.

In General Formulae (A-II) and (A-III), R³ to R⁶ are each preferably a hydrogen atom or —CH₃, and, in terms of moisture permeability, more preferably a hydrogen atom.

X² and X³ are each preferably a hydrogen atom, —CH₃, or —C₂H₅ and, in terms of moisture permeability, more preferably a hydrogen atom.

Y² and Y³ are each preferably a hydrogen atom, a halogen atom (particularly a chlorine atom), or —(CH₂)ₙCOOR¹¹ (particularly —COOCH₃) and, in terms of moisture permeability, more preferably a hydrogen atom.

Other groups are appropriately selected.

The polymer having the structural unit represented by General Formula (A-II) or (A-III) may further include at least one or more structural units represented by General Formula (A-I).

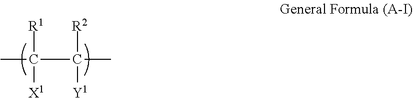

In General Formula (A-I), R¹ and R² each independently represent a hydrogen atom or a hydrocarbon group having 1 to 10 carbon atoms, and X¹ and Y¹ each independently represent a hydrogen atom, a hydrocarbon group having 1 to 10 carbon atoms, a halogen atom, a hydrocarbon group having 1 to 10 carbon atoms, which is substituted with a halogen atom, —(CH₂)ₙCOOR¹¹, —(CH₂)ₙOCOR¹², —(CH₂)ₙNCO, —(CH₂)ₙNO₂, —(CH₂)ₙCN, —(CH₂)ₙCONR¹³R¹⁴, —(CH₂)ₙNR¹³R¹⁴, —(CH₂)ₙOZ, —(CH₂)ₙW, or (—CO)₂O or (—CO)₂NR¹⁵ which is formed by X¹ and Y¹ being bonded to each other.

Here, R¹¹ to R¹⁵ each independently represent a hydrogen atom or a hydrocarbon group having 1 to 20 carbon atoms, Z represents a hydrocarbon group or a hydrocarbon group substituted with halogen, W represents Si(R¹⁶)ₚD₍₃₋ₚ₎ (R¹⁶ represents a hydrocarbon group having 1 to 10 carbon atoms, D represents a halogen atom, —OCOR¹⁷, or —OR¹⁷ (R¹⁷ represents a hydrocarbon group having 1 to 10 carbon atoms), and p is an integer of 0 to 3). n is an integer of 0 to 10.

From the viewpoint of adhesiveness, the content of the structural unit derived from a norbornene compound in the cyclic polyolefin having the structural unit represented by General Formula (A-II) or (A-III) is preferably 90% by mass or less, more preferably 30% to 85% by mass, still more preferably 50% to 79% by mass, and most preferably 60% to 75% by mass with respect to the total mass of the cyclic polyolefin. Here, the proportion of the structural unit derived from a norbornene compound represents the average value in the cyclic polyolefin.

The addition (co)polymer of a norbornene compound is described in JP1998-7732A (JP-H10-7732A), JP2002-504184A, US2004/229157A1A, and WO2004/070463A.

The polymer of a norbornene compound is obtained by the addition polymerization of norbornene compounds (for example, polycyclic unsaturated compounds of norbornene).

In addition, as the polymer of a norbornene compound, copolymers obtained by the addition copolymerization of, as necessary, a norbornene compound, olefin such as ethylene, propylene, and butene, conjugated diene such as butadiene and isoprene, unconjugated diene such as ethylidene norbornene, and an ethylenically unsaturated compound such as acrylonitrile, acrylic acid, methacrylic acid, maleic acid anhydride, acrylic acid ester, methacrylic acid ester, maleimide, vinyl acetate, and vinyl chloride are exemplified. Among these, a copolymer of a norbornene compound and ethylene is preferable.

Examples of the addition (co)polymers of a norbornene compound include APL8008T (Tg: 70° C.), APL6011T (Tg: 105° C.), APL6013T (Tg: 125° C.), and APL6015T (Tg: 145° C.), which are available from Mitsui Chemicals, Inc. under a product name of APEL and have glass transition temperatures (Tg) different from each other. In addition, pellets such as TOPAS8007, TOPAS6013, and TOPAS6015 are commercially available from Polyplastics Co., Ltd. Further, Appear 3000 is commercially available from Film Ferrania S. R. L.

As the polymer of a norbornene compound, a commercially available product can be used. For example, it is commercially available from JSR Corporation under a product name of Arton G or Arton F, and it is also commercially available from Zeon Corporation under a product name of Zeonor ZF14, ZF16, Zeonex 250, or Zeonex 280.

The hydride of a polymer of a norbornene compound can be synthesized by the addition polymerization or the metathesis ring-opening polymerization of a norbornene compound or the like and then the addition of hydrogen. The synthesis method is described in, for example, JP1989-240517A (JP-H1-240517A), JP1995-196736A (JP-H7-196736A), JP1985-26024A (JP-S60-26024A), JP1987-19801A (JP-S62-19801A), JP2003-159767A, and JP2004-309979A.

The molecular weight of the cyclic polyolefin is appropriately selected depending on the intended use, and it is a mass average molecular weight measured in terms of polyisoprene or polystyrene by the gel permeation chromatography of a cyclohexane solution (a toluene solution in a case where the polymer is not dissolved). It is preferable that the molecular weight is generally in a range of 5,000 to 500,000, preferably 8,000 to 200,000, and more preferably 10,000 to 100,000. A polymer having a molecular weight in the above-described range is capable of satisfying both the mechanical strength of a molded body and the molding workability of compacts at a high level in a well-balanced manner.

In the wavelength selective absorption layer, the content of the matrix resin is preferably 5% by mass or more, more preferably 20% by mass or more, still more preferably 50% by mass or more, and particularly preferably 60% by mass or more.

The content of the matrix resin in the wavelength selective absorption layer is generally 99.90% by mass or less and preferably 99.85% by mass or less.

The cyclic polyolefin contained in the wavelength selective absorption layer may be two or more kinds, and polymers that differ in at least one of the compositional ratio or the molecular weight may be used in combination. In this case, the total content of the respective polymers is in the above range.

(Extensible Resin Component)

The wavelength selective absorption layer can appropriately select and contain a component exhibiting extensibility (also referred to as an extensible resin component) as a resin component. Specific examples thereof include an acrylonitrile-butadiene-styrene resin (an ABS resin), a styrene-butadiene resin (an SB resin), an isoprene resin, a butadiene resin, a polyether-urethane resin, and a silicone resin. Further, these resins may be further hydrogenated as appropriate.

As the extensible resin component, it is preferable to use an ABS resin or an SB resin, and it is more preferable to use an SB resin.

As the SB resin, for example, a commercially available one can be used. Examples of such commercially available products include TR2000, TR2003, and TR2250 (all, product name, manufactured by JSR Corporation); CLEAREN 210M, 220M, and 730V (all, product name, manufactured by Denka Corporation); ASAFLEX 800S, 805, 810, 825, 830, and 840 (all, product name, manufactured by Asahi Kasei Corporation); and EPOREX SB2400, SB2610, and SB2710 (all, product name, Sumitomo Chemical Co., Ltd.).

The extensible resin component is preferably an extensible resin component having a breaking elongation of 10% or more and more preferably an extensible resin component having a breaking elongation of 20% or more, in a case where a sample having a form with a thickness of 30 m and a width of 10 mm is produced by using the extensible resin component alone and the breaking elongation at 25° C. is measured in accordance with JIS 7127.

(Peelability Control Resin Component)

The wavelength selective absorption layer can contain, as a resin component, a component that controls the peelability (a peelability control resin component) in a case of being produced according to a method including a step of peeling a wavelength selective absorption layer from a release film, among the manufacturing methods for a wavelength selective absorption layer described later, which is preferable. In a case of controlling the peelability of the wavelength selective absorption layer from the release film, it is possible to prevent a peeling mark from being left on the wavelength selective absorption layer after peeling, and it is possible to cope with various processing speeds in the peeling step. As a result, a preferred effect can be obtained for improving the quality and productivity of the wavelength selective absorption layer.

The peelability control resin component is not particularly limited and can be appropriately selected depending on the kind of the release film. In a case where a polyester-based polymer film is used as the release film as described later, for example, a polyester resin (also referred to as a polyester-based additive) is suitable as the peelability control resin component.

The polyester-based additive can be obtained by a conventional method such as a dehydration condensation reaction of a polyhydric basic acid and a polyhydric alcohol and an addition of a dibasic anhydride to a polyhydric alcohol and a dehydration condensation reaction, and a polycondensation ester formed from a dibasic acid and a diol is preferable.

The mass average molecular weight (Mw) of the polyester-based additive is preferably 500 to 50,000, more preferably 750 to 40,000, and still more preferably 2,000 to 30,000.

In a case where the mass average molecular weight of the polyester-based additive is equal to or larger than the above-described preferred lower limit value, it is preferable from the viewpoint of brittleness and moisture-heat resistance, and in a case where the mass average molecular weight thereof is equal to or smaller than the above-described preferred upper limit value, it is preferable from the viewpoint of compatibility with the resin.

The mass average molecular weight of the polyester-based additive is a value of the mass average molecular weight (Mw) in terms of standard polystyrene measured under the following conditions. The molecular weight distribution (Mw/Mn) can also be measured under the same conditions. Mn is a number average molecular weight in terms of standard polystyrene.

GPC: Gel permeation chromatograph device (HLC-8220GPC manufactured by Tosoh Corporation,

column: Guard column HXL-H manufactured by Tosoh Corporation, where TSK gel G7000HXL, TSK gel GMHXL 2 pieces, and TSK gel G2000HXL are connected in sequence,

eluent: tetrahydrofuran,

flow velocity: 1 mL/min,

sample concentration: 0.7% to 0.8% by mass,

sample injection volume: 70 μL,

measurement temperature: 40° C.,

detector: differential refractometer (RI) meter (40° C.), and

standard substance: TSK standard polystyrene manufactured by Tosoh Corporation)

Preferred examples of the dibasic acid component constituting the polyester-based additive include dicarboxylic acid.

Examples of the dicarboxylic acid include an aliphatic dicarboxylic acid and an aromatic dicarboxylic acid. An aromatic dicarboxylic acid or a mixture of an aromatic dicarboxylic acid and an aliphatic dicarboxylic acid can be preferably used.

Among the aromatic dicarboxylic acids, an aromatic dicarboxylic acid having 8 to 20 carbon atoms is preferable, and an aromatic dicarboxylic acid having 8 to 14 carbon atoms is more preferable. Specifically, preferred examples thereof include at least one of phthalic acid, isophthalic acid, or terephthalic acid.

Among the aliphatic dicarboxylic acids, an aliphatic dicarboxylic acid having 3 to 8 carbon atoms is preferable, and an aliphatic dicarboxylic acid having 4 to 6 carbon atoms is more preferable. Specifically, preferred examples thereof include at least one of succinic acid, maleic acid, adipic acid, or glutaric acid, and at least one of succinic acid or adipic acid is more preferable.

Examples of the diol component constituting the polyester-based additive include an aliphatic diol and an aromatic diol, and aliphatic diol is preferable.

Among the aliphatic diols, an aliphatic diol having 2 to 4 carbon atoms is preferable, and an aliphatic diol having 2 to 3 carbon atoms is more preferable.

Examples of the aliphatic diol include ethylene glycol, diethylene glycol, 1,2-propylene glycol, 1,3-propylene glycol, 1,3-butylene glycol, and 1,4-butylene glycol. These aliphatic diols can be used alone, or two or more kinds thereof can be used in combination.

The polyester-based additive is particularly preferably a compound obtained by fusing at least one of phthalic acid, isophthalic acid, or terephthalic acid with an aliphatic diol.

The terminal of the polyester-based additive may be sealed by reacting with a monocarboxylic acid. The monocarboxylic acid that is used for sealing is preferably an aliphatic monocarboxylic acid. Preferred examples thereof include acetic acid, propionic acid, butanoic acid, benzoic acid, and a derivative thereof, where acetic acid or propionic acid is more preferable and acetic acid is still more preferable.

Examples of the commercially available polyester-based additive include ester-based resin polyesters manufactured by Nippon Synthetic Chemical Industry Co., Ltd. (for example, LP050, TP290, LP035, LP033, TP217, and TP220) and ester-based resins Byron manufactured by Toyobo Co., Ltd. (for example, Byron 245, Byron GK890, Byron 103, Byron 200, and Byron 550. GK880).

The content of the peelability control resin component in the wavelength selective absorption layer is preferably 0.05% by mass or more, and more preferably 0.1% by mass or more in the matrix resin. In addition, the upper limit value thereof is preferably 25% by mass or less, more preferably 20% by mass or less, and still more preferably 15% by mass or less. From the viewpoint of obtaining proper adhesiveness, the above-described preferred range is preferable.

<Antifading Agent>

The wavelength selective absorption layer preferably contains the antifading agent for a dye (simply also referred to as an antifading agent) in order to prevent the fading of the dye including the dyes A to C.

As the antifading agent, it is possible to use commonly used antifading agents without particular limitation, such as the antioxidants described in paragraphs [0143] to [0165] of WO2015/005398A, the radical scavengers described in paragraphs [0166] to [0199] of WO2015/005398A, and the deterioration preventing agents described in paragraphs [0205] to [0206] of WO2015/005398A.

The compound represented by General Formula (IV) below can be preferably used as the antifading agent.

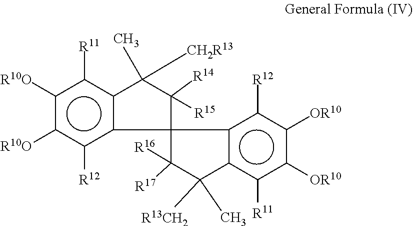

In General Formula (IV), R¹⁰ represents an alkyl group, an alkenyl group, an aryl group, a heterocyclic group, or a group represented by R¹⁸CO—, R¹⁹SO₂— or R²⁰NHCO—. Here, R¹⁸, R¹⁹, and R²⁰ each independently represent an alkyl group, an alkenyl group, an aryl group, or a heterocyclic group. R¹¹ and R¹² each independently represent a hydrogen atom, a halogen atom, an alkyl group, an alkenyl group, an alkoxy group, or an alkenyloxy group, and R¹³, R¹⁴, R¹⁵, R¹⁶, and R¹⁷ each independently represent a hydrogen atom, an alkyl group, an alkenyl group, or an aryl group.

However, the alkyl group in R¹⁰ to R²⁰ includes an aralkyl group.

Examples of the alkyl group represented by R¹⁰ in General Formula (IV) include methyl, ethyl, propyl, and benzyl; examples of the alkenyl group include allyl; examples of the aryl group include phenyl; and examples of the heterocyclic group include tetrahydropyranyl and pyrimidyl. R¹⁸, R¹⁹, and R²⁰ each independently represent an alkyl group (for example, methyl, ethyl, n-propyl, n-butyl, or benzyl), an alkenyl group (for example, allyl), an aryl group (for example, phenyl, or methoxyphenyl), or a heterocyclic group (for example, pyridyl, or pyrimidyl).

Examples of the halogen atom represented by R¹¹ and R¹² in General Formula (IV) include chlorine and bromine; examples of the alkyl group include methyl, ethyl, n-butyl, and benzyl; examples of the alkenyl group include allyl; examples of the alkoxy group include methoxy, ethoxy, and benzyloxy; and examples of the alkenyloxy group include 2-propenyloxy.

Examples of the alkyl group represented by R¹³, R¹⁴, R¹⁵, R¹⁶, and R¹⁷ in General Formula (IV) include methyl, ethyl, n-butyl, and benzyl; examples of the alkenyl group include 2-propenyl; and examples of the aryl group include phenyl, methoxyphenyl, and chlorophenyl.

R¹⁰ to R²⁰ may further have a substituent, and examples of the substituent include each group represented by R¹⁰ to R²⁰.

Specific examples of the compound represented by General Formula (IV) are shown below. However, the present invention is not limited thereto.

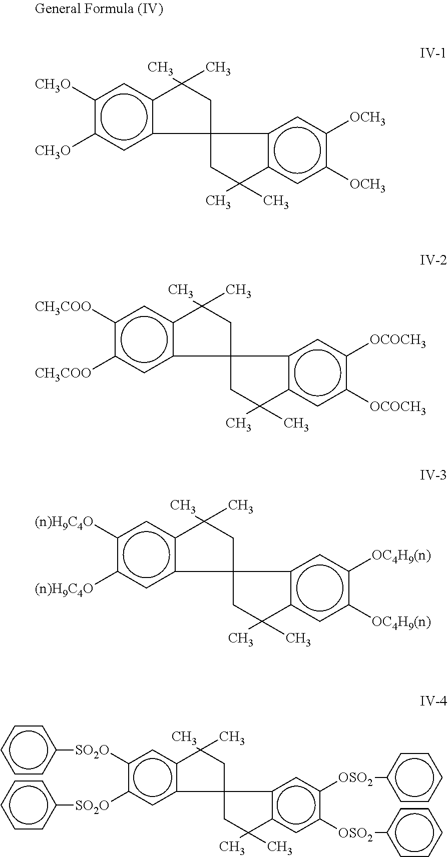

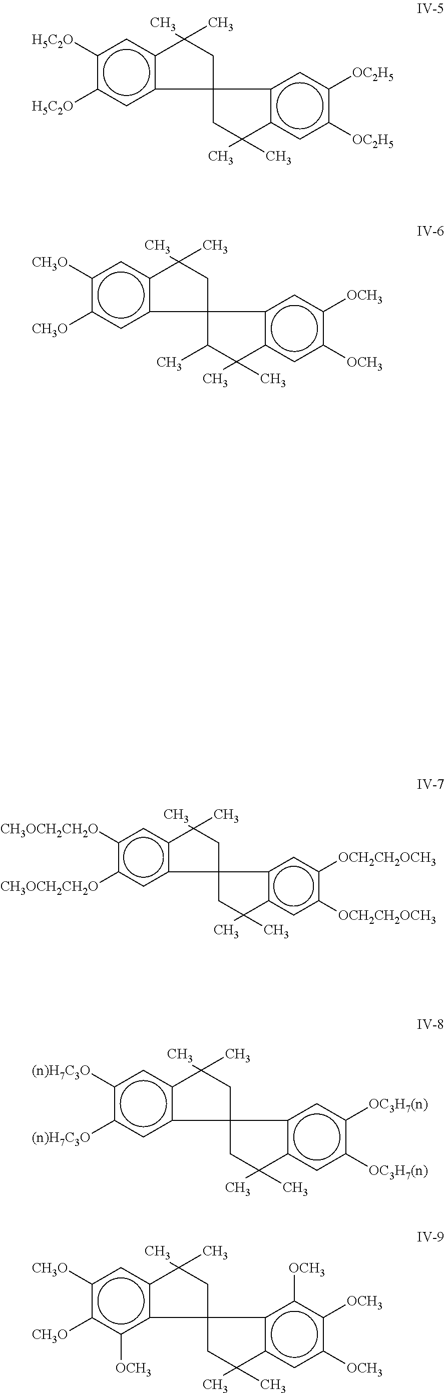

As the antifading agent, the compound represented by General Formula [III] can also be preferably used.

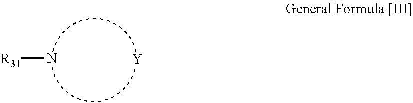

In General Formula [III], R³¹ represents an aliphatic group or an aromatic group, and Y represents a non-metal atomic group necessary for forming a 5- to 7-membered ring with a nitrogen atom.

Next, in General Formula [III], R³¹ represents an aliphatic group or an aromatic group, and is preferably an alkyl group, an aryl group, or a heterocyclic group (preferably, an aliphatic heterocyclic group), and more preferably an aryl group.

Examples of the heterocyclic ring formed by Y together with the nitrogen atom include a piperidine ring, a piperazine ring, a morpholine ring, a thiomorpholine ring, a thiomorpholine-1,1-dione ring, a pyrrolidine ring, and an imidazolidine ring.

In addition, the heterocyclic ring may further have a substituent, and examples of the substituent include an alkyl group and an alkoxy group.

Specific examples of the compound represented by General Formula [III] are shown below. However, the present invention is not limited thereto.

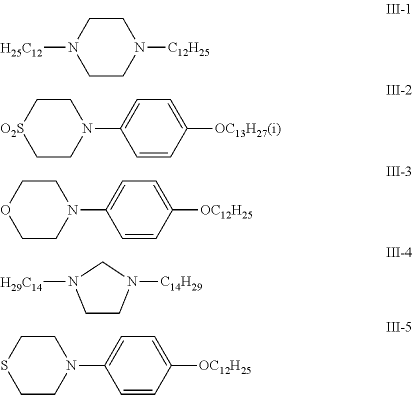

In addition to the above specific examples, specific examples of the compound represented by General Formula [III] above include exemplary compounds B-1 to B-65 described on pages 8 to 11 of JP2004-167543A (JP-H2-167543A), and exemplary compounds (1) to (120) described on pages 4 to 7 of JP1988-95439A (JP-S63-95439A).

The content of the antifading agent in the wavelength selective absorption layer is preferably 0.1% to 15% by mass and more preferably 1% to 15% by mass in 100% by mass of the total mass of the wavelength selective absorption layer.

In a case where the antifading agent is contained within the above-described preferred range, the wavelength selective absorption layer can improve the light resistance of the dye (the coloring agent) without causing side effects such as discoloration of the wavelength selective absorption layer.

<Other Components>

In addition to the above-described dye and matrix resin, the wavelength selective absorption layer may contain the above-described antifading agent for a dye, and it may contain a matting agent, a leveling agent (a surfactant), and the like.

(Matting Agent)

It is preferable to add fine particles to the surface of the wavelength selective absorption layer in order to impart sliding properties and prevent blocking. As the fine particles, silica (silicon dioxide, SiO₂) of which the surface is coated with a hydrophobic group and which has an aspect of secondary particles is preferably used. As the fine particles, in addition to or instead of silica, fine particles of titanium dioxide, aluminum oxide, zirconium oxide, calcium carbonate, talc, clay, calcined kaolin, calcined calcium silicate, hydrated calcium silicate, aluminum silicate, magnesium silicate, and calcium phosphate may be used. Examples of the commercially available product of the fine particles include the R972 or NX90S (product name, both manufactured by Nippon Aerosil Co., Ltd.).

The fine particles function as a so-called matting agent, and the addition of the fine particles forms fine unevenness on the surface of the wavelength selective absorption layer. Due to the unevenness, even in a case where the wavelength selective absorption layers overlap each other or the wavelength selective absorption layer of the present invention and other films overlap each other, the films do not stick to each other and sliding properties are secured.

In a case where the wavelength selective absorption layer contains a matting agent as fine particles, and in the fine unevenness due to the protrusions in which fine particles protrude from the filter surface, there are 10⁴/mm² or more of protrusions having a height of 30 nm or more, the effect of improving sliding properties and blocking properties are particularly large.

It is preferable to apply the matting agent fine particles particularly onto the surface layer in order to improve the blocking properties and the sliding properties. Examples of the method of applying fine particles onto the surface layer include methods such as multilayer casting and coating.

The content of the matting agent in the wavelength selective absorption layer is appropriately adjusted according to the purpose.

However, in the wavelength selective absorption layer, it is preferable to apply the above-described matting agent fine particles to the surface of the wavelength selective absorption layer in contact with the gas barrier layer as long as the effect of the present invention is not impaired.

(Leveling Agent)

A leveling agent (surfactant) can be appropriately mixed with the wavelength selective absorption layer. As the leveling agent, a commonly used compound can be used, and a fluorine-containing surfactant is particularly preferable. Specific examples thereof include the compounds described in paragraphs [0028] to [0056] of JP2001-330725A.

The content of the leveling agent in the wavelength selective absorption layer is appropriately adjusted according to the purpose.

The wavelength selective absorption layer may contain, in addition to the above components, a low-molecular plasticizer, an oligomer-based plasticizer, a retardation modifier, an ultraviolet absorbing agent, a deterioration preventing agent, a peeling accelerator, an infrared absorbing agent, an antioxidant, a filler, and a compatibilizer.

<Manufacturing Method for Wavelength Selective Absorption Layer>

The wavelength selective absorption layer can be produced, according to a conventional method, by a solution film forming method, a melt extrusion method, or a method (a coating method) of forming a coating layer on a base material film (a release film) according to a predetermined method, and stretching can also be appropriately combined. The wavelength selective absorption layer is preferably produced by a coating method.

(Solution Film Forming Method)

In the solution film forming method, a solution in which a material of the wavelength selective absorption layer is dissolved in an organic solvent or water is prepared, a concentration step, a filtration step, and the like are appropriately performed, and then the solution is uniformly cast on a support. Next, the raw dry film is peeled off from the support, both ends of a web are appropriately held by clips or the like, and the solvent is dried in the drying zone. In addition, stretching can be carried out separately while or after the film is dried.

(Melt Extrusion Method)

In the melt extrusion method, the material of the wavelength selective absorption layer is melted by heat, a filtration step and the like are appropriately performed, and then the material is uniformly cast on a support. Next, a film solidified by cooling or the like can be peeled off and appropriately stretched. In a case where the main material of the wavelength selective absorption layer is a thermoplastic polymer resin, a thermoplastic polymer resin can be selected as the main material of the release film, and the polymer resin in a molten state can be formed into a film by a known co-extrusion method. In this case, by adjusting the polymer type of the wavelength selective absorption layer and the release film and the additives mixed in each layer, or by adjusting the stretching temperature, the stretching speed, the stretching ratio, and the like of the co-extruded film, the adhesive force between the wavelength selective absorption layer and the release film can be controlled.

Examples of the co-extrusion method include a co-extrusion T-die method, a co-extrusion inflation method, and a co-extrusion lamination method. Among these, the co-extrusion T-die method is preferable. The co-extrusion T-die method includes a feed block method and a multi-manifold method. Among these, the multi-manifold method is particularly preferable from the viewpoint that a variation in thickness can be reduced.

In a case where the co-extrusion T-die method is adopted, the melting temperature of the resin in an extruder having a T-die is set to be a temperature higher than the glass transition temperature (Tg) of each resin by preferably 80° C. or higher and more preferably 100° C. or higher, and it is set to be a temperature higher than the glass transition temperature (Tg) of each resin by preferably 180° C. or lower and more preferably 150° C. or lower. In a case where the melting temperature of the resin in the extruder is set to be equal to or larger than the lower limit value of the above-described preferred range, the fluidity of the resin can be sufficiently enhanced, and in a case where the melting temperature is set to the upper limit value or less of the above-described preferred range, the resin can be prevented from being deteriorated.

In general, the sheet-shaped molten resin extruded from the opening portion of the die is brought into close contact with the cooling drum. The method of bringing the molten resin into close contact with the cooling drum is not particularly limited, and examples thereof include an air knife method, a vacuum box method, and an electrostatic contact method.

The number of cooling drums is not particularly limited; however, it is generally 2 or more. In addition, the method of arranging the cooling drum is not particularly limited, and examples of the disposition form include a linear form, a Z form, and an L form. Further, the method of passing the molten resin extruded from the opening portion of the die through the cooling drum is not particularly limited.

The degree of close contact of the extruded sheet-shaped resin with the cooling drum changes depending on the temperature of the cooling drum. In a case where the temperature of the cooling drum is raised, the intimate attachment is improved, but in a case where the temperature is raised too much, the sheet-shaped resin may not be peeled off from the cooling drum and may be wound around the drum. Therefore, the temperature of the cooling drum is preferably (Tg+30°) C or lower, and still more preferably in a range of (Tg−5°) C to (Tg−45°) C in a case where Tg is the glass transition temperature of the resin of the layer that is brought into contact with the drum in the resin extruded from the die. In a case where the cooling drum temperature is set within the above-described preferred range, problems such as sliding and scratches can be prevented.

Here, it is preferable to reduce the content of the residual solvent in the film before stretching. Examples of the method of reducing the content include methods of (1) reducing the amount of the residual solvent of the resin as the raw material; and (2) predrying the resin before forming the film before stretching. Predrying is carried out, for example, by making the resin into a form of a pellet or the like and using a hot air dryer or the like. The drying temperature is preferably 100° C. or higher, and the drying time is preferably 2 hours or longer. In a case of carrying out predrying, it is possible to reduce the residual solvent in the film before stretching and to prevent the extruded sheet-shaped resin from foaming.

(Coating Method)

In the coating method, a solution of a material of the wavelength selective absorption layer is applied to a release film to form a coating layer. A release agent or the like may be appropriately applied to the surface of the release film in advance in order to control the adhesiveness to the coating layer. The coating layer can be used by peeling off the release film after being laminated with another member while interposing an adhesive layer in a later step. Any adhesive can be appropriately used as the adhesive constituting the adhesive layer. The release film can be appropriately stretched together with the release film coated with the solution of the material of the wavelength selective absorption layer or with the coating layer laminated.

The solvent used for the solution of the material of the wavelength selective absorption layer can be appropriately selected from the viewpoint that the material of the wavelength selective absorption layer can be dissolved or dispersed, a uniform surface shape can be easily achieved during the coating step and drying step, liquid storage stability can be secured, and an appropriate saturated vapor pressure is provided.

-Addition of Dye (Coloring Agent) or the Like-

The timing of adding the dye to the wavelength selective absorption layer material is not particularly limited as long as the dye and the antifading agent are added at the time of film formation. For example, the dye may be added at the time of synthesizing the matrix resin or may be mixed with the material of the wavelength selective absorption layer at the time of preparing the coating liquid for the material of the wavelength selective absorption layer. In addition, the same applies to other components that may be contained in the wavelength selective absorption filter, such as the antifading agent.

-Release Film-

The release film used for forming the wavelength selective absorption layer according to the embodiment of the present invention by a coating method or the like preferably has a film thickness of 5 to 100 μm, more preferably 10 to 75 μm, and still more preferably 15 to 55 μm. In a case where the film thickness is equal to or larger than the above-described preferred lower limit value, sufficient mechanical strength can be easily secured, and failures such as curling, wrinkling, and buckling are less likely to occur. In addition, in a case where the film thickness is equal to or smaller than the preferred upper limit value, in the storage of a multi-layer film of the release film and the wavelength selective absorption layer, for example, in the form of a long roll, the surface pressure applied to the multi-layer film is easily adjusted to be in an appropriate range, and adhesion defect is less likely to occur.

The surface energy of the release film is not particularly limited, and by adjusting the relationship between the surface energy of the material of the wavelength selective absorption layer or the coating solution and the surface energy of the surface of the release film on which the wavelength selective absorption layer is to be formed, the adhesive force between the wavelength selective absorption layer and the release film can be adjusted. In a case where the surface energy difference is reduced, the adhesive force tends to increase, and in a case where the surface energy difference is increased, the adhesive force tends to decrease, and thus the surface energy can be set appropriately.

The surface energy of the release film can be calculated from the contact angle value between water and methylene iodide using the Owen's method. For the measurement of the contact angle, for example, DM901 (contact angle meter, manufactured by Kyowa Interface Science Co., Ltd.) can be used.

The surface energy of the surface of the release film on which the wavelength selective absorption layer is to be formed is preferably 41.0 to 48.0 mN/m and more preferably 42.0 to 48.0 mN/m. In a case where the surface energy is equal to or more than the preferred lower limit value, the evenness of the thickness of the wavelength selective absorption layer is increased. In a case where the surface energy is equal to or smaller than the preferred upper limit value, it is easy to control the peeling force of the wavelength selective absorption layer from the release film within an appropriate range.

The surface unevenness of the release film is not particularly limited, and depending on the relationship between the surface energy of the wavelength selective absorption layer surface, the hardness, and the surface unevenness, and the surface energy and hardness of the surface of the release film opposite to the side on which the wavelength selective absorption layer is formed, for example, in order to prevent adhesion defect in a case where the multi-layer film of the release film and the wavelength selective absorption layer is stored in the form of a long roll, the surface unevenness of the release film can be adjusted. In a case where the surface unevenness is increased, adhesion defect tends to be suppressed, and in a case where the surface unevenness is reduced, the surface unevenness of the wavelength selective absorption layer tends to decrease and the haze of the wavelength selective absorption layer tends to be small. Thus, the surface unevenness can be set appropriately.

For such a release film, any material and film can be appropriately used. Specific examples of the material include a polyester-based polymer (including polyethylene terephthalate-based film), an olefin-based polymer, a cycloolefin-based polymer, a (meth)acrylic polymer, a cellulose-based polymer, and a polyamide-based polymer. In addition, a surface treatment can be appropriately carried out for the intended purpose of adjusting the surface properties of the release film. For example, a corona treatment, a room temperature plasma treatment, or a saponification treatment can be carried out to decrease the surface energy, and a silicone treatment, a fluorine treatment, an olefin treatment, or the like can be carried out to raise the surface energy.

-Peeling Force Between Wavelength Selective Absorption Layer and Release Film-

In a case where the wavelength selective absorption layer is formed by a coating method, the peeling force between the wavelength selective absorption layer and the release film can be controlled by adjusting the material of the wavelength selective absorption layer, the material of the release film, the internal strain of the wavelength selective absorption layer. The peeling force can be measured by, for example, a test of peeling off the release film in a direction of 90°, and the peeling force in a case of being measured at a rate of 300 mm/min is preferably 0.001 to 5 N/25 mm, more preferably 0.01 to 3 N/25 mm, and still more preferably 0.05 to 1 N/25 mm. In a case where the peeling force is equal to or greater than at least the above preferable lower limit value, peeling off the release film in a step other than the peeling step can be prevented, and in a case where the peeling force is equal to or smaller than the above preferable upper limit value, peeling failure in the peeling step (for example, zipping and cracking of the wavelength selective absorption layer) can be prevented.

<Film Thickness of Wavelength Selective Absorption Layer>

The film thickness of the wavelength selective absorption layer is not particularly limited, and is preferably 1 to 18 μm, more preferably 1 to 12 μm, and still more preferably 2 to 8 μm. In a case where the film thickness is equal to or smaller than the above-described preferred upper limit value, the decrease in the degree of polarization due to the fluorescence emitted by a dye (a coloring agent) can be suppressed by adding the dye to the thin film at a high concentration. In addition, the effects of the quencher and the antifading agent are easily exhibited. On the other hand, in a case where the film thickness is equal to or larger than the above-described preferred lower limit value, it becomes easy to maintain the evenness of the in-plane absorbance.

In the present invention, the film thickness of 1 to 18 m means that the thickness of the wavelength selective absorption layer is within a range of 1 to 18 m at any portion. The same applies to the film thicknesses of 1 to 12 m and 2 to 8 m. The film thickness can be measured with an electronic micrometer manufactured by Anritsu Corporation.

<Transmittance of Wavelength Selective Absorption Layer>

The minimum transmittance (Tₘᵢₙ(390 to 435)) of the wavelength selective absorption layer at a wavelength of 390 to 435 nm is preferably 0% or more and 98% or less, more preferably 5% or more and 90% or less, still more preferably 10% or more and 80% or less, and particularly preferably 20% or more and 60% or less.

The minimum transmittance (Tₘᵢₙ(500 to 520)) of the wavelength selective absorption layer at a wavelength of 500 to 520 nm is preferably 5% or more and 98% or less, more preferably 10% or more and 95% or less, still more preferably 20% or more and 90% or less, and particularly preferably 20% or more and 60% or less.

The minimum transmittance (Tₘᵢₙ(580 to 620)) of the wavelength selective absorption layer at a wavelength of 580 to 620 nm is preferably 0% or more and 95% or less, more preferably 0% or more and 90% or less, still more preferably 0% or more and 80% or less, and particularly preferably 0% or more and 30% or less.

In a case of incorporating the wavelength selective absorption layer in which the transmittance is adjusted in the above range, into the self-luminous display device according to the embodiment of the present invention, the external light reflection is further suppressed at higher brightness, and a self-luminous display device exhibiting excellent display performance, in which the color difference (the change in tint) of the reflected light is suppressed, is obtained.

The transmittance of the wavelength selective absorption layer can be adjusted by the kind or adding amount of the dye. The transmittance of the wavelength selective absorption layer is a value measured according to the above-described method.

<Moisture Content of Wavelength Selective Absorption Layer>

From the viewpoint of the durability, the moisture content of the wavelength selective absorption layer is preferably 0.5% by mass or less, and more preferably 0.3% by mass or less, in conditions of 25° C. and 80% relative humidity, regardless of the film thickness.

In the present specification, the moisture content of the wavelength selective absorption layer can be measured by using a sample having a thick film thickness as necessary. The moisture content can be calculated by humidity-conditioning the sample for 24 hours or longer, then measuring a moisture content (g) by the Karl Fischer method with a water measuring instrument and a sample drying apparatus “CA-03” and “VA-05” (both manufactured by Mitsubishi Chemical Corporation), and dividing the moisture content (g) by the sample mass (g, including the moisture content).

<Glass Transition Temperature (Tg) of Wavelength Selective Absorption Layer>

The glass transition temperature of the wavelength selective absorption layer is preferably 50° C. or higher and 140° C. or lower. The glass transition temperature is more preferably 60° C. or higher and 130° C. or lower, and still more preferably 70° C. or higher and 120° C. or lower. In a case where the glass transition temperature is equal to or higher than the above preferable lower limit value, deterioration of the polarizer in a case of being used at a high temperature can be suppressed, and in a case where the glass transition temperature is equal to or lower than the above preferable upper limit value, it is possible to suppress that the organic solvent used in the coating liquid easily remains in the wavelength selective absorption layer.

The glass transition temperature of the wavelength selective absorption layer can be measured according to the following method.

With a differential scanning calorimetry device (X-DSC7000 (manufactured by IT Measurement Control Co., Ltd.)), 20 mg of a wavelength selective absorption layer is placed in a measurement pan, and the temperature of the pan is raised from 30° C. to 120° C. in a nitrogen stream at a speed of 10° C./min, and held for 15 minutes, and then cooled to 30° C. at −20° C./min. Thereafter, the temperature was raised again from 30° C. to 250° C. at a rate of 10° C./min, and the temperature at which the baseline began to deviate from the low temperature side was defined as the glass transition temperature Tg.

The glass transition temperature of the wavelength selective absorption layer can be adjusted by mixing two or more kinds of polymers having different glass transition temperatures, or by changing the adding amount of a low-molecular weight compound such as an antifading agent.

<Treatment of Wavelength Selective Absorption Layer>

It is preferable that the wavelength selective absorption layer is subjected to, for example, a hydrophilic treatment by a predetermined glow discharge treatment, corona discharge treatment, alkali saponification treatment, or the like, and a corona discharge treatment is most preferably used. It is also preferable to apply the method disclosed in JP1994-94915A (JP-H6-94915A) and JP1994-118232A (JP-H6-118232A).

As necessary, the obtained film may be subjected to a heat treatment step, a superheated steam contact step, an organic solvent contact step, or the like. In addition, a surface treatment may be appropriately carried out.

Further, as the pressure sensitive adhesive layer, a layer consisting of a pressure sensitive adhesive composition in which a (meth)acrylic resin, a styrene-based resin, a silicone-based resin, or the like is used as a base polymer, and a crosslinking agent such as an isocyanate compound, an epoxy compound, or an aziridine compound is added thereto can be applied.

Preferably, the description for the pressure sensitive adhesive layer in the self-luminous display device described later can be applied.

<<Gas Barrier Layer>>

The wavelength selective absorption layer contains a gas barrier layer directly disposed on at least one surface of the wavelength selective absorption layer, and this gas barrier layer contains a crystalline resin, where it is preferable that the thickness of the layer is 0.1 μm to 10 μm and the oxygen permeability of the layer is 60 cc/m².day atm or less.

In the gas barrier layer, the “crystalline resin” is a resin having a melting point that undergoes a phase transition from a crystal to a liquid in a case where the temperature is raised, and it can impart gas barrier properties related to oxygen gas to the gas barrier layer.

Since the wavelength selective absorption layer has a gas barrier layer at least on a surface where the wavelength selective absorption layer comes into contact with air in a case where the gas barrier layer is incorporated in the self-luminous display device according to the embodiment of the present invention, it is possible to suppress a decrease in the absorption intensity of the dye in the wavelength selective absorption layer and improve the light resistance. As long as the gas barrier layer is provided at an interface of the wavelength selective absorption layer in contact with air, the gas barrier layer may be provided on only one surface of the wavelength selective absorption layer or may be provided on both surfaces.

In the wavelength selective absorption layer, since the gas barrier layer is directly provided on at least one surface of the wavelength selective absorption layer, the light resistance of the dye contained in the wavelength selective absorption filter can be improved. The presumable reason for this is conceived to be as follows.

The absorbance of the dye contained in the wavelength selective absorption filter may decrease due to light irradiation. The main cause of this phenomenon is that a singlet oxygen generated by a transfer of excitation energy due to the light irradiation to oxygen molecules decomposes molecules of the dye. For example, in a case where a dye and an antifading agent for the dye are contained in the wavelength selective absorption filter, it is possible to suppress the decomposition of the dye due to the singlet oxygen generated as described above.

In the present invention, the gas barrier layer is provided at least at a place near an air interface in the wavelength selective absorption filter, and thus the permeation of the oxygen molecules (oxygen gas) can be suppressed, and as a result, the decomposition of the dye in the wavelength selective absorption filter can be suppressed.

Further, in addition to the above configuration, the wavelength selective absorption layer includes the gas barrier layer directly on at least one surface of the wavelength selective absorption filter, and the gas barrier layer contains a crystalline resin and exhibits a specific oxygen permeability. The laminate consisting of the wavelength selective absorption layer and the gas barrier layer, having such a configuration, can suppress the permeation of oxygen molecules at a desired level and is also excellent in productivity. On the other hand, in a case where the gas barrier layer is too thick, an amount of the antifading agent that moves to the amorphous portion in the crystalline resin increases in a case where the wavelength selective absorption layer contains the antifading agent in the wavelength selective absorption layer. As a result, although the oxygen permeability of the gas barrier layer can be reduced by thickening the gas barrier layer, a problem that the desired effect of improving the light resistance cannot be obtained, or conversely, the effect of improving the light resistance is reduced occurs.

In the wavelength selective absorption layer that is used in the self-luminous display device according to the embodiment of the present invention, in a case of directly disposing a gas barrier layer having a specific thickness on at least one surface of the wavelength selective absorption layer, it is conceived that it is possible to realize the effect of suppressing a decrease in light resistance due to the gas barrier layer at an excellent level, and in particular, in a case where the antifading agent is contained in the wavelength selective absorption layer, it is possible to realize the light resistance at a more excellent level.

(Crystalline Resin)

The crystalline resin contained in the gas barrier layer is a crystalline resin having gas barrier properties, and it can be used without particular limitation as long as a desired oxygen permeability can be imparted to the gas barrier layer.

Examples of the crystalline resin include polyvinyl alcohol and polyvinylidene chloride, and the polyvinyl alcohol is preferable from the viewpoint that a crystalline portion can effectively suppress the permeation of gas.

The polyvinyl alcohol may be modified or may not be modified. Examples of the modified polyvinyl alcohol include modified polyvinyl alcohol into which a group such as an acetoacetyl group and a carboxy group is introduced.

The saponification degree of the polyvinyl alcohol is preferably 80.0% by mol or more, more preferably 90.0% by mol or more, still more preferably 97.0% by mol or more, and particularly preferably 98.0% by mol or more, from the viewpoint of further enhancing the oxygen gas barrier properties. The upper limit value thereof is not particularly limited, and it is practically 99.99% by mol or less. The saponification degree of the polyvinyl alcohol is a value calculated based on the method described in JIS K 6726 1994.

The gas barrier layer may contain any component usually contained in the gas barrier layer, as long as the effect of the present invention is not impaired. For example, in addition to the above crystalline resin, organic-inorganic hybrid materials such as an amorphous resin material and a sol-gel material, and inorganic materials such as SiO₂, SiOₓ, SiON, SiNₓ, and Al₂O₃ may be contained.

Further, the gas barrier layer may contain a solvent such as water and an organic solvent derived from a manufacturing step, as long as the effect of the present invention is not impaired.

The content of the crystalline resin in the gas barrier layer is, for example, preferably 90% by mass or more and more preferably 95% by mass or more in 100% by mass of the total mass of the gas barrier layer. The upper limit value thereof is not particularly limited, and it can be set to 100% by mass.

The oxygen permeability of the gas barrier layer is 60 cc/m²·day·atm or less, preferably 50 cc/m²·day·atm or less, more preferably 30 cc/m²·day·atm or less, still more preferably 10 cc/m²·day·atm or less, particularly preferably 5 cc/m²·day·atm or less, and most preferably 1 cc/m²·day·atm or less. The practical lower limit value thereof is 0.001 cc/m²·day·atm or more, and it is preferably, for example, more than 0.05 cc/m²·day·atm. In a case where the oxygen permeability is within the above-described preferred range, the light resistance can be further improved.

The oxygen permeability of the gas barrier layer is a value measured based on the gas permeability test method based on JIS K 7126-2 2006. As the measuring device, for example, an oxygen permeability measuring device OX-TRAN2/21 (product name) manufactured by MOCON can be used. The measurement conditions are set to a temperature of 25° C. and a relative humidity of 50%.

For the oxygen permeability, (fm)/(s·Pa) can be used as the SI unit. It is possible to carry out the conversion by (1 fm)/(s·Pa)=8.752 (cc)/(m²·day·atm). fm is read as femtometer and represents 1 fm=10⁻¹⁵ m.

The thickness of the gas barrier layer is preferably 0.5 μm to 5 μm, and more preferably 1.0 μm to 4.0 μm, from the viewpoint of further improving the light resistance.

The thickness of the gas barrier layer is measured according to a method described in Examples to be described later.

The degree of crystallinity of the crystalline resin contained in the gas barrier layer is preferably 25% or more, more preferably 40% or more, and still more preferably 45% or more. The upper limit value thereof is not particularly limited; however, it is practically 55% or less.

The degree of crystallinity of the crystalline resin contained in the gas barrier layer is a value measured and calculated according to the following method based on the method described in J. Appl. Pol. Sci., 81, 762 (2001).

Using a differential scanning calorimeter (DSC), a temperature of a sample peeled from the gas barrier layer is raised at 10° C./min over the range of 20° C. to 260° C., and a heat of fusion 1 is measured. Further, as a heat of dissolution 2 of the perfect crystal, the value described in J. Appl. Pol. Sci., 81, 762 (2001) is used. Using the obtained heat of dissolution 1 and heat of dissolution 2, the degree of crystallinity is calculated according to the following expression.

[Degree of crystallinity (%)]=([heat of fusion1]/[heat of fusion2])×100

Specifically, the degree of crystallinity is a value measured and calculated according to the method described in Examples to be described later. The heat of fusion 1 and heat of fusion 2 may have the same unit, which is generally Jg⁻¹.

<Manufacturing Method for Gas Barrier Layer>

The method of forming the gas barrier layer is not particularly limited, and examples thereof include a production method according to a conventional method, according to a casting method such as spin coating or slit coating. In addition, examples thereof include a method of bonding a commercially available resin gas barrier film or a resin gas barrier film produced in advance to the wavelength selective absorption layer.

<<Optical Film >>

In addition to the wavelength selective absorption layer and the gas barrier layer, the above-described wavelength selective absorption layer may appropriately comprise any optical film as long as the effect of the present invention is not impaired.

The optional optical film is not particularly limited in terms of any of optical properties and materials, and a film containing (or containing as a main component) at least any of a cellulose ester resin, an acrylic resin, a cyclic olefin resin, and a polyethylene terephthalate resin can be preferably used. It is noted that an optically isotropic film or an optically anisotropic phase difference film may be used.

For the above optional optical films, for example, Fujitac TD80UL (manufactured by FUJIFILM Corporation) or the like can be used as a film containing a cellulose ester resin.

Regarding the optional optical film, as those containing an acrylic resin, an optical film containing a (meth)acrylic resin containing a styrene-based resin described in JP4570042B, an optical film containing a (meth)acrylic resin having a glutarimide ring structure in a main chain described in JP5041532B, an optical film containing a (meth)acrylic resin having a lactone ring structure described in JP2009-122664A, and an optical film containing a (meth)acrylic resin having a glutaric anhydride unit described in JP2009-139754A can be used.

Further, regarding the optional optical films, as those containing a cyclic olefin resin, cyclic olefin-based resin film described in paragraphs [0029] and subsequent paragraphs of JP2009-237376A, and cyclic olefin resin film containing an additive reducing Rth described in JP4881827B and JP2008-063536B can be used.

In addition, the above-described optional optical film may contain an ultraviolet absorbing agent. As the ultraviolet absorbing agent, a commonly used compound can be used without particular limitation.

The content of the ultraviolet absorbing agent in the ultraviolet absorption layer is appropriately adjusted according to the intended purpose.

<<Manufacturing Method for Laminate>>

In a case where the wavelength selective absorption layer included in the self-luminous display device according to the embodiment of the present invention has the above-described gas barrier layer or any optical film in addition to the above-described wavelength selective absorption layer, a laminate consisting of these wavelength selective absorption layer and gas barrier layer and/or any optical film can be produced by using the above-described manufacturing method for a wavelength selective absorption layer and manufacturing method for a gas barrier layer.

Examples thereof include a method of directly producing the above-described gas barrier layer on the wavelength selective absorption layer produced according to the above-described production method. In this case, it is also preferable to apply a corona treatment to the surface of the wavelength selective absorption layer, on which the gas barrier layer is provided.

Further, in a case where the above-described optional optical film is provided, it is also preferable to carry out bonding by interposing a pressure sensitive adhesive layer. For example, it is also preferable to provide the gas barrier layer on the wavelength selective absorption layer, and then bond an optical film containing an ultraviolet absorbing agent by interposing a pressure sensitive adhesive layer.

[Self-Luminous Display Device]

The self-luminous display device according to the embodiment of the present invention is a self-luminous type display device including a light emitting diode as a light emitting source, where it contains the wavelength selective absorption layer.

As another configuration of the self-luminous display device according to the embodiment of the present invention, a configuration of a generally used self-luminous display device, for example, a micro light emitting diode (micro LED) display device or a mini light emitting diode (mini LED) display device can be used without particular limitation, as long as it is a configuration in which the wavelength selective absorption layer is included at such a position that the external light antireflection function is exhibited (as long as it is such a configuration that a gas barrier layer is positioned at least closer to the external light side than the wavelength selective absorption layer in a case where the gas barrier layer is included). The configuration example of the self-luminous display device according to the embodiment of the present invention is not particularly limited, and examples thereof include a display device including glass, a layer containing a thin film transistor (TFT), a light emitting element, the above-described wavelength selective absorption filter (wavelength selective absorption layer), and a surface film, in order from the opposite side to external light.

As a light source of the display light of the self-luminous display device according to the embodiment of the present invention, a single blue color may be used, or the three primary colors of blue, green, and red may be used, as long as the light emitting diode is provided as a light emitting source. Among the above, it is particularly preferable to use a combination of a blue light source that emits light in a wavelength range of 440 nm to 470 nm, a green light source that emits light in a wavelength range of 520 nm to 560 nm, and a red light source that emits light in a wavelength range of 620 nm to 660 nm.

In the present invention, the mini LED means an LED having a chip size of about 100 to 200 μm, and the micro LED means an LED having a chip size of less than 100 μm. Preferred examples of the micro LED include the micro LED described in WO2014/204694A.

The self-luminous display device according to the present invention is excellent in the suppression of a decrease in brightness, the antireflection, and the suppression of a change in the tint of the reflected light, even in a case where the wavelength selective absorption layer is provided as an antireflection unit instead of the circularly polarizing plate.

As described above, in one embodiment of the present invention having the gas barrier layer directly disposed on at least one surface of the wavelength selective absorption layer, an excellent level of light resistance that overtakes the decrease in light resistance in association with the mixing of the three dyes A to C contained in the wavelength selective absorption layer can be exhibited. In addition, in another embodiment of the present invention in which the wavelength selective absorption layer contains the three kinds of dyes A to C so that the above-described Relational Expression (I) is satisfied, both the suppression of external light reflection and the suppression of brightness decrease can be achieved at a sufficient level, and moreover, the change in the tint of the reflected light can be suppressed, whereby the original tint of the image formed by the light emitted from the light emitting layer (light source) can be maintained at an excellent level.

That is, the circularly polarizing plate having the antireflection function is usually used as the surface film. However, by adopting the above-described wavelength selective absorption layer, the self-luminous display device according to the embodiment of the present invention can exhibit an excellent effect without using the circularly polarizing plate. It is noted that it does not interfere with the combination use of the antireflection film, as the configuration of the self-luminous display device or self-luminous display device according to the embodiment of the present invention, within the range not impairing the effect of the present invention.

<Pressure Sensitive Adhesive Layer>

In the self-luminous display device according to the embodiment of the present invention, it is preferable that the wavelength selective absorption layer is bonded to the glass (the base material) with a pressure sensitive adhesive layer being interposed, on a surface positioned opposite to the side of the external light.

The composition of the pressure sensitive adhesive composition that is used for forming the pressure sensitive adhesive layer is not particularly limited, and for example, a pressure sensitive adhesive composition containing a base resin having a mass average molecular weight (Mw) of 500,000 or more may be used. In a case where the mass average molecular weight of the base resin is less than 500,000, the durability reliability of the pressure sensitive adhesive may decrease due to a decrease in cohesive force causing bubbles or peeling phenomenon under at least one of the high temperature condition or the high humidity condition. The upper limit of the mass average molecular weight of the base resin is not particularly limited. However, in a case where the mass average molecular weight is excessively increased, the coating property may deteriorate due to the increase in viscosity, and thus the upper limit thereof is preferably 2,000,000 or less.

The specific kind of the base resin is not particularly limited, and examples thereof include an acrylic resin, a silicone-based resin, a rubber-based resin, and an ethylene-vinyl acetate (EVA)-based resin. In a case of being applied to an optical device such as a liquid crystal display device, an acrylic resin is mainly used in that the acrylic resin is excellent in transparency, oxidation resistance, and resistance to yellowing, and it is not limited thereto.

Examples of the acrylic resin include a polymer of monomer mixture containing 80 parts by mass to 99.8 parts by mass of the (meth)acrylic acid ester monomer; and 0.02 parts by mass to 20 parts by mass (preferably 0.2 parts by mass to 20 parts by mass) of another crosslinkable monomer.

The kind of the (meth)acrylic acid ester monomer is not particularly limited, and examples thereof include alkyl (meth)acrylate. In this case, in a case where the alkyl group contained in the monomer becomes an excessively long chain, the cohesive force of the pressure sensitive adhesive may decrease, and it may be difficult to adjust the glass transition temperature (T_{g}) or the adhesiveness. Therefore, it is preferable to use a (meth)acrylic acid ester monomer having an alkyl group having 1 to 14 carbon atoms. Examples of such a monomer include methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl (meth)acrylate, 2-ethylhexyl (meth)acrylate, 2-ethylbutyl (meth)acrylate, n-octyl (meth)acrylate, isooctyl (meth)acrylate, isononyl (meth)acrylate, lauryl (meth)acrylate, isobornyl (meth)acrylate, and tetradecyl (meth)acrylate. In the present invention, the above-described monomers may be used alone or two or more kinds thereof may be used in combination. The (meth)acrylic acid ester monomer is preferably contained in an amount of 80 parts by mass to 99.8 parts by mass in 100 parts by mass of the monomer mixture. In a case where the content of the (meth)acrylic acid ester monomer is less than 80 parts by mass, the initial adhesive force may decrease, and in a case where the content exceeds 99.8 parts by mass, the durability may decrease due to the decrease in cohesive force.

The other crosslinkable monomer contained in the monomer mixture reacts with a polyfunctional crosslinking agent described later to impart a cohesive force to the pressure sensitive adhesive, and can impart a crosslinking functional group having a role of adjusting the pressure sensitive adhesive force and durability reliability to the polymer. Examples of such a crosslinkable monomer include a hydroxy group-containing monomer, a carboxy group-containing monomer, and a nitrogen-containing monomer. Examples of the hydroxy group-containing monomer include 2-hydroxyethyl (meth)acrylate, 2-hydroxypropyl (meth)acrylate, 4-hydroxybutyl (meth)acrylate, 6-hydroxyhexyl (meth)acrylate, and 8-hydroxyoctyl (meth)acrylate, 2-hydroxyethylene glycol (meth)acrylate, and 2-hydroxypropylene glycol (meth)acrylate. Examples of the carboxy group-containing monomer include acrylic acid, methacrylic acid, 2-(meth)acryloyloxyacetic acid, 3-(meth)acryloyloxypropyl acid, 4-(meth)acryloyloxybutyl acid, an acrylic acid dimer, itaconic acid, maleic acid, and a maleic acid anhydride. Examples of the nitrogen-containing monomer include (meth)acrylamide, N-vinylpyrrolidone, and N-vinylcaprolactam. In the present invention, these crosslinkable monomers may be used alone, or two or more kinds thereof may be used in combination.

The other crosslinkable monomer may be contained in an amount of 0.02 parts by mass to 20 parts by mass in 100 parts by mass of the monomer mixture. In a case where the content is less than 0.02 parts by mass, the durability reliability of the pressure sensitive adhesive may decrease, and in a case where the content exceeds 20 parts by mass, at least one of the adhesiveness or the peelability may decrease.

The method of producing a polymer using a monomer mixture is not particularly limited, and the polymer can be produced, for example, through a general polymerization method such as solution polymerization, photopolymerization, bulk polymerization, suspension polymerization, or emulsion polymerization. In the present invention, it is particularly preferable to use a solution polymerization method, and solution polymerization is preferably carried out at a polymerization temperature of 50° C. to 140° C. by mixing an initiator in a state where each monomer is uniformly mixed. In this case, examples of the initiator used include azo-based polymerization initiators such as azobisisobutyronitrile and azobiscyclohexanecarbonitrile; and ordinary initiators such as peroxides such as benzoyl peroxide and acetyl peroxide.

The pressure sensitive adhesive composition may further contain 0.1 parts by mass to 10 parts by mass of a crosslinking agent with respect to 100 parts by mass of the base resin. Such a crosslinking agent can impart cohesive force to the pressure sensitive adhesive through a crosslinking reaction with the base resin. In a case where the content of the crosslinking agent is less than 0.1 parts by mass, the cohesive force of the pressure sensitive adhesive may decrease. On the other hand, in a case where the content exceeds 10 parts by mass, durability reliability may decrease due to delamination and floating phenomenon.

The kind of the crosslinking agent is not particularly limited, and for example, any crosslinking agent such as an isocyanate-based compound, an epoxy-based compound, an aziridine-based compound, and a metal chelate-based compound can be used.

Examples of the isocyanate-based compound include tolylene diisocyanate, xylene diisocyanate, diphenylmethane diisocyanate, hexamethylene diisocyanate, isophorone diisocyanate, tetramethylxylene diisocyanate, and naphthalene diisocyanate, and a reactant of any one of these compounds and polyol (for example, trimethylolpropane); examples of the epoxy-based compound include ethylene glycol diglycidyl ether, triglycidyl ether, trimethylolpropane triglycidyl ether, N,N,N′, N′-tetraglycidyl ethylenediamine, and glycerin diglycidyl ether; and examples of aziridine-based compounds include N,N′-toluene-2,4-bis(1-aziridine carboxamide), N,N′-diphenylmethane-4,4′-bis(1-aziridine carboxamide), triethylene melamine, bisprothaloyl-1-(2-methylaziridine), and tri-1-aziridinylphosphine oxide. Examples of the metal chelate-based compound include compounds in which at least any one of polyvalent metals such as aluminum, iron, zinc, tin, titanium, antimony, magnesium, and vanadium is coordinated with acetylacetone or ethyl acetoacetate.

The pressure sensitive adhesive composition may further contain 0.01 parts by mass to 10 parts by mass of a silane-based coupling agent with respect to 100 parts by mass of the base resin. The silane-based coupling agent can contribute to the improvement of adhesive reliability in a case where the pressure sensitive adhesive is left for a long time under high temperature or high humidity conditions, particularly improve the adhesive stability in a case where adhering to a glass base material, and improve heat resistance and moisture resistance. Examples of the silane-based coupling agent include γ-glycidoxypropyltrimethoxysilane, γ-glycidoxypropylmethyldiethoxysilane, γ-glycidoxypropyltriethoxysilane, 3-mercaptopropyltrimethoxysilane, vinyltrimethoxysilane, vinyl triethoxysilane, γ-methacryloxypropyltrimethoxysilane, γ-methacryloxypropyltriethoxysilane, γ-aminopropyltriethoxysilane, 3-isocyanuppropyltriethoxysilane, γ-acetoacetatepropyltrimethoxysilane. These silane-based coupling agents may be used alone, or two or more kinds thereof may be used in combination.

The silane-based coupling agent is preferably contained in an amount of 0.01 parts by mass to 10 parts by mass, and still more preferably contained in an amount of 0.05 parts by mass to 1 part by mass, with respect to 100 parts by mass of the base resin. In a case where the content is less than 0.01 parts by mass, the effect of increasing the pressure sensitive adhesive force may not be sufficient, and in a case where the content exceeds 10 parts by mass, durability reliability may decrease, which includes the occurrence of bubbling or peeling phenomenon.

The above-described pressure sensitive adhesive composition can further contain an antistatic agent. As the antistatic agent, any compound can be used, as long as the antistatic agent has excellent compatibility with other components contained in the pressure sensitive adhesive composition such as an acrylic resin, not adversely affect the transparency of the pressure sensitive adhesive, workability, and durability and can impart the antistatic performance to the pressure sensitive adhesive. Examples of the antistatic agent include inorganic salts and organic salts.

The inorganic salt is a salt containing an alkali metal cation or an alkaline earth metal cation as a cation component. Examples of the cation include one or two or more of a lithium ion (Li⁺), a sodium ion (Na⁺), a potassium ion (K⁺), a rubidium ion (Rb⁺), a cesium ion (Cs⁺), a beryllium ion (Be²⁺), a magnesium ion (Mg²⁺), a calcium ion (Ca²⁺), a strontium ion (Sr²⁺), and a barium ion (Ba²⁺), and preferred examples thereof include a lithium ion (Li⁺), a sodium ion (Na⁺), a potassium ion (K⁺), a cesium ion (Cs⁺), a beryllium ion (Be²⁺), a magnesium ion (Mg²⁺), a calcium ion (Ca²⁺), and a barium ion (Ba²⁺). The inorganic salt may be used alone or two or more kinds thereof may be used in combination. A lithium ion (Li⁺) is particularly preferable in terms of ion safety and mobility within the pressure sensitive adhesive.

The organic salt is a salt containing onium cations as a cation component. The term “onium cation” means ion charged to the cation (+), where at least some of the charge is unevenly distributed on one or more of the nitrogen (N), phosphorus (P), and sulfur (S). The onium cation is a cyclic or acyclic compound, and in the case of a cyclic compound, a non-aromatic or aromatic compound can be adopted. Further, in the case of a cyclic compound, one or more heteroatoms (for example, oxygen) other than nitrogen, phosphorus, or a sulfur atom can be contained. Further, the cyclic or acyclic compound is optionally substituted with a substituent such as a hydrogen atom, a halogen atom, alkyl, or aryl. Further, in the case of an acyclic compound, one or more, preferably four or more substituents can be contained, and in this case, the substituent is a cyclic type or an acyclic substituent or an aromatic or non-aromatic substituent.

The onium cation is preferably a cation containing a nitrogen atom and more preferably an ammonium ion. The ammonium ion is a quaternary ammonium ion or an aromatic ammonium ion.

The pressure sensitive adhesive composition contains an antistatic agent in an amount of 0.01 parts by mass to 5 parts by mass, preferably 0.01 parts by mass to 2 parts by mass, more preferably 0.1 parts by mass to 2 parts by mass, with respect to 100 parts by mass of the base resin. In a case where the content is less than 0.01 parts by mass, the desired antistatic effect may not be obtained, and in a case where the content exceeds 5 parts by mass, the compatibility with other components is reduced and the durability reliability of the pressure sensitive adhesive or the transparency may be deteriorated.

The pressure sensitive adhesive composition further includes a compound capable of forming a coordinate bond with an antistatic agent, specifically, with a cation contained in the antistatic agent (hereinafter, referred to as a “coordinate-bonding compound”). In a case where a coordinate-bonding compound is properly contained, it is possible to effectively impart antistatic performance by increasing the anion concentration inside the pressure sensitive adhesive layer even in a case where a relatively small amount of antistatic agent is used.

The kind of the coordinate-bonding compound that can be used is not particularly limited as long as it has a functional group capable of forming a coordinate bond with the antistatic agent in the molecule, and examples thereof include alkylene oxide-based compounds.

The alkylene oxide-based compound is not particularly limited, and it is preferable to use an alkylene oxide-based compound containing an alkylene oxide unit that has a basic unit having 2 or more carbon atoms, preferably 3 to 12 carbon atoms, and more preferably 3 to 8 carbon atoms.

The alkylene oxide-based compound preferably has a molecular weight of 5,000 or less. The term “molecular weight” that is used in the present invention means the molecular weight or mass average molecular weight of a compound. In the present invention, in a case where the molecular weight of the alkylene oxide-based compound exceeds 5,000, the viscosity may be excessively increased and the coating property may be deteriorated, or the complex forming ability with the metal may be lowered. On the other hand, the lower limit of the molecular weight of the alkylene oxide compound is not particularly limited; however, it is preferably 500 or more, and more preferably 4,000 or more.

In the present invention, in addition to the above-described alkylene oxide-based compound, various coordinate-bonding compounds such as an ester compound having one or more ether bonds disclosed in KR2006-0018495A, an oxalate group-containing compound disclosed in KR2006-0128659A, a diamine group-containing compound, a polyvalent carboxy group-containing compound, or a ketone group-containing compound can be appropriately selected and used as necessary.

The coordinate-bonding compound is preferably contained in the pressure sensitive adhesive composition at a ratio of 3 parts by mass or less with respect to 100 parts by mass of the base resin, more preferably 0.1 parts by mass to 3 parts by mass, and still more preferably, 0.5 parts by mass to 2 parts by mass. In a case where the content exceeds 3 parts by mass, the pressure sensitive adhesive physical properties such as peelability may deteriorate.

From the viewpoint of adjusting the adhesive performance, the pressure sensitive adhesive composition may further contain 1 part by mass to 100 parts by mass of a tackifying resin with respect to 100 parts by mass of the base resin. In a case where the content of the tackifying resin is less than 1 part by mass, the addition effect may not be sufficient, and in a case where the exceeds 100 parts by mass, at least one of the compatibility or the cohesive force improving effect may be lowered. The tackifying resin is not particularly limited, and examples thereof include a (hydrogenated) hydrocarbon resin, a (hydrogenated) rosin resin, a (hydrogenated) rosin ester resin, a (hydrogenated) terpene resin, a (hydrogenated) terpene phenol resin, a polymerized rosin resin, and a polymerized rosin ester resin. These tackifying resins may be used alone, or two or more kinds thereof may be used in combination.

The pressure sensitive adhesive composition may contain one or more additives, as long as the effect of the present invention is not affected, a polymerization initiator such as a thermal polymerization initiator or a photopolymerization initiator; an epoxy resin; a curing agent; an ultraviolet stabilizer; an antioxidant; a toning agent, a reinforcing agent; a filler; an antifoaming agent; a surfactant; a photopolymerizable compound such as a polyfunctional acrylate; and a plasticizer.

<Base Material>

In the self-luminous display device according to the embodiment of the present invention, it is preferable that the wavelength selective absorption layer is bonded to the glass (the base material) with a pressure sensitive adhesive layer being interposed, on a surface positioned opposite to the side of the external light.

The method of forming the pressure sensitive adhesive layer is not particularly limited, and it is possible to use, for example, a method of applying the pressure sensitive adhesive composition to the wavelength selective absorption layer by a usual means such as a bar coater, drying, and curing the pressure sensitive adhesive composition; and a method of applying the pressure sensitive adhesive composition first to the surface of a peelable base material, and drying the composition, and then transferring the pressure sensitive adhesive layer using the peelable base material to the wavelength selective absorption layer and then aging and curing the composition.

The peelable base material is not particularly limited, and a predetermined peelable base material can be used. For example, the release film in the manufacturing method for the wavelength selective absorption layer described above is exampled.

In addition, the conditions of application, drying, aging, and curing can be appropriately adjusted based on a conventional method.

### Examples

Hereinafter, the present invention will be described in more detail based on Examples. The materials, using amount, ratio, details of treatment, procedures of treatment, and the like described in Examples below can be appropriately changed without departing from the spirit of the present invention. Therefore, it is to be understood that the scope of the present invention is not limited to Examples described below.

It is noted that “parts” and “%” that indicate the composition in Examples below are based on mass unless otherwise specified. In addition, λₘₐₓ means the maximal absorption wavelength showing the maximum absorbance in the measurement of the absorbance of the light resistance evaluation film to be described later.

[Production of Wavelength Selective Absorption Layer]

The materials used in the production of the wavelength selective absorption layer are shown below.

<Matrix Resin>

(Resin 1)

A polystyrene resin (PSJ-polystyrene GPPS SGP-10 (product name), manufactured by PS Japan Corporation) was used as resin 1.

(Resin 2)

A polyphenylene ether resin (manufactured by Asahi Kasei Corporation, Zylon S201A (product name), poly(2,6-dimethyl-1,4-phenylene oxide), Tg: 210° C.)

(Peelability Control Resin Component 1)

Byron 550 (product name, manufactured by Toyobo Co., Ltd., a polyester-based additive)

<Dye>

The above-described E-13 and E-24, and the following Compound Example 5 used in Example of WO2014/208749A were used as the dye A, the above-described 7-11, 7-21, and 7-22 were used as the dye B, and the above-described C-73 and C-80 were used as the dye C.

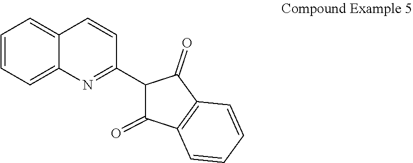 [SMILES: O=C1c2ccccc2C(=O)C1c1ccc2ccccc2n1]

<Additive>

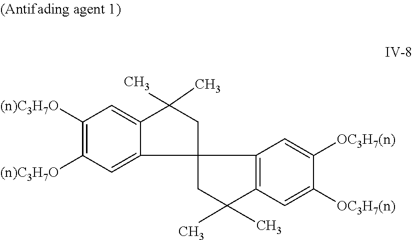

(Leveling Agent 1)

A polymer surfactant composed of the following constitutional components was used as a leveling agent 1. In the following structural formulae, the proportion of each constitutional component is in terms of a molar ratio, and t-Bu means a tert-butyl group.

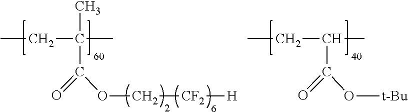

(Base Material 1)

A polyethylene terephthalate film, LUMIRROR XD-510P (product name, film thickness: 50 m, manufactured by Toray Industries, Inc.) was used as a base material 1.

### Examples

<Production of Base Material-Attached Wavelength Selective Absorption Layer 1>

(1) Preparation of Wavelength Selective Absorption Layer Forming Liquid 1

Each component was mixed according to the composition shown below to prepare a wavelength selective absorption layer forming liquid 1.

Composition of wavelength selective
absorption layer forming liquid 1

| | | |
|---|---|---|
| Resin 1 | 64.8 | parts by mass |
| Resin 2 | 17.5 | parts by mass |
| Peelability control resin component 1 | 0.20 | parts by mass |
| Leveling agent 1 | 0.08 | parts by mass |
| Dye E-24 | 2.6 | parts by mass |
| Dye 7-21 | 1.0 | parts by mass |
| Dye C-73 | 1.4 | parts by mass |
| Antifading agent 1 | 12.4 | parts by mass |
| Toluene (a solvent) | 1710.0 | parts by mass |
| Cyclohexanone (a solvent) | 190.0 | parts by mass |

Subsequently, the obtained wavelength selective absorption layer forming liquid 1 was filtered using a filter having an absolute filtration precision of 5 m (product name: Hydrophobic Fluorepore Membrane, manufactured by Millex).

(2) Production of Base Material-Attached Wavelength Selective Absorption Layer 1

The above-described wavelength selective absorption layer forming liquid 1 after the filtration treatment was applied onto the base material 1 by using a bar coater so that the film thickness after drying was 2.5 μm, and dried at 120° C. to produce a base material-attached wavelength selective absorption layer 1.

<Production of Base Material-Attached Wavelength Selective Absorption Layer Nos. 2 to 5 and c01 to c05>

Base material-attached wavelength selective absorption layers 2 to 5 and c01 to c05 were produced in the same manner as in the production of the base material-attached base material-attached wavelength selective absorption layer 1, except that the formulation amount and the kind of dye were changed to the contents shown in Table 1 below.

[Production of Laminate of Gas Barrier Layer and Wavelength Selective Absorption Layer]

The materials used in the production of the laminate of the gas barrier layer and the wavelength selective absorption layer (hereinafter, simply referred to as the laminate) are shown below.

<Resin>

(1) Crystalline Resin

(Resin 4)

AQ-4104 (manufactured by Kuraray Co., Ltd., EXCEVAL AQ-4104 (product name), modified polyvinyl alcohol, saponification degree: 98% to 99% by mole)

(Base Material 2)

The wavelength selective absorption layer side of the base material-attached wavelength selective absorption layer 1 is subjected to a corona treatment using a corona treatment device (product name: Corona-Plus, manufactured by VETAPHONE), at a discharge amount of 1,000 W min/m², and at a processing speed of 3.2 m/min and used as a base material 2.

<Production of Laminate No. 101>

(1) Preparation of Resin Solution

Each component was mixed according to the composition shown below, and the mixture was stirred in a constant-temperature tank at 90° C. for 1 hour to dissolve the resin 4 to prepare a gas barrier layer forming liquid 1.

Composition of gas barrier layer forming liquid 1

| | |
|---|---|
| Resin 4 | 4.0 parts by mass |
| Pure water | 96.0 parts by mass |

Subsequently, the obtained gas barrier layer forming liquid 1 was filtered using a filter having an absolute filtration precision of 5 μm (product name: Hydrophobic Fluorepore Membrane, manufactured by Millex).

(2) Production of Laminate

The gas barrier layer forming liquid 1 after the filtration treatment was applied to the corona-treated surface side of the base material 2 using a bar coater so that the film thickness after drying was 1.6 μm, and dried at 120° C. for 60 seconds, and the laminate No. 101 was produced.

This laminate No. 101 has a structure in which the base material 1, the wavelength selective absorption layer, and the gas barrier layer are laminated in this order.

<Production of Laminate Nos. 102 to 105 and c001 to c005>

Laminate Nos. 102 to 105 and c001 to c005 were produced in the same manner as in the production of the laminate No. 101, except that the kind of the base material-attached wavelength selective absorption layer was changed as shown in Table 1 below.

The laminates Nos. 101 to 105 are laminates including the wavelength selective absorption layer defined in the present invention, and the laminate Nos. c001 to c005 are laminates including a wavelength selective absorption layer for comparison.

<Evaluation of Physical Properties of Gas Barrier Layer>

The degree of crystallinity, oxygen permeability, and thickness of the gas barrier layer were evaluated according to the following methods.

(Degree of Crystallinity)

The gas barrier layer was peeled off by 2 to 3 mg from the laminate produced as described above, and the temperature was raised at 10° C./min in the range of 20° C. to 260° C. using DSC7000X (product name) manufactured by Hitachi High-Tech Science Co., Ltd, and heat of fusion 1 was measured.

The degree of crystallinity of the gas barrier layer was calculated based on the method described in J. Appl. Pol. Sci., 81, 762 (2001). Specifically, the degree of crystallinity was calculated according to the following expression using the above-described heat of fusion 1 and the heat of fusion 2 of the perfect crystal described in J. Appl. Pol. Sci., 81, 762 (2001).

[Degree of crystallinity (%)]=([heat of fusion1]/[heat of fusion2])×100

The degree of crystallinity of the gas barrier layers of the laminate Nos. 101 to 105 and c001 to c005, measure in this way, was 53%.

(Thickness)

A cross-sectional image of the laminate was taken using a field emission scanning electron microscope 5-4800 (product name) manufactured by Hitachi High-Technologies Corporation, and the thickness was read.

The thicknesses of the gas barrier layers of the laminate Nos. 101 to 105 and c001 to c005, measured in this way, was 1.6 μm.

(Oxygen Permeability)

Laminates were produced in the same manner except that the wavelength selective absorption layer was not subjected to the corona treatment in the production of the laminate Nos. 101 to 105 and Nos. c001 to c005. Next, a triacetyl cellulose film (product name: Fujitac TD80UL, manufactured by FUJIFILM Corporation) having a thickness of 80 m was bonded on the side of the gas barrier layer of the laminate with a pressure sensitive adhesive 1 (product name: SK2057, manufactured by Soken Chemical Co., Ltd.) having a thickness of about 20 m being interposed. Subsequently, the base material 1 corresponding to the base material 2 and the wavelength selective absorption layer were peeled off to prepare oxygen permeability evaluation films L101 to L105 and Lc001 to Lc005, which were obtained by laminating a triacetyl cellulose film, the pressure sensitive adhesive 1, and a gas barrier layer in this order by.

Using OX-TRAN 2/21 (product name) manufactured by MOCON as an oxygen permeability determination device, the oxygen permeability of the oxygen permeability evaluation film was measured by an isobaric method (JIS K 7126-2) under the condition of 25° C., relative humidity 50%, oxygen partial pressure 1 atm, and measurement area 50 cm².

The oxygen permeability of the laminate Nos. L101 to L105 and Lc001 to Lc005, measured in this way, was 0.6 cc/m².day atm.

<Maximal Absorption Value and Transmittance of Wavelength Selective Absorption Filter (Wavelength Selective Absorption Layer)>

Using a UV3150 spectrophotometer (product name) manufactured by Shimadzu Corporation, the absorbance of a base material-attached wavelength selective absorption layer in the wavelength range of 380 nm to 800 nm was measured every 1 nm. An absorbance difference Abₓ(λ)−Ab₀(λ) between an absorbance Abₓ(λ) at each wavelength λ nm of the base material-attached wavelength selective absorption layer containing no dyes and an absorbance Ab₀(λ) of the base material-attached wavelength selective absorption layer (that is, the wavelength selective absorption layer No. c01) was calculated. Next, this was converted into a transmittance T (%) according to the following expression, and the minimum transmittance in each of the wavelength ranges of 395 to 435 nm, 500 to 520 nm, and 580 to 620 nm was determined.

T(%)=100×10^{-[Abx(λ)-Ab0(λ)]}

The results are shown in Table 1.

TABLE 1

| | Base | | | | | | | | | | | | |
|---|---|---|---|---|---|---|---|---|---|---|---|---|---|
| | material- | | | | | | | | | | | | |
| | attached | | | | | | | | | | | | |
| | wavelength | Dye A | | | | Dye B | | | | Dye C | | | |
| | selective | | | | Tₘᵢₙ | | | | Tₘᵢₙ | | | | Tₘᵢₙ |
| Laminate | absorption | | λmax | | (390 to | | λmax | | (500 to | | λmax | | (580 to |
| No. | layer No. | Kind | (nm) | Content | 435) | Kind | (nm) | Content | 520) | Kind | (nm) | Content | 620) |
| 101 | 1 | E-24 | 409 | 2.6% | 26% | 7-21 | 500 | 1.0% | 30% | C-73 | 593 | 1.4% | 10% |
| 102 | 2 | E-13 | 429 | 2.2% | 29% | 7-11 | 513 | 0.5% | 52% | C-73 | 593 | 1.7% | 6% |
| 103 | 3 | E-13 | 429 | 1.9% | 34% | 7-22 | 509 | 0.5% | 47% | C-73 | 593 | 1.7% | 6% |
| 104 | 4 | Compound | 416 | 2.0% | 37% | 7-11 | 513 | 0.6% | 49% | C-73 | 593 | 1.7% | 6% |
| | | Example 5 | | | | | | | | | | | |
| 105 | 5 | E-24 | 409 | 1.0% | 55% | 7-21 | 500 | 1.3% | 22% | C-80 | 599 | 1.0% | 25% |
| c001 | c01 | Absent | — | — | — | Absent | — | — | — | Absent | — | — | — |
| c002 | c02 | Absent | — | — | — | 7-22 | 509 | 0.5% | 47% | C-73 | 593 | 1.7% | 6% |
| c003 | c03 | Absent | — | — | — | 7-21 | 500 | 1.0% | 30% | C-73 | 593 | 1.4% | 10% |
| c004 | c04 | Absent | — | — | — | 7-21 | 500 | 0.2% | 77% | C-73 | 593 | 1.4% | 10% |
| c005 | c05 | Absent | — | — | — | 7-21 | 500 | 1.0% | 31% | C-73 | 593 | 0.3% | 58% |

(Note in Table 1)
The “—” notation in the column of Dye indicates that the corresponding dye is not contained.

Compound Example 5 in the column of Dye A: Compound Example 5 described in WO2014-208749A

The content of the dye means the content proportion of the dye in the wavelength selective absorption layer in terms of the mass ratio. In addition, λₘₐₓ indicates the absorption maximum wavelength of the dye.

Tₘᵢₙ (390 to 435) indicates the minimum transmittance of the wavelength selective absorption layer at a wavelength of 390 to 435 nm, Tₘᵢₙ (500 to 520) indicates the minimum transmittance of the wavelength selective absorption layer at a wavelength of 500 to 520 nm, and Tₘᵢₙ (580 to 620) indicates the minimum transmittance of the wavelength selective absorption layer at a wavelength of 580 to 620 nm.

<Simulation of Brightness, Reflectivity, and Tint>

Regarding the base material-attached wavelength selective absorption layer (wavelength selective absorption filter) produced as described above, in a configuration in which the wavelength selective absorption layer was transferred to an aluminum foil substrate, with an pressure sensitive adhesive being interposed, and then the base material 1 was peeled off, simulations were carried out on the external light reflection with respect to the aluminum foil substrate and the transmittance of the display light of the self-luminous display device, and the reflectivity of the external light, the tint (a* and b*), and the brightness of the display light were calculated. The results are collectively shown in Table 2.

(1) Simulations of Reflectivity and Tint (a* and b*) of External Light

In the configuration illustrated in FIG. 2, the intensity of light obtained in a case where white light having a spectrum of standard illuminant D65 defined by the International Commission on Illumination (CIE) is transmitted through the wavelength selective absorption layer, subsequently reflected by an aluminum foil substrate having a reflectivity of 85%, and further transmitted again through the wavelength selective absorption layer was calculated every 1 nm in a range of a wavelength of 380 nm to a wavelength of 780 nm, and this was multiplied by the standard photopic relative luminous efficiency and summed (corrected for luminous efficiency) to calculate the reflectivity and the tint (a* and b*).

(2) Calculation of Relative Brightness

The relative brightness in a case where the wavelength selective absorption layer produced as described above was used was calculated as follows.

For the emission spectrum S(λ) of the display, an emission spectrum in white display of Magnolia (product name) manufactured by SiliconCore Technology using micro LEDs for R, G, and B was used.

The spectrum S (λ) was multiplied by the standard photopic relative luminous efficiency and summed (corrected for luminous efficiency) to calculate the brightness in a case where the wavelength selective absorption layer was not used, and this brightness was set to 100. Next, the transmission spectrum of the wavelength selective absorption layer was defined as T(λ), and the brightness of the spectrum S(λ)×T(λ) in a case where the wavelength selective absorption layer was used was calculated, where it was calculated as the relative brightness with respect to the brightness in a case where the above wavelength selective absorption layer was not used.

<Evaluation of Effect of Suppressing External Light Reflection>

Using the reflectivity value obtained in the above simulation, the reflectivity reduction rate was calculated according to the following expression, and the effect of suppressing external light reflection was evaluated based on the following evaluation standards. In this test, “AA”, “A”, and “B” are pass levels, and “AA” and “A” are preferred levels.

Reflectivity reduction rate=(R₀−R₁)/R₀×100%

R₁: Reflectivity in a case of using a wavelength selective absorption layer containing a dye

R₀: Reflectivity of No. c001 in a case where a base material-attached wavelength selective absorption layer that does not contain dye is used

(Evaluation Standard)

AA: 60%≤reflectivity reduction rate

A: 55%≤reflectivity reduction rate<60%

B: 45%≤reflectivity reduction rate<55%

C: 20%<reflectivity reduction rate≤45%

D: Reflectivity reduction rate<20%

<Evaluation of Tint>

Using the values of a* and b* calculated in the above simulation, the color difference was calculated according to the following expression.

(Color difference)=[(a*₁−a*₀)²+(b*₁−b*₀)²]^{1/2}

The meaning of each reference numeral in the above expression is as follows.

a*₁: a* in a case of using a base material-attached wavelength selective absorption layer containing a dye

a*₀: a* of No. c001 in a case of using a base material-attached wavelength selective absorption layer that does not contain dye

b*₁: b* in a case of using a base material-attached wavelength selective absorption layer containing a dye

b*₀: b* of No. c001 in a case of using a base material-attached wavelength selective absorption layer that does not contain dye

In this test, the color difference calculated from the above expression is 16.0 or less in terms of the practical level and 5.0 or less in terms of the more preferred level.

<Light Resistance>

(Production of Light Resistance Evaluation Film)

Atriacetyl cellulose film (product name: Fujitac TD80UL, manufactured by FUJIFILM Corporation) having a thickness of 80 μm was bonded on the side of the gas barrier layer of the laminate with a pressure sensitive adhesive 1 (product name: SK2057, manufactured by Soken Chemical Co., Ltd.) having a thickness of about 20 m being interposed. Subsequently, the base material 1 was peeled off, and glass was bonded to the wavelength selective absorption layer side to which the base material 1 was bonded with the pressure sensitive adhesive 1 being interposed, thereby producing a light resistance evaluation film.

(Maximal Absorption Value of Light Resistance Evaluation Film)

Using a UV3600 spectrophotometer (product name) manufactured by Shimadzu Corporation, the absorbance of the light resistance evaluation film in a wavelength range of 200 nm to 1,000 nm was measured every 1 nm. The absorbance difference between the absorbance of the light resistance evaluation film at each wavelength and the absorbance of the light resistance evaluation film having the same configuration except that it does not contain the dye was calculated, and the maximum value of this absorbance difference was defined as the maximal absorption value.

(Light Resistance)

The light resistance evaluation film was irradiated with light for 200 hours in an environment of 60° C. and 50% relative humidity with Super Xenon Weather Meter SX75 (product name) manufactured by Suga Test Instruments Co., Ltd., and the maximal absorption value before and after this irradiation was measured, and the light resistance was calculated according to the following expression. The results are shown in Table 2.

[Light resistance (%)]=([a maximal absorption value after light irradiation for 200hours]/[a maximal absorption value before light irradiation])×100

TABLE 2

| | Relative | Reflectivity | Tint of reflected light | | | | | |
|---|---|---|---|---|---|---|---|---|
| | brightness | reduction | | | Color | Light resistance (200 hrXe) | | |
| No. | (%) | rate | a* | b* | difference | Dye A | Dye B | Dye C |
| 101 | 74 | AA | 0.9 | −0.3 | 1.2 | 96% | 80% | 90% |
| 102 | 68 | AA | −0.9 | −0.5 | 0.8 | 88% | 96% | 90% |
| 103 | 70 | AA | −0.5 | −0.1 | 0.3 | 88% | 93% | 90% |
| 104 | 67 | AA | 0.6 | 0.2 | 0.8 | 10% | 97% | 90% |
| 105 | 74 | B | −0.7 | −0.3 | 0.6 | 96% | 81% | 95% |
| c001 | 100 | D | −0.2 | 0.0 | 0.0 | — | — | — |
| c002 | 70 | AA | 23.1 | −37.8 | 44.4 | — | 92% | 90% |
| c003 | 74 | AA | 15.0 | −23.2 | 27.7 | — | 82% | 90% |
| c004 | 81 | B | 0.7 | −31.4 | 31.3 | — | 81% | 90% |
| c005 | 86 | C | 10.7 | −0.5 | 10.9 | — | 80% | 90% |

(Note in Table 2)
The “—” notation in the column of the light resistance evaluation indicates that the corresponding dye is not contained.

The relative brightness, the reflectivity reduction rate, and the tint of the reflected light are evaluated in a state where the gas barrier layer is not provided, but the light resistance is evaluated in a state where the gas barrier layer is provided.

From the results in Table 2, the following facts can be seen.

In the laminate Nos. c002 to c005 including a wavelength selective absorption layer for comparison which contains only the dye B and the dye C but does not contains the dye A, a change (a color difference) in a tint of reflected light becomes large in a case where an attempt is made to reduce the reflectivity (No. c002 to c004), and conversely, the reflectivity cannot be sufficiently reduced in a case where an attempt is made to suppress the change in the tint of the reflected light to be small (No. c005). That is, it is not possible to achieve both reduction of external light reflection and suppression of a decrease in brightness at a high level while sufficiently suppressing a change in the tint of the reflected light.

On the other hand, in the laminate Nos. 101 to 105 having a wavelength selective absorption layer in which all of the dyes A, B, and C defined in the present invention are contained and having a wavelength selective absorption layer satisfying a specific relationship defined by Expression (I), the change in the tint of the reflected light due to the inclusion of the wavelength selective absorption layer is suppressed to be small, the reduction rate of the reflectivity is high, and the decrease in the relative brightness is also suppressed.

Among them, in the laminate No. 101 in which the minimum transmittance at a wavelength of 580 to 620 nm is smaller than the minimum transmittance at a wavelength of 500 to 520 nm and Tₘᵢₙ(500 to 520)−Tₘᵢₙ(580 to 620)>0% is satisfied, the reduction rate of the reflectivity is larger in the comparison in a state where the same relative brightness of 74% is exhibited as compared with the laminate No. 105 in which the minimum transmittance at a wavelength of 580 to 620 nm is larger than the minimum transmittance at a wavelength of 500 to 520 nm and Tₘᵢₙ(500 to 520)−Tₘᵢₙ(580 to 620)>0% is not satisfied, which is particularly preferable.

In addition, in the laminate Nos. 101 to 105 having a wavelength selective absorption layer containing all of the dyes A, B, and C defined in the present invention and having a gas barrier layer satisfying a specific relationship defined in the present invention, the change in the tint of the reflected light due to the inclusion of the wavelength selective absorption layer is suppressed to be small, the reduction rate of the reflectivity is high, the decrease in the relative brightness is also suppressed, and the excellent light resistance can be exhibited. In particular, it can be seen that the laminate Nos. 101 to 103 and 105 which contain the dye represented by General Formula (A1) defined in the present invention exhibits excellent light resistance as compared with the laminate of No. 104.

Although the present invention has been described with reference to the embodiments, it is the intention of the inventors of the present invention that the present invention should not be limited by any of the details of the description unless otherwise specified and rather be construed broadly within the spirit and scope of the invention appended in WHAT IS CLAIMED IS.

### EXPLANATION OF REFERENCES

11: aluminum foil substrate
91: wavelength selective absorption filter (wavelength selective absorption layer)
92: gas barrier layer
93: laminate
D65: white light having spectrum of standard illuminant D65 defined by International Commission on Illumination (CIE)
R: reflected light

What is claimed is:

1. A self-luminous display device comprising:
a wavelength selective absorption filter containing a resin and a dye that includes the following dyes A, B, and C; and
a light emitting diode as a light emitting source,
wherein the wavelength selective absorption filter satisfies a definition according to Expression (I),
the dye A: a dye having a main absorption wavelength band at a wavelength of 390 to 435 nm
the dye B: a dye having a main absorption wavelength band at a wavelength of 500 to 520 nm
the dye C: a dye having a main absorption wavelength band at a wavelength of 580 to 620 nm
Tₘᵢₙ(500to520)−Tₘᵢₙ(580to620)>0% Expression (I)
in the expression, Tₘᵢₙ(500 to 520) indicates a minimum transmittance (%) at a wavelength of 500 to 520 nm, and Tₘᵢₙ(580 to 620) indicates a minimum transmittance (%) at a wavelength of 580 to 620 nm.

2. A self-luminous display device comprising:
a wavelength selective absorption filter containing a resin and the following dyes A, B, and C; and
a light emitting diode as a light emitting source,
wherein the wavelength selective filter has a gas barrier layer directly disposed on at least one surface of the wavelength selective absorption filter, and
the gas barrier layer contains a crystalline resin, where a thickness of the gas barrier layer is 0.1 μm to 10 μm, and an oxygen permeability of the gas barrier layer is 60 cc/m²·day·atm or less,
the dye A: a dye having a main absorption wavelength band at a wavelength of 390 to 435 nm
the dye B: a dye having a main absorption wavelength band at a wavelength of 500 to 520 nm
the dye C: a dye having a main absorption wavelength band at a wavelength of 580 to 620 nm.

3. The self-luminous display device according to claim 1,
wherein the wavelength selective filter has a gas barrier layer directly disposed on at least one surface of the wavelength selective absorption filter, and
the gas barrier layer contains a crystalline resin, where a thickness of the gas barrier layer is 0.1 μm to 10 μm, and an oxygen permeability of the gas barrier layer is 60 cc/m²·day·atm or less.

4. The self-luminous display device according to claim 2,
wherein a degree of crystallinity of the crystalline resin contained in the gas barrier layer is 25% or more.

5. The self-luminous display device according to claim 2,
wherein the oxygen permeability of the gas barrier layer is 0.001 cc/m²·day·atm or more and 60 cc/m²·day·atm or less.

6. The self-luminous display device according to claim 1,
wherein the wavelength selective absorption filter contains an antifading agent for a dye.

7. The self-luminous display device according to claim 1,
wherein at least one of the dye B or C is a squarine-based coloring agent represented by General Formula (1), 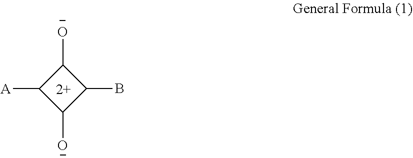
in the formula, A and B each independently represent an aryl group which may have a substituent, a heterocyclic group which may have a substituent, or —CH=G, where G represents a heterocyclic group which may have a substituent.

8. The self-luminous display device according to claim 1,
wherein the dye A is a coloring agent represented by General Formula (A1), 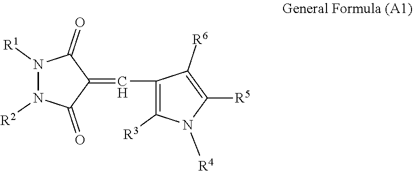
in the formula, R¹ and R² each independently represent an alkyl group or an aryl group, R³ to R⁶ each independently represent a hydrogen atom or a substituent, and R⁵ and R⁶ may be bonded to each other to form a 6-membered ring.

9. The self-luminous display device according to claim 6,
wherein the antifading agent is represented by General Formula (IV 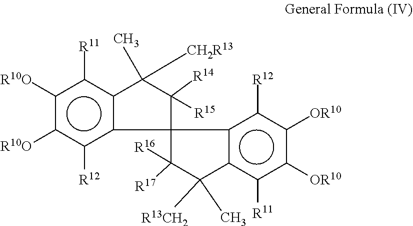
in the formula, R¹⁰'s each independently represent an alkyl group, an alkenyl group, an aryl group, a heterocyclic group, or a group represented by R¹⁸CO—, R¹⁹SO₂—, or R²⁰NHCO—, where R¹⁸, R¹⁹, and R²⁰ each independently represent an alkyl group, an alkenyl group, an aryl group, or a heterocyclic group,
R¹¹ and R¹² each independently represent a hydrogen atom, a halogen atom, an alkyl group, an alkenyl group, an alkoxy group, or an alkenyloxy group, and
R¹³ to R¹⁷ each independently represent a hydrogen atom, an alkyl group, an alkenyl group, or an aryl group.

10. The self-luminous display device according to claim 1,
wherein the resin in the wavelength selective absorption filter includes a polystyrene resin.

11. The self-luminous display device according to claim 1,
wherein the light emitting diode includes a mini light emitting diode or a micro light emitting diode.
